(19) United States
(12) Patent Application Publication
(10) Pub. No.: US 2015/0105563 A1
(43) Pub. Date: Apr. 16, 2015

(54) NOVEL ORGANIC ELECTROLUMINESCENT COMPOUNDS AND ORGANIC ELECTROLUMINESCENT DEVICE COMPRISING THE SAME

(71) Applicant: Rohm and Haas Electronic Materials Korea Ltd., Cheonan-Si (KR)

(72) Inventors: Hee-Choon Ahn, Gyeonggi-do (KR); Young-Jun Cho, Gyeonggi-do (KR); Bong-Ok Kim, Seoul (KR); Yong-Gil Kim, Gyeonggi-do (KR); Hyuck-Joo Kwon, Seoul (KR); Jong-Seok Ku, Gyeonggi-do (KR); Hyo-Jung Lee, Gyeonggi-do (KR); Kyung-Joo Lee, Seoul (KR); Tae-Jin Lee, Seoul (KR); Jeong-eun Yang, Gyeonggi-do (KR)

(73) Assignee: Rohm and Haas Electronic Materials Korea Ltd., Cheonan-Si (KR)

(21) Appl. No.: 14/504,565

(22) PCT Filed: Apr. 2, 2013
(86) PCT No.: PCT/KR2013/002713

§ 371 Date: Oct. 2, 2014

(30) Foreign Application Priority Data
Apr. 3, 2012 (KR) 10-2012-0034639

(51) Int. Cl. H01L 51/00

(52) U.S. Cl. CPC H01L 51/0072; H01L 51/0071; H01L 51/5012
USPC 548/418

(57) ABSTRACT

The present invention relates to novel organic electroluminescent compounds and an organic electroluminescent device containing the same. The organic electroluminescent compounds according to the present invention can be used as a phosphorescent host material, a hole transport material, or a mixed host material; have a good hole transport ability; prevent crystallization in the production of the device; are suitable for forming a layer; and improve the current density of the device thereby reducing the driving voltage of the device.

### TECHNICAL FIELD

The present invention relates to novel organic electroluminescent compounds and organic electroluminescent device comprising the same.

### BACKGROUND ART

An electroluminescent (EL) device is a self-light-emitting device with the advantage of providing a wider viewing angle, a greater contrast ratio, and a faster response time. An organic EL device was first developed by Eastman Kodak, by using small aromatic diamine molecules, and aluminum complexes as a material for forming a light-emitting layer [Appl. Phys. Lett. 51, 913, 1987].

The most important factor determining luminous efficiency in an organic EL device is the light-emitting material. Until now, fluorescent materials have been widely used as light-emitting materials. However, in view of electroluminescent mechanisms, developing phosphorescent materials is one of the best methods to theoretically enhance luminous efficiency by four (4) times compared to fluorescent materials. Iridium(III) complexes have been widely known as phosphorescent materials, including bis(2-(2′-benzothienyl)-pyridinato-N,C3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively.

The light-emitting material may be used in the combination of a host material with a light-emitting material (dopant) to improve color purity, luminous efficiency, and stability. In a system of a light-emitting material (dopant)/host material, the selection of a host material is important, because the host material greatly influences the efficiency and capacity of a light-emitting device. Until now, 4,4′-N,N′-dicarbazol-biphenyl (CBP) is the most widely known phosphorescent host material. Further, Pioneer (Japan) et al., developed a high performance organic EL device by employing bathocuproine (BCP) and aluminum(III)bis(2-methyl-8-quinolinate)(4-phenylphenolate) (BAlq), which were used in a hole blocking layer, as host materials.

Though these phosphorescent host materials provide good light-emitting characteristics, they have the following disadvantages: (1) Due to their low glass transition temperatures and poor thermal stability, their degradation may occur during a high-temperature deposition process in a vacuum. (2) The power efficiency of an organic EL device is given by [(π/voltage)×current efficiency], and the power efficiency is inversely proportional to voltage. An organic EL device comprising phosphorescent host materials provides higher current efficiency (cd/A) and has a higher driving voltage than one comprising fluorescent host materials. Thus, the EL device using conventional phosphorescent materials has no advantage in terms of power efficiency (Im/W). (3) Further, the operating lifespan and luminous efficiency of the organic EL device are not satisfactory.

Meanwhile, copper phthalocyanine (CuPc), 4,4′-bis[N-(1-naphthyl)-N-phenylamino]biphenyl (NPB), N,N′-diphenyl-N,N′-bis(3-methylphenyl)-(1,1′-biphenyl)-4,4′-diamine (TPD), 4,4′,4″-tris(3-methylphenylphenylamino)triphenylamine (MTDATA), etc., have been used as hole injection and transport materials in the organic EL device. However, the organic EL device comprising the materials has low quantum efficiency and a short operating lifespan, because, when the organic EL device is driven at a high current, thermal stress is generated between an anode and a hole injection layer, thereby rapidly reducing the operating lifespan of the device. Further, holes greatly move in organic materials used in a hole injection layer, and thus the hole-electron charge balance is broken and quantum efficiency (cd/A) is reduced.

International Publication No. WO 2009/148015 discloses compounds for an organic EL device, wherein a heteroaryl group including carbazole, dibenzofuran, and dibenzothiophene is directly bonded to the carbon atom in backbones of polycyclic compounds which are formed by fusing fluorene, carbazole, dibenzofuran, and dibenzothiophene with a heteroaryl group including indene, indole, benzofuran, and benzothiophene.

Further, U.S. Patent Application Laying-Open No. US 2011/0279020 A1 discloses compounds for an organic EL device, wherein two carbazoles are bonded to each other via a single bond between carbon atoms.

However, organic EL devices comprising the compounds of the publications are not satisfactory in power efficiency, luminous efficiency, quantum efficiency, and operating lifespan.

### DISCLOSURE OF THE INVENTION

### Problems to be Solved

The objective of the present invention is to provide an organic electroluminescent compound having high luminous efficiency, a long operating lifespan, and having proper color coordination; and an organic electroluminescent device having high efficiency and a long lifespan, comprising the organic electroluminescent compound in a light-emitting layer or a hole transport layer.

### Solution to Problems

The present inventors found that the above objective can be achieved by a compound represented by the following formula 1:

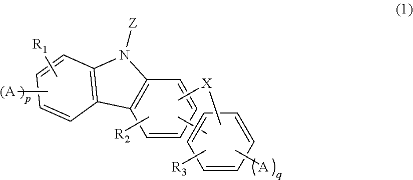

wherein

A is represented by the following formula 2:

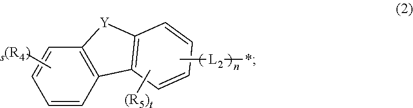

formula 2 is bonded to the compound of formula 1 via *;

Z is represented by the following formula 3:

*-(L₁)ₘ-Ar₁ (3);

formula 3 is bonded to the compound of formula 1 via *;

L₁ and L₂ each independently represent a single bond, a substituted or unsubstituted 5-to 30-membered heteroarylene group, or a substituted or unsubstituted (C6-C30)arylene group;

X and Y each independently represent —O—, —S—, —N(R₆)—, —C(R₇)(R₈)—, or —Si(R₉)(R₁₀)—;

Ar₁ and R₁ to R₅ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₁R₁₂, or —SiR₁₃R₁₄R₁₅; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur, proviso that when q is 1, R₁ is not the group of formula 2, and when p is 1, R₃ is not the group of formula 2;

R₆ to R₁₅ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group; or are linked to an adjacent substituent(s) to form a mono- or polycyclic, 3- to 30-membered alicyclic or aromatic ring

m and n each independently represent an integer of 0 to 2; where m is 2, each of L₁ is the same or different, and n is 2, each of L₂ is the same or different;

p and q each independently represent an integer of 0 or 1; where p+q=1;

s and t each independently represent an integer of 1 or 2; where s is 2, each of R₄ is the same or different, and t is 2, each of R₅ is the same or different; and

the heteroaryl(ene) group contains at least one hetero atom selected from B, N, O, S, P(═O), Si and P.

### Effects of the Invention

The organic electroluminescent compounds according to the present invention have advantages in that they have high luminous efficiency and a long operating lifespan, and thus can produce an organic electroluminescent device having a long driving lifespan. Further, the organic electroluminescent compounds according to the present can be used as a phosphorescent host material, a hole transport material, or mixed host materials; have the superior ability of hole transport; prevent crystallization in the production of the device; are suitable for forming a layer; and improve the current density of the device thereby reducing driving voltage of the device.

### EMBODIMENTS OF THE INVENTION

Hereinafter, the present invention will be described in detail. However, the following description is intended to explain the invention, and is not meant in any way to restrict the scope of the invention.

The present invention relates to an organic electroluminescent compound represented by formula 1 above, an organic electroluminescent material comprising the organic electroluminescent compound, and an organic electroluminescent device comprising the material.

Herein, “(C1-C30)alkyl(ene)” is meant to be a linear or branched alkyl(ene) having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc. “(C2-C30) alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc. “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc. “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc. “3- to 7-membered heterocycloalkyl” is a cycloalkyl having at least one heteroatom selected from B, N, O, S, P(═O), Si and P, preferably O, S and N, and 3 to 7, preferably 5 to 7 ring backbone atoms, and includes tetrahydrofurane, pyrrolidine, thiolan, tetrahydropyran, etc. “(C6-C30)aryl(ene)” is a monocyclic or fused ring derived from an aromatic hydrocarbon having 6 to 30 carbon atoms, in which the number of carbon atoms is preferably 6 to 20, more preferably 6 to 15, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc. “5- to 30-membered heteroaryl(ene)” is an aryl group having at least one, preferably 1 to 4 heteroatom selected from the group consisting of B, N, O, S, P(═O), Si and P, and 5 to 30 ring backbone atoms; is a monocyclic ring, or a fused ring condensed with at least one benzene ring; has preferably 5 to 20, more preferably 5 to 15 ring backbone atoms; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, Cl, Br and I.

Herein, “substituted” in the expression “substituted or unsubstituted” means that a hydrogen atom in a certain functional group is replaced with another atom or group, i.e., a substituent.

Substituents of the substituted alkyl group, the substituted aryl(ene) group, and the substituted heteroaryl(ene) group in L₁, L₂, Ar₁, and R₁ to R₁₅ groups of formulae 1 to 3, each independently are at least one selected from the group consisting of deuterium; a halogen; a cyano group; a carboxyl group; a nitro group; a hydroxyl group; a (C1-C30)alkyl group; a halo(C1-C30)alkyl group; a (C6-C30)aryl group; a 5- to 30-membered heteroaryl group; a 5- to 30-membered heteroaryl group substituted with a (C6-C30)aryl; a (C6-C30)aryl group substituted with a 5- to 30-membered heteroaryl; a (C3-C30)cycloalkyl group; a 3- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; and a (C1-C30)alkyl(C6-C30)aryl group.

The compound of formula 1 according to the present invention is selected from the group consisting of the following formulae 4 to 9:

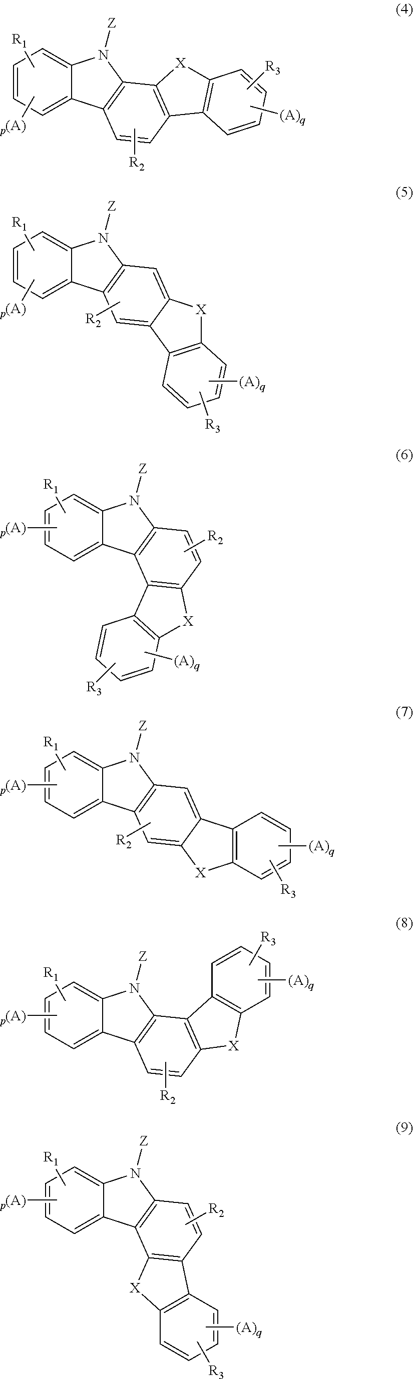

wherein

A, Z, X, R₁ to R₃, p, and q are as defined in formula 1.

The substituents in the above formulae are specifically defined in the below.

A is preferably represented by the following formula 10:

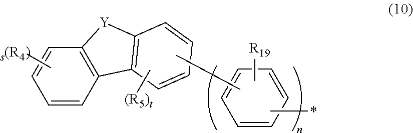

wherein

formula 10 is bonded to the compounds of formulae 1 and 4 to 9 via *;

Y, R₄, R₅, n, s and t are as defined in claim 1;

R₁₉ each independently represents hydrogen, deuterium, a halogen, a substituted or unsubstituted (C1-C30)alkyl group, a substituted or unsubstituted (C6-C30)aryl group, or a substituted or unsubstituted 5- to 30-membered heteroaryl group, preferably hydrogen or an unsubstituted (C1-C30)alkyl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur; and

the heteroaryl group contains at least one hetero atom selected from B, N, O, S, P(═O), Si and P.

X preferably represents —O—, —S—, or —C(R₇)(R₈)—.

Y preferably represents —O—, —S—, or —N(R₆)—; more preferably, —N(R₆)—.

Z preferably represents formula 3, wherein Ar₁ represents a substituted or unsubstituted (C1-C30)alkyl group, a substituted or unsubstituted (C6-C30)aryl group, a substituted or unsubstituted 5- to 30-membered heteroaryl group, —NR₁₁R₁₂, or —SiR₁₃R₁₄R₁₅. More preferably, Z represents formula 3, wherein L₁ represents a single bond, or a substituted or unsubstituted (C6-C30)arylene group, and Ar₁ represents an unsubstituted (C1-C10)alkyl group, a (C6-C20)aryl group unsubstituted or substituted with a (C1-C10)alkyl, a 5- to 20-membered heteroaryl group unsubstituted or substituted with a (C1-C10)alkyl, or —NR₁₁R₁₂.

More preferably, Z represents the following formula 11:

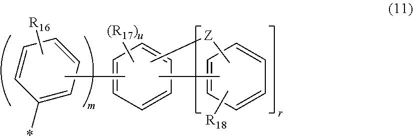

wherein

formula 11 is bonded to the compounds of formulae 1 and 4 to 9 via *;

Z represents —O—, —S—, —N(R₂₀)—, —C(R₂₁)(R₂₂)—, or —Si(R₂₃)(R₂₄)—;

R₁₆ to R₁₈ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₂₅R₂₆, or —SiR₂₇R₂₈R₂₉; preferably hydrogen or an unsubstituted (C1-C30)alkyl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;

R₂₀ to R₂₉ each independently represent hydrogen, deuterium, a halogen, a substituted or unsubstituted (C1-C30)alkyl group, a substituted or unsubstituted (C6-C30)aryl group, or a substituted or unsubstituted 5- to 30-membered heteroaryl group; preferably hydrogen, an unsubstituted (C1-C30)alkyl group, or an unsubstituted (C6-C30)aryl group; or are linked to an adjacent substituent(s) to form a mono- or polycyclic, 3- to 30-membered alicyclic or aromatic ring;

m represents an integer of 0 to 2, preferably 0 or 1;

r represents an integer of 0 or 1, preferably 0;

u represents an integer of 1 to 3; where u is 2 or more, each of R₁₇ is the same or different; and

the heteroaryl group contains at least one hetero atom selected from B, N, O, S, P(═O), Si and P.

Preferably, R₁ to R₅ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₁R₁₂, or —SiR₁₃R₁₄R₁₅; or are linked to an adjacent substituent(s) to form a monocyclic, 3- to 30-membered aromatic hydrocarbon ring. More preferably, R₁ to R₅ each independently represent hydrogen; an unsubstituted (C1-C10)alkyl group; a (C6-C20)aryl group unsubstituted or substituted with a (C1-C10)alky or (C6-C20)aryl group; a 5- to 20-membered heteroaryl group unsubstituted or substituted with a (C1-C10)alky or (C6-C20)aryl group; or —NR₁₁R₁₂; or are linked to an adjacent substituent(s) to form a monocyclic, 3- to 30-membered aromatic hydrocarbon ring. Still more preferably, R₁ to R₅ each independently represent hydrogen.

Preferably, R₆ to R₁₀ each independently represent a substituted or unsubstituted (C1-C30)alkyl group, a substituted or unsubstituted (C6-C30)aryl group, or a substituted or unsubstituted 5- to 30-membered heteroaryl group.

Preferably, R₁₁ to R₁₅ each independently represent hydrogen; an unsubstituted (C1-C30)alkyl group; or a (C6-C30)aryl group unsubstituted or substituted with a (C1-C30)alkyl or a (C6-C30)aryl.

The organic electroluminescent compounds of the present invention include the following compounds:

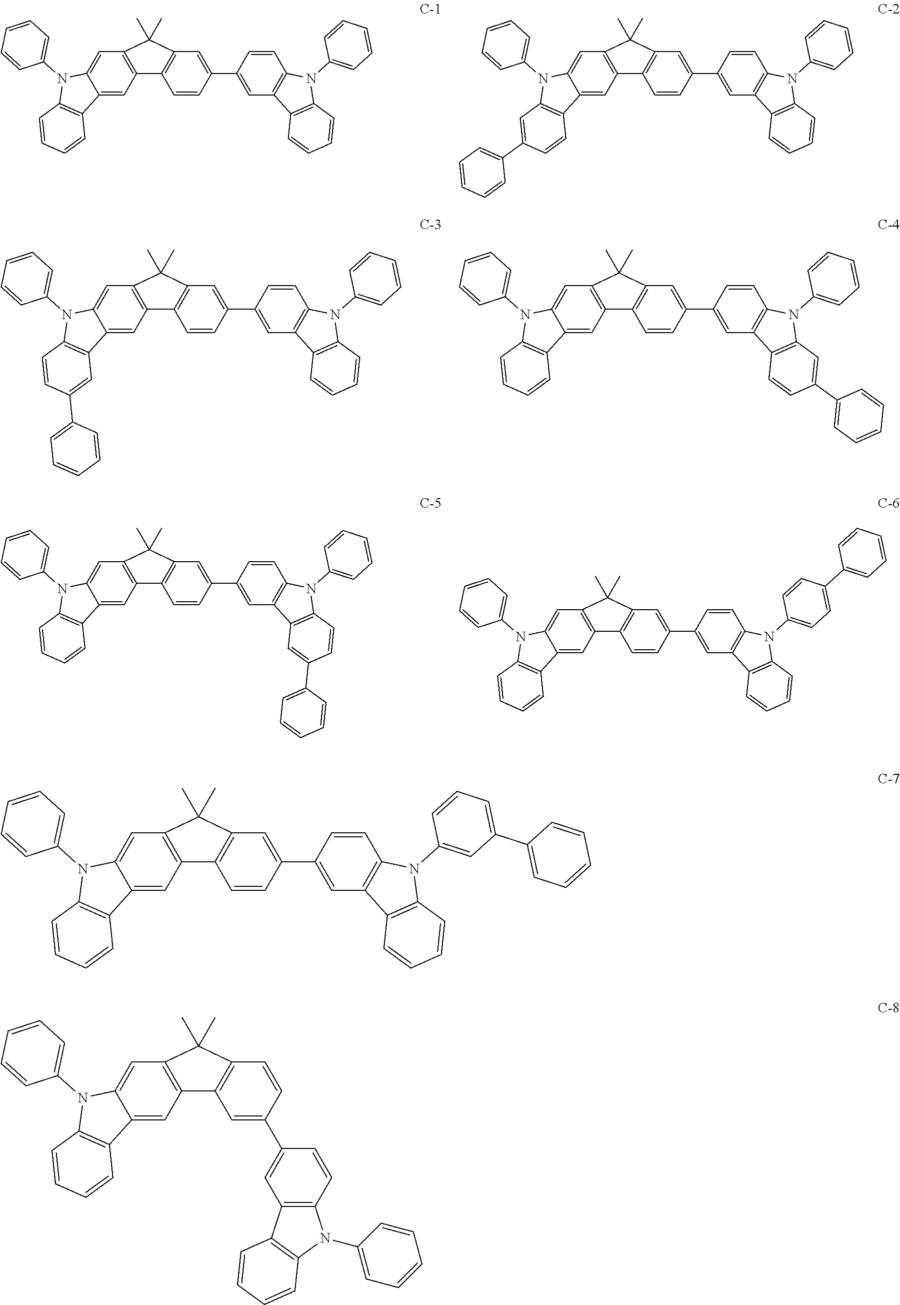

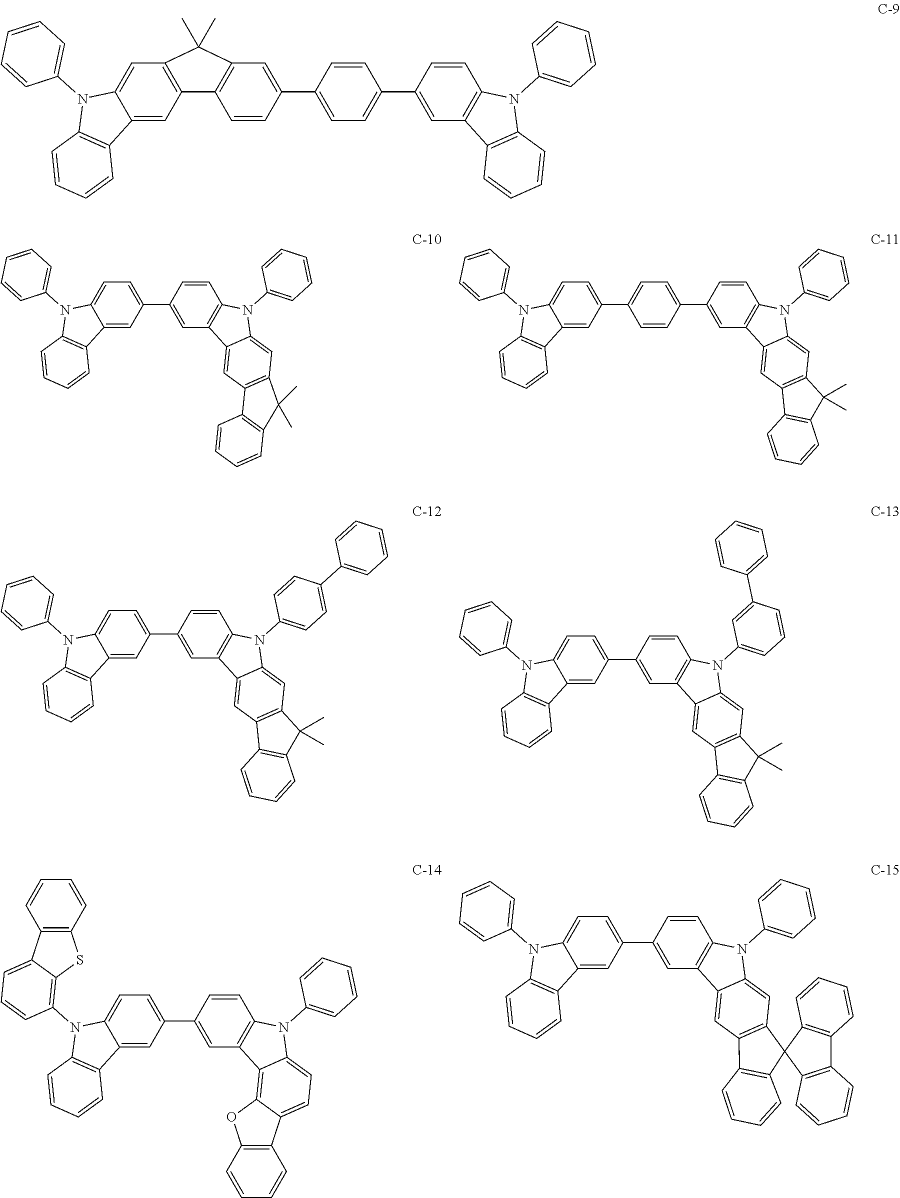

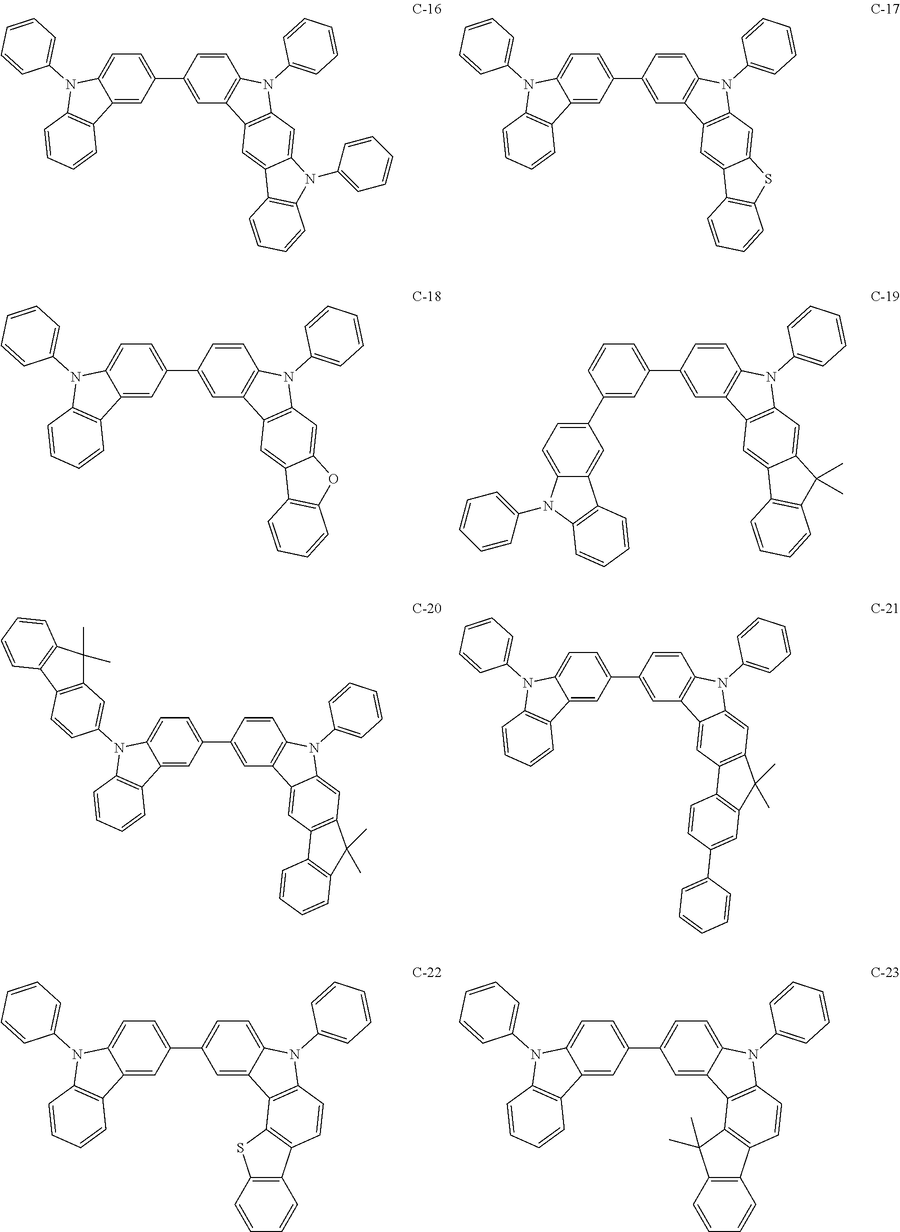

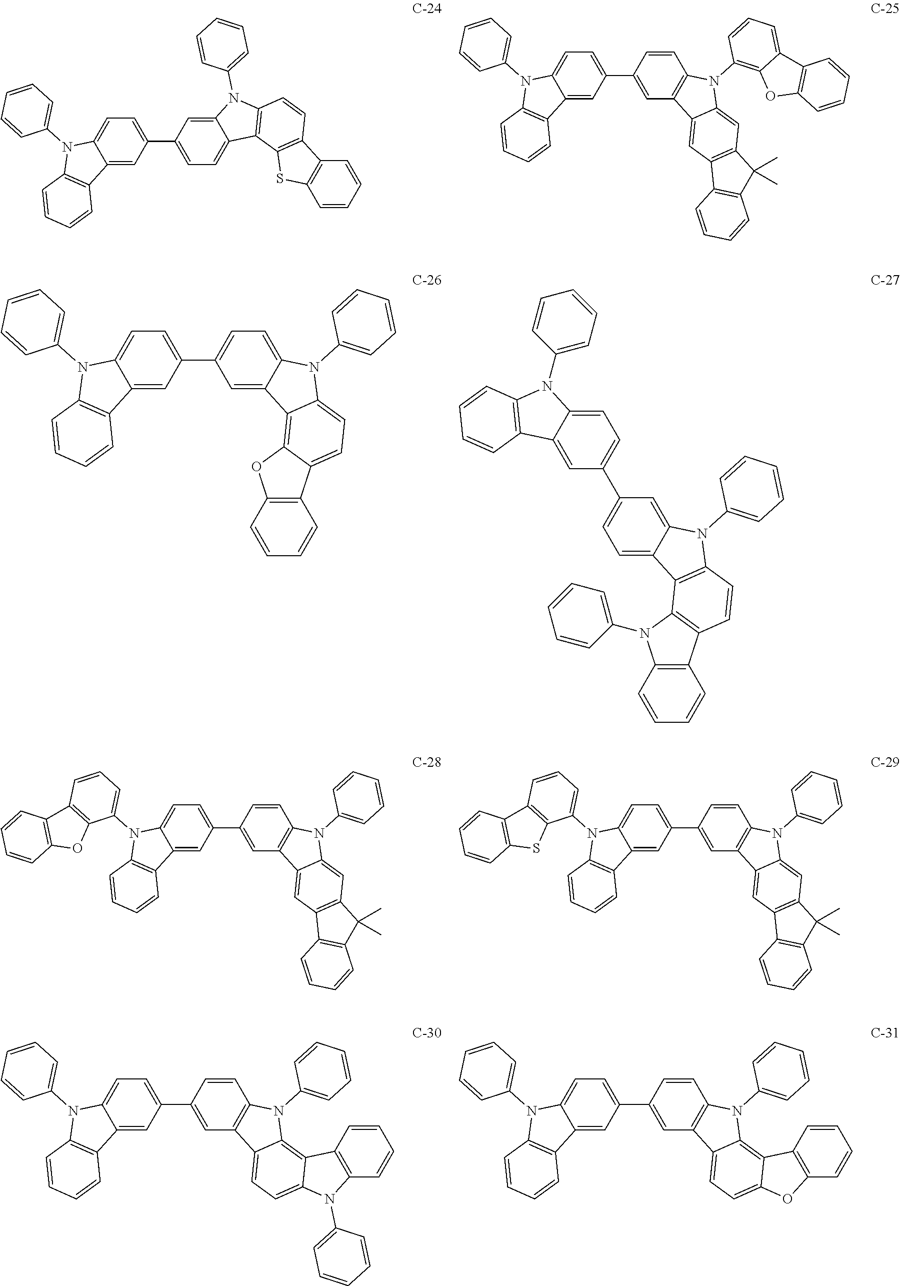

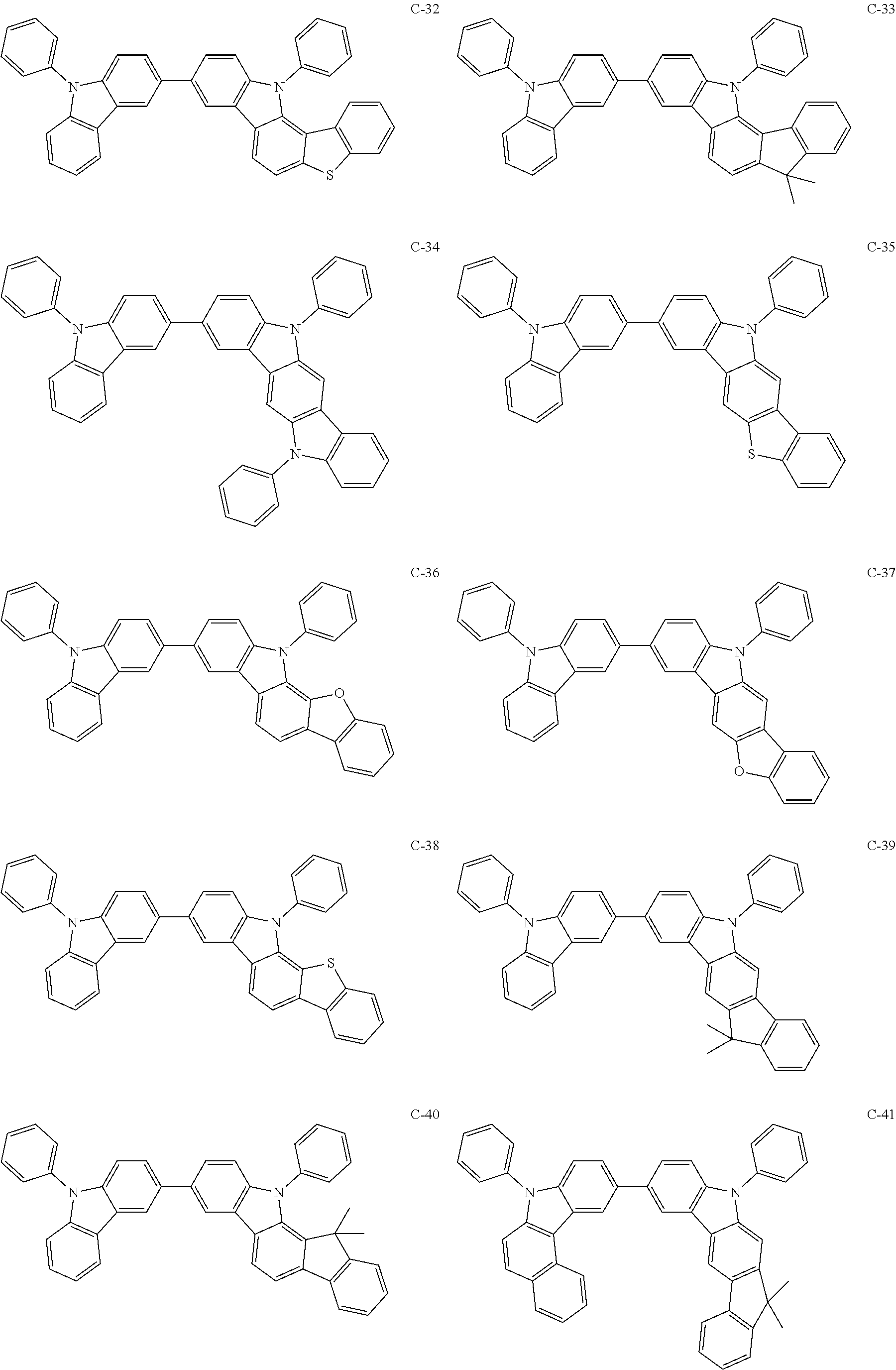

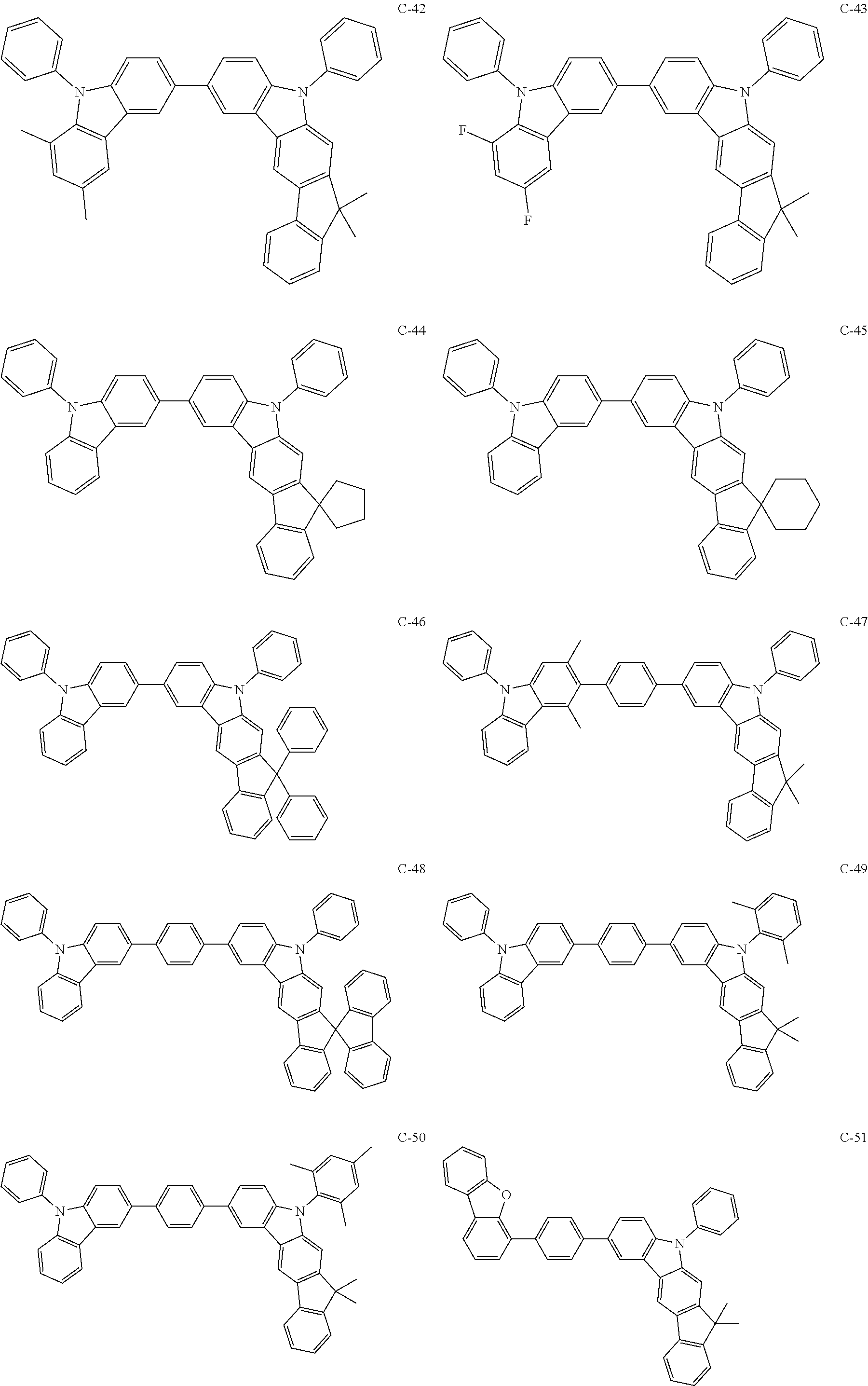

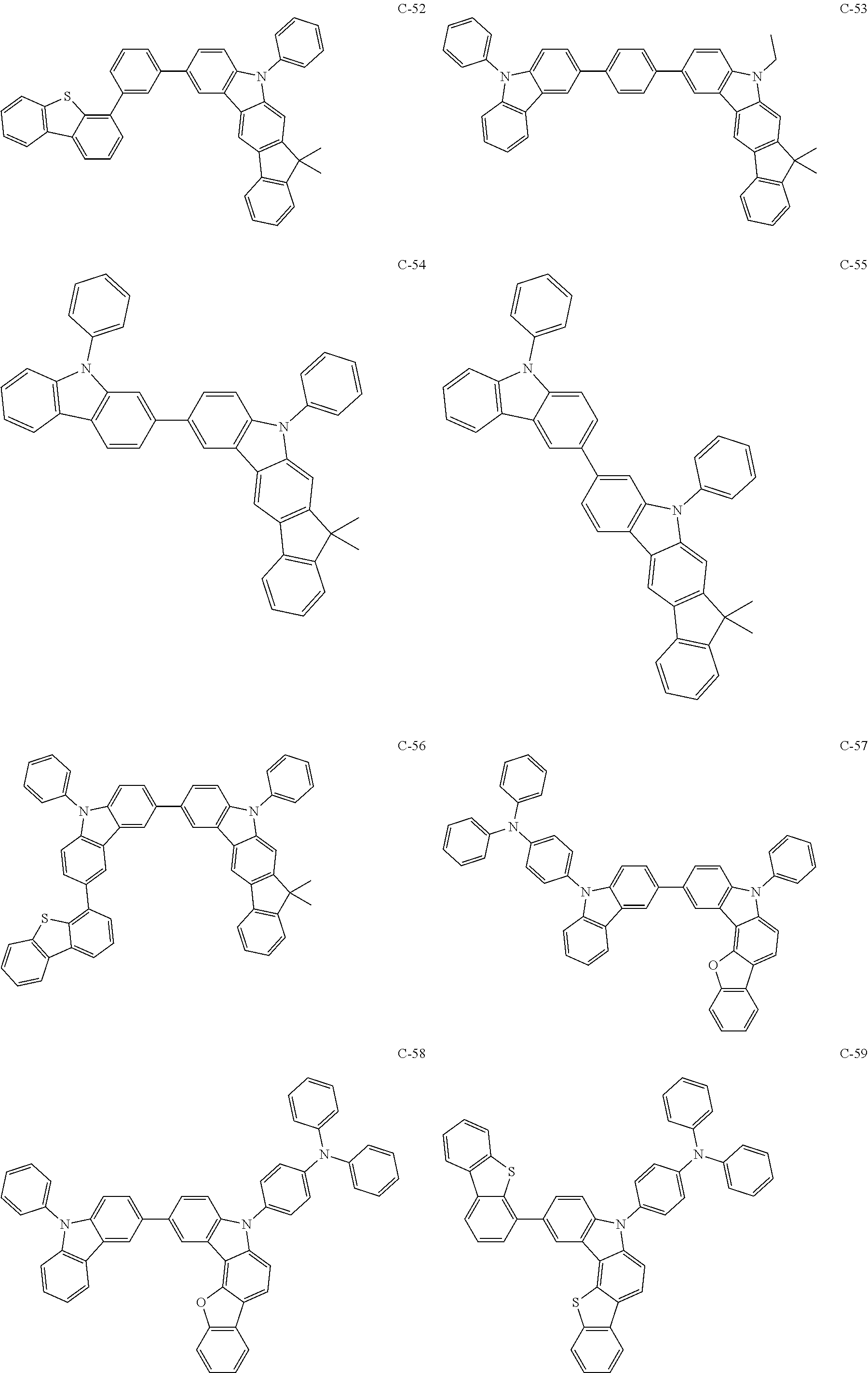

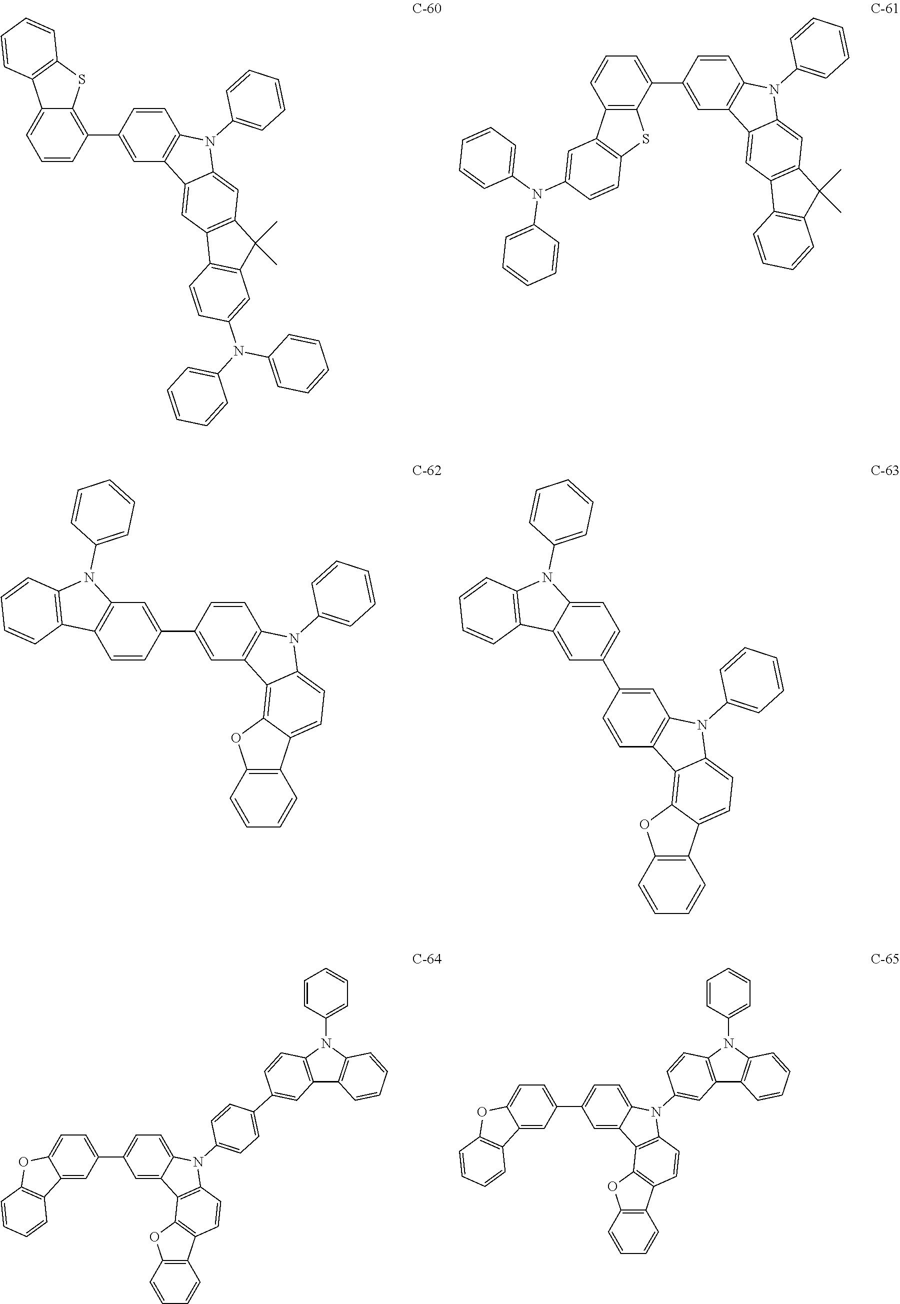

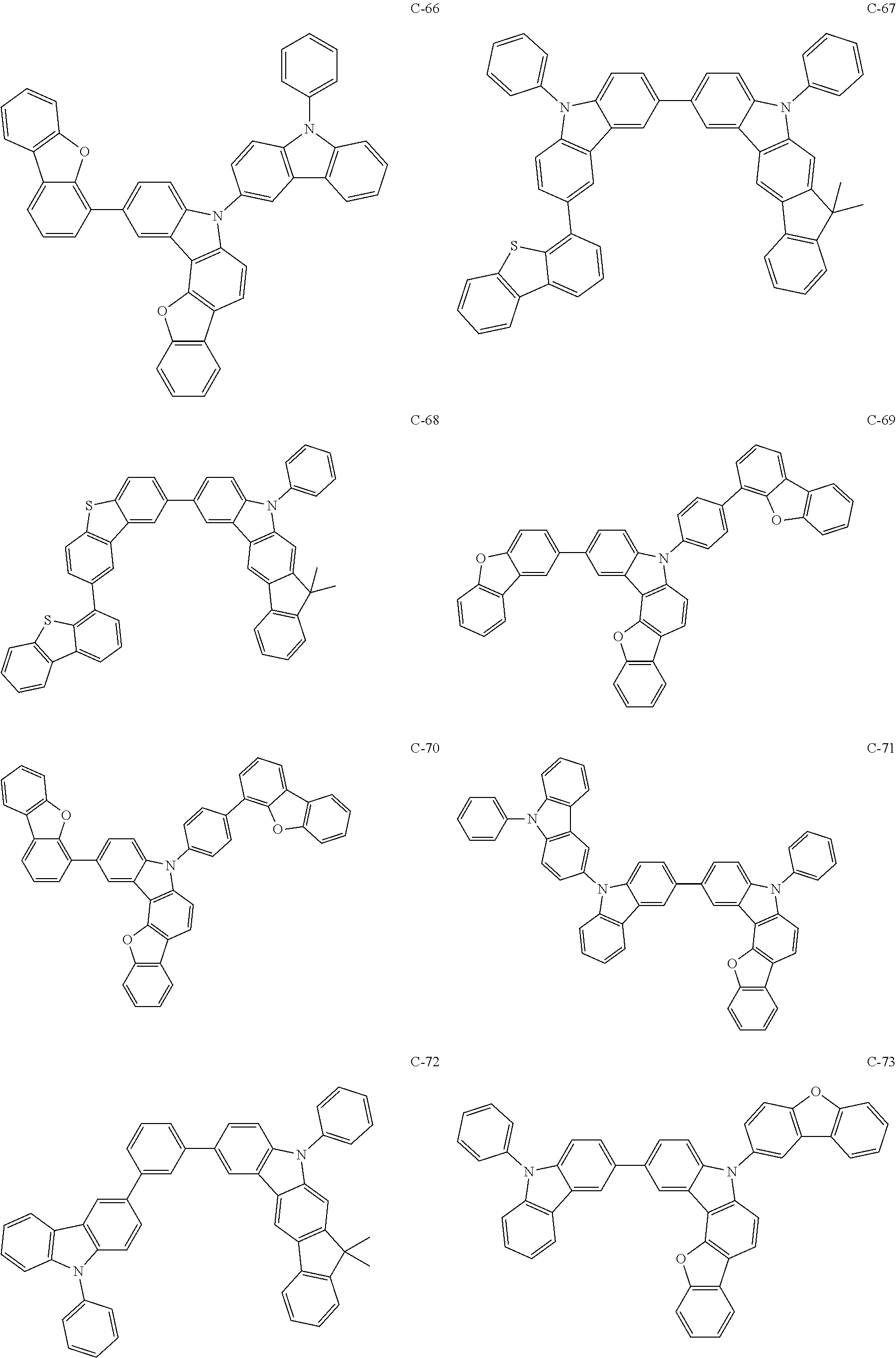

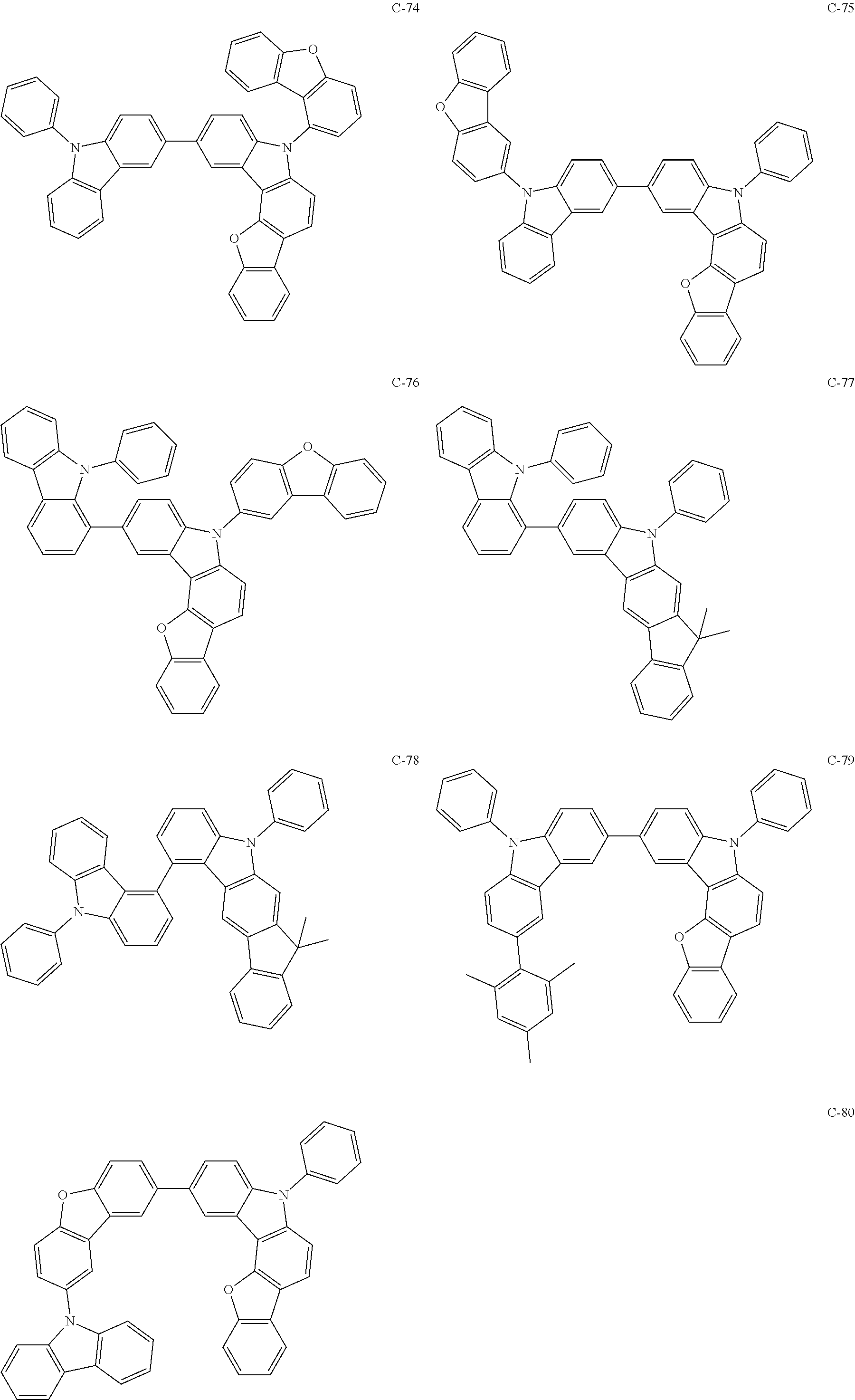

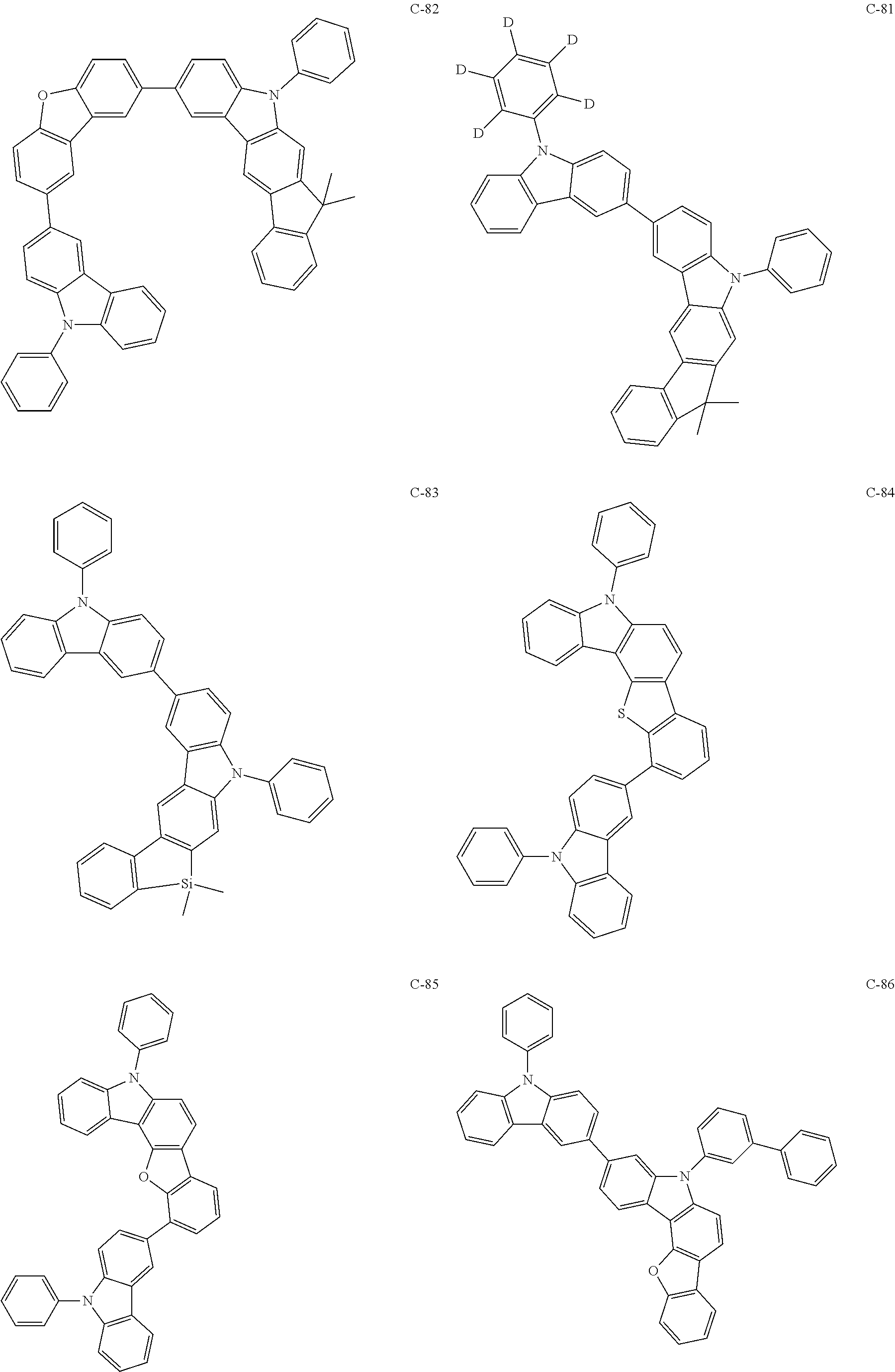

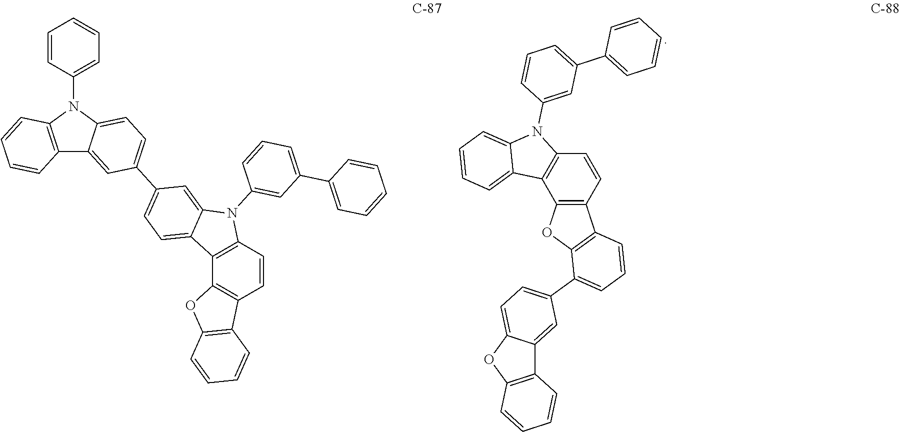 [SMILES: c1ccc(-c2cccc(-n3c4cc(-c5ccc6c(c5)c5ccccc5n6-c5ccccc5)ccc4c4c5oc6ccccc6c5ccc43)c2)cc1 ; c1ccc(-c2cccc(-n3c4ccccc4c4c5oc6c(-c7ccc8oc9ccccc9c8c7)cccc6c5ccc43)c2)cc1]

The organic electroluminescent compounds according to the present invention can be prepared according to the methods known in the art, for example, following reaction schemes 1 and 2.

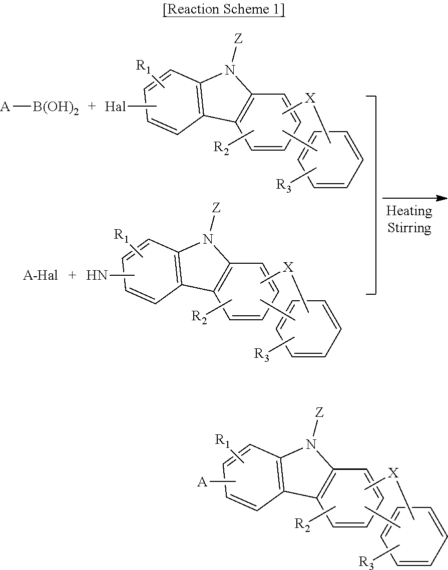

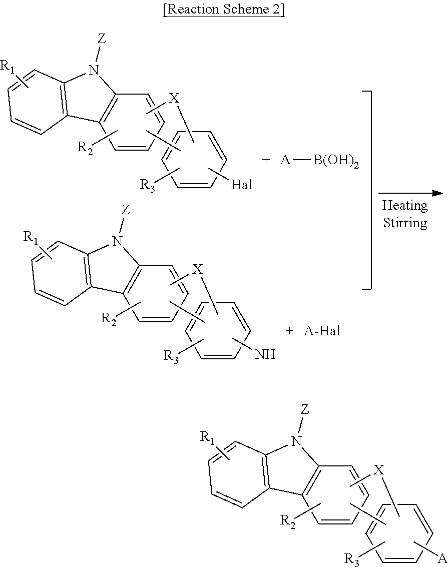

wherein A, Z, X, and R₁ to R₃ are as defined in formula 1 above, and Hal represents a halogen.

The present invention further provides an organic electroluminescent material comprising the organic electroluminescent compound of formula 1, and an organic electroluminescent device comprising the material. The material can be comprised of the organic electroluminescent compound according to the present invention alone, or can further include conventional materials generally used in organic electroluminescent materials. The organic electroluminescent device may comprise a first electrode, a second electrode, and at least one organic layer between the first and second electrodes, wherein the organic layer comprises at least one compound of formula 1 according to the present invention.

One of the first electrodes and the second electrodes can be an anode and the other can be a cathode. The organic layer further comprises a light-emitting layer, and at least one layer selected from the group consisting of a hole injection layer, a hole transport layer, an electron transport layer, an electron injection layer, an interlayer, and a hole blocking layer.

The organic electroluminescent compound of formula 1 of the present invention can be included in at least one of the light-emitting layers and hole transport layers. When used in the hole transport layer, the organic electroluminescent compounds of formula 1 of the present invention can be included as a hole transport material. When used in the light-emitting layer, the organic electroluminescent compounds of formula 1 of the present invention can be included as a host material. Preferably, the light-emitting layer may comprise at least one dopant. If necessary, other compounds in addition to the organic electroluminescent compound of formula 1 of the present invention may be further included as a second host material.

The dopants are preferably one or more phosphorescent dopants. The phosphorescent dopant material applied to the organic electroluminescent device of the present invention is not specifically limited, but preferably may be selected from complex compounds of iridium (Ir), osmium (Os), copper (Cu), and platinum (Pt), more preferably ortho metallated complex compounds of iridium (Ir), osmium (Os), copper (Cu), and platinum (Pt), and even more preferably ortho metallated iridium complex compounds.

The phosphorescent dopants specifically include the following:

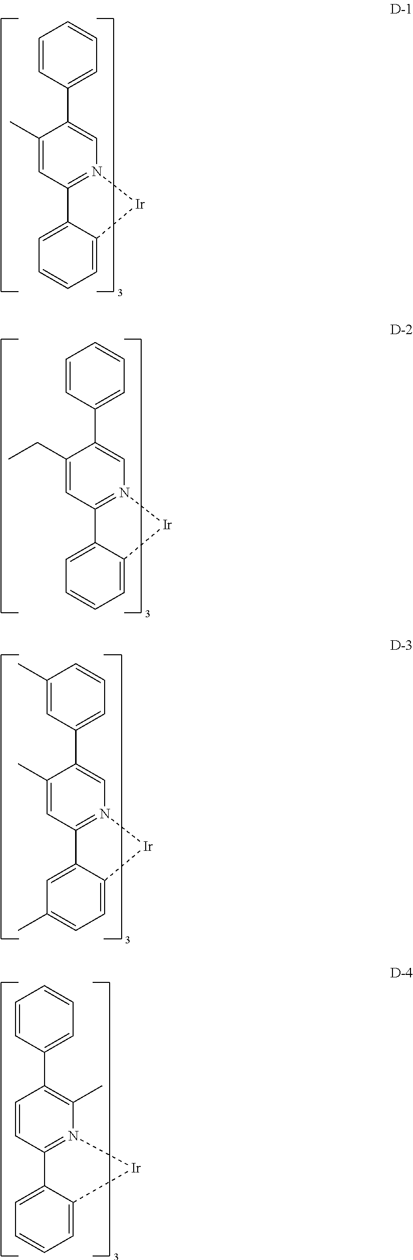

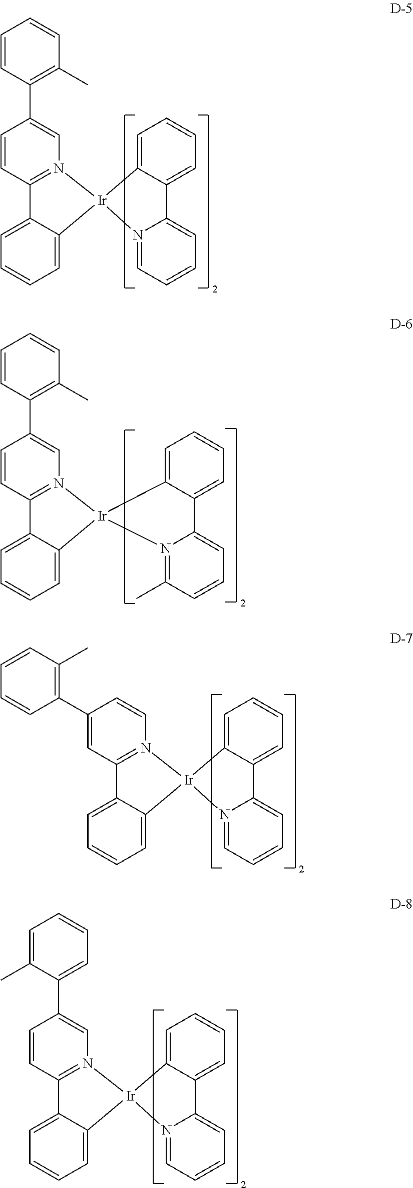

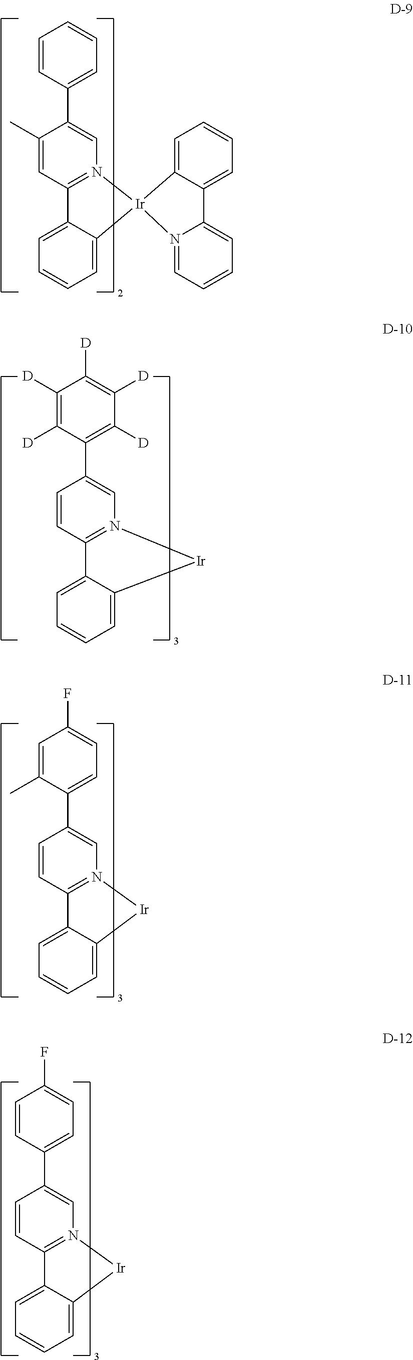

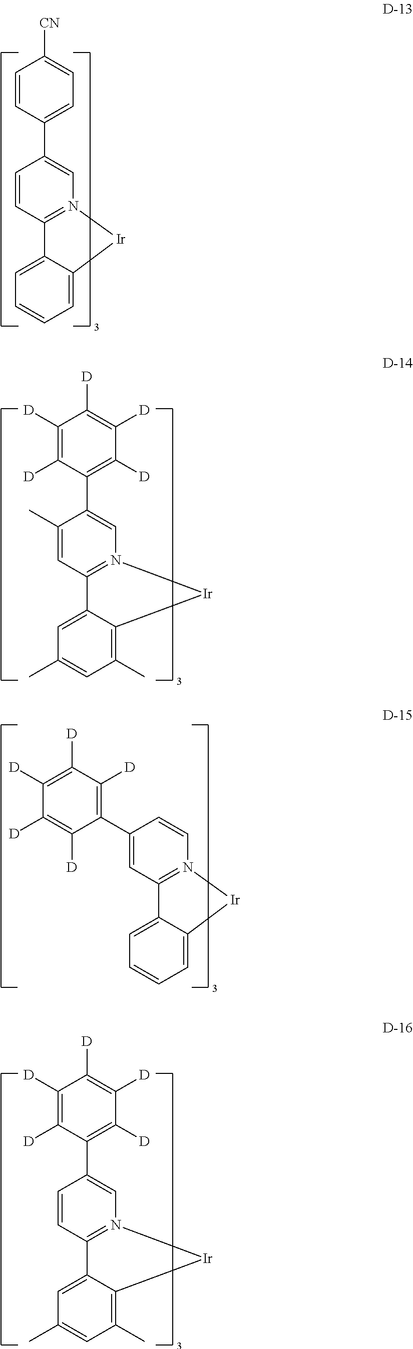

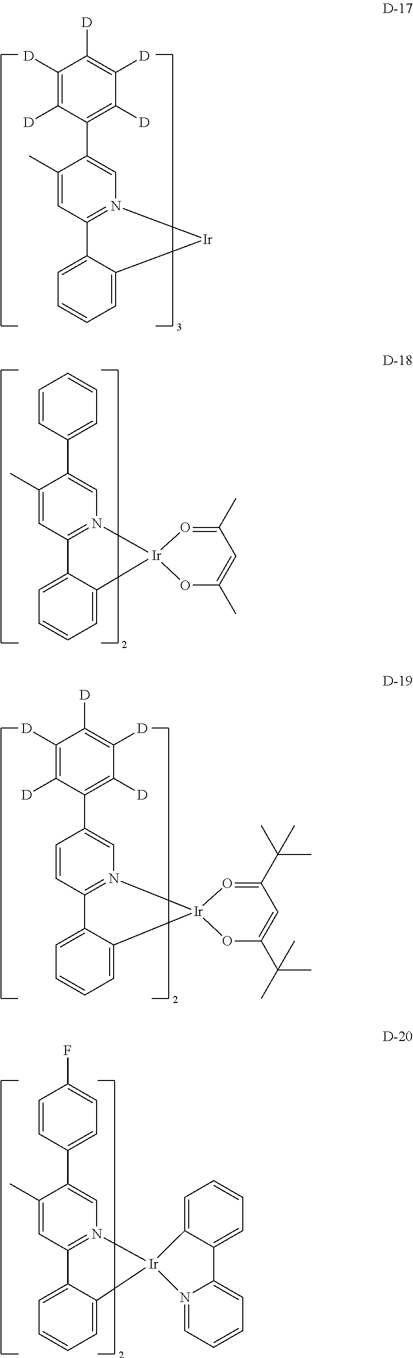

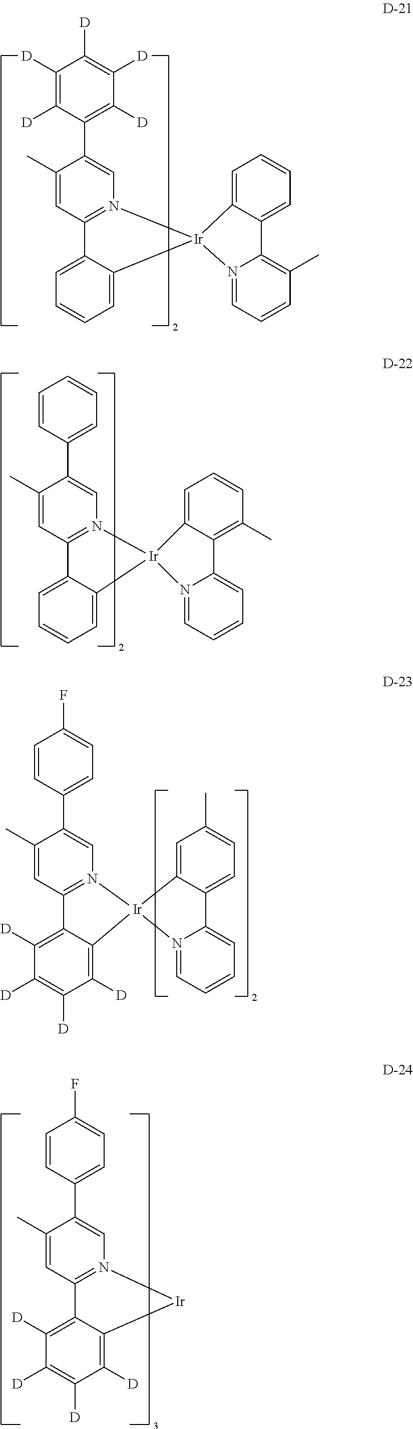

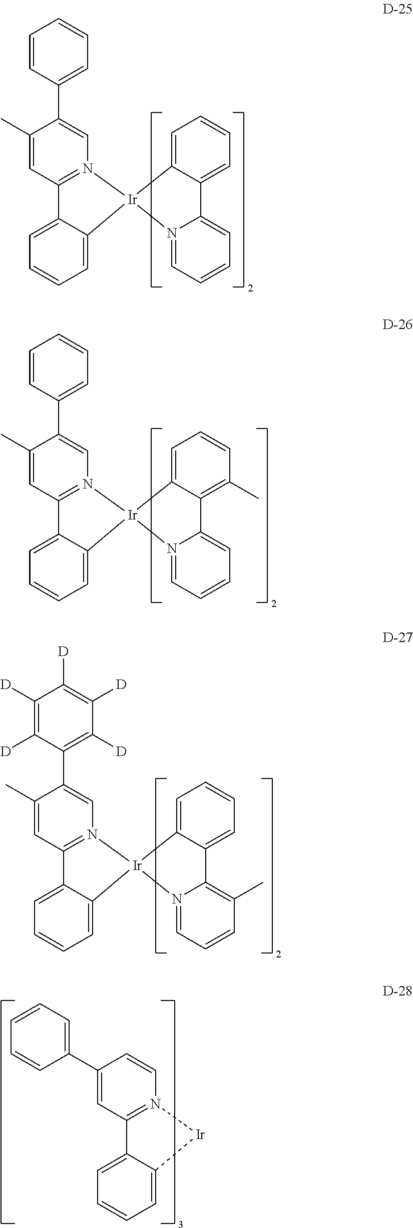

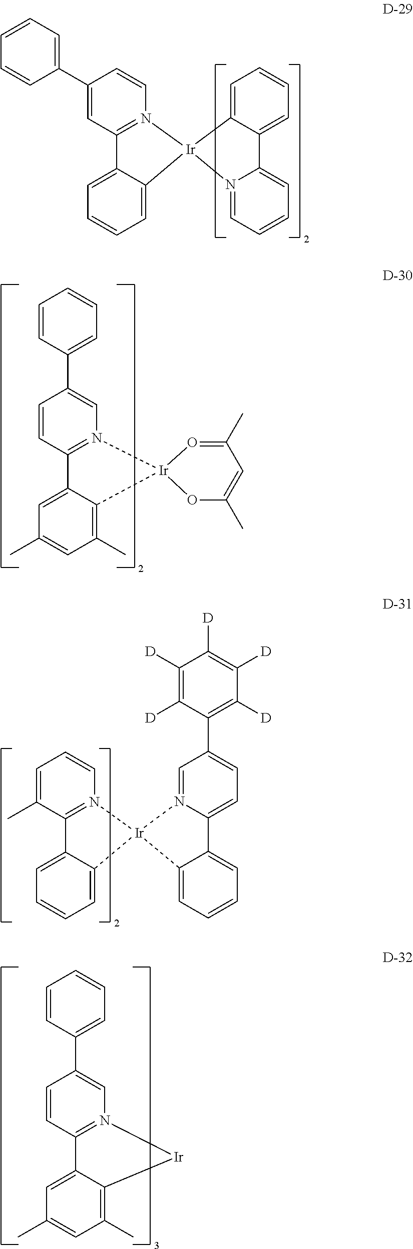

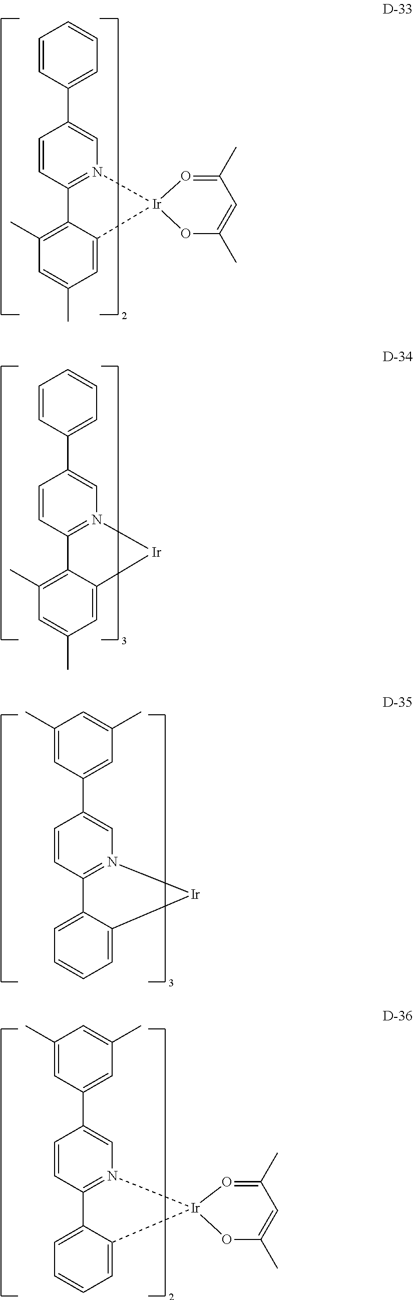

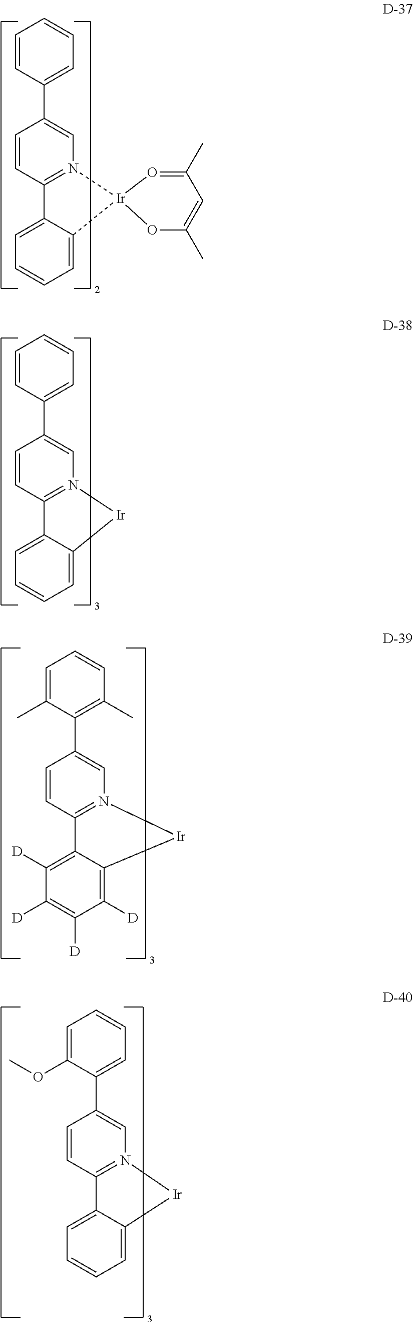

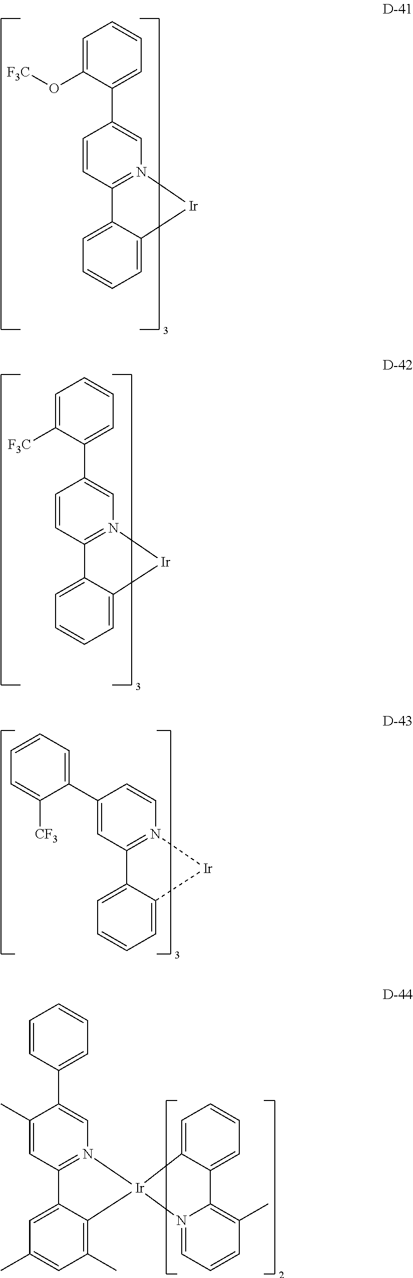

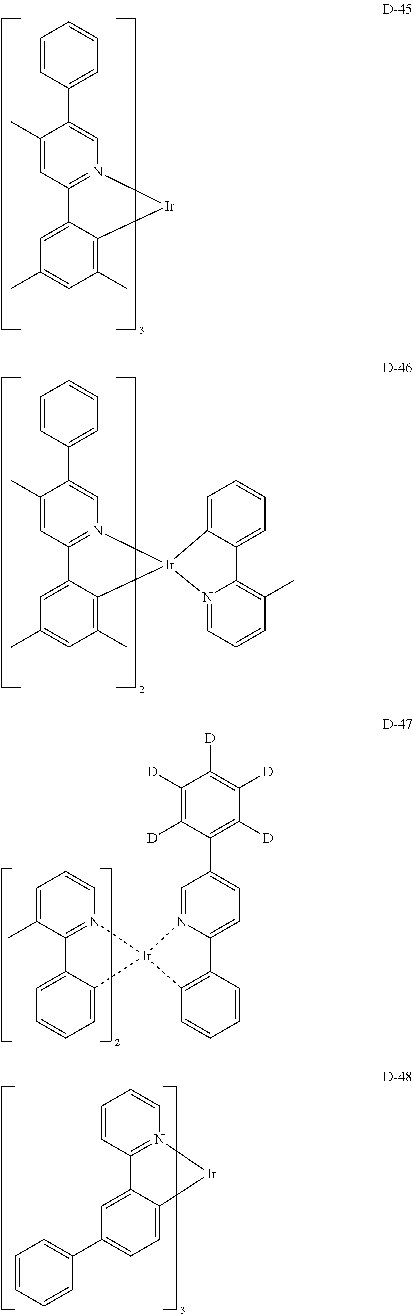

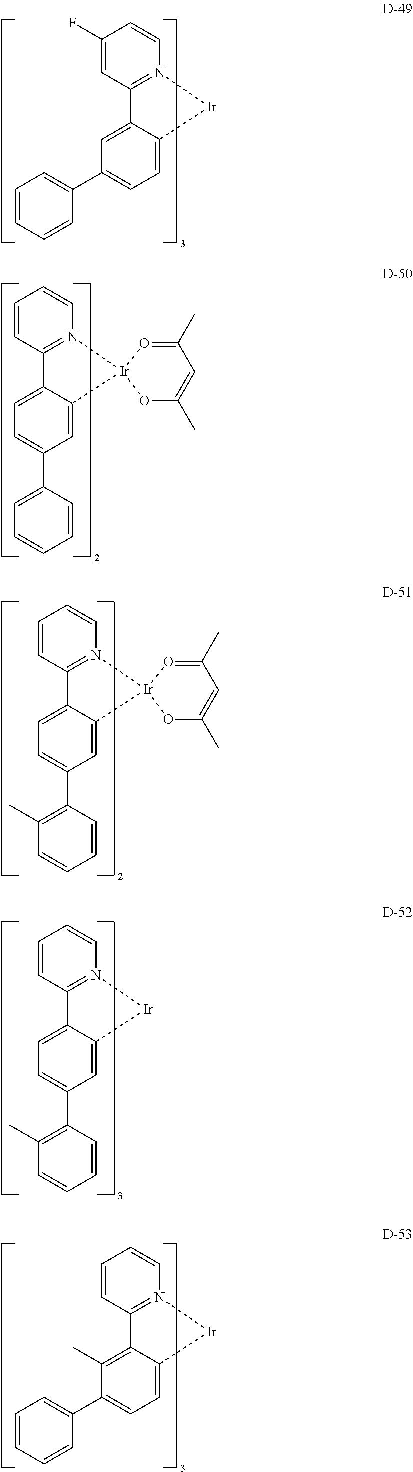

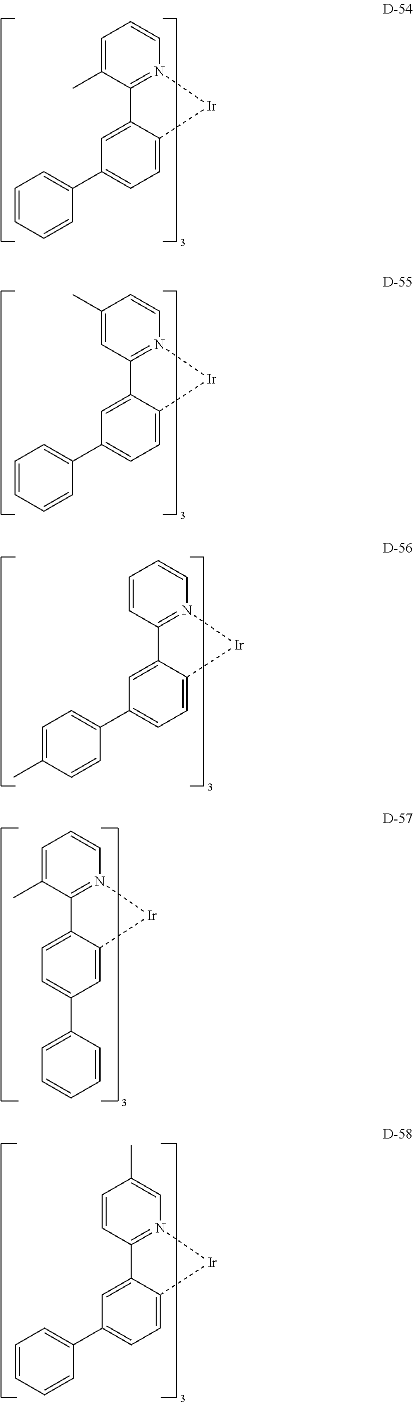

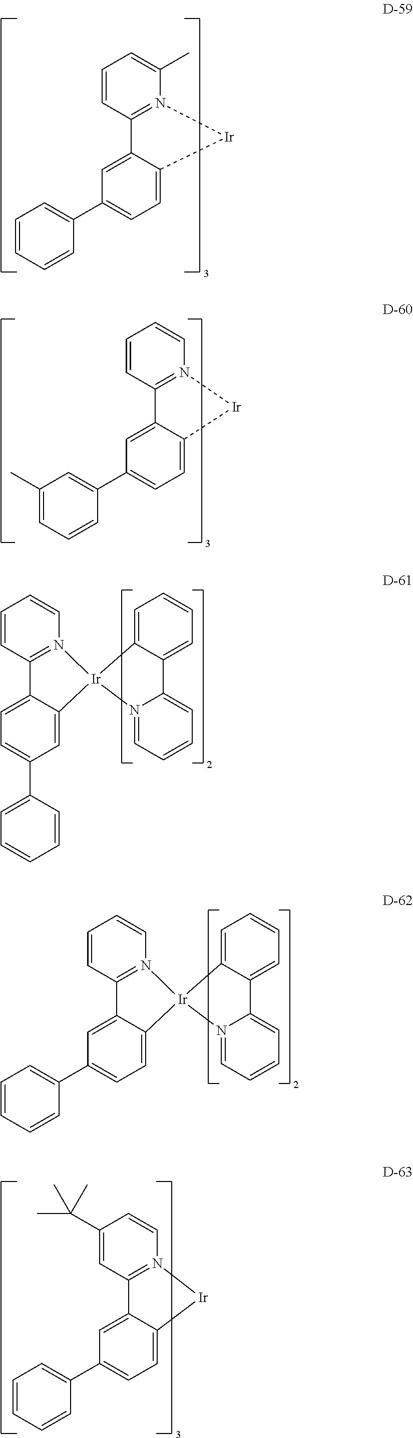

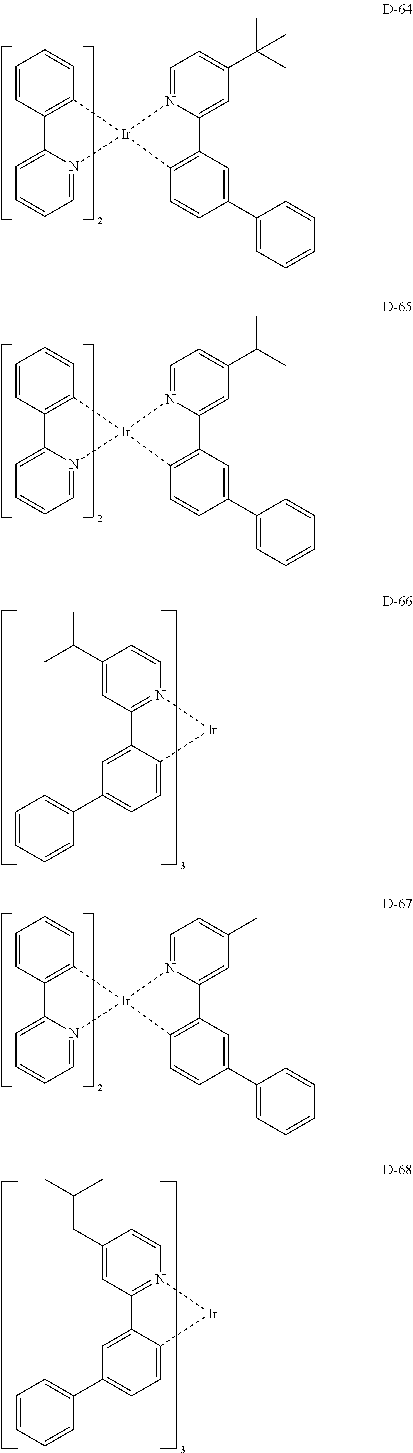

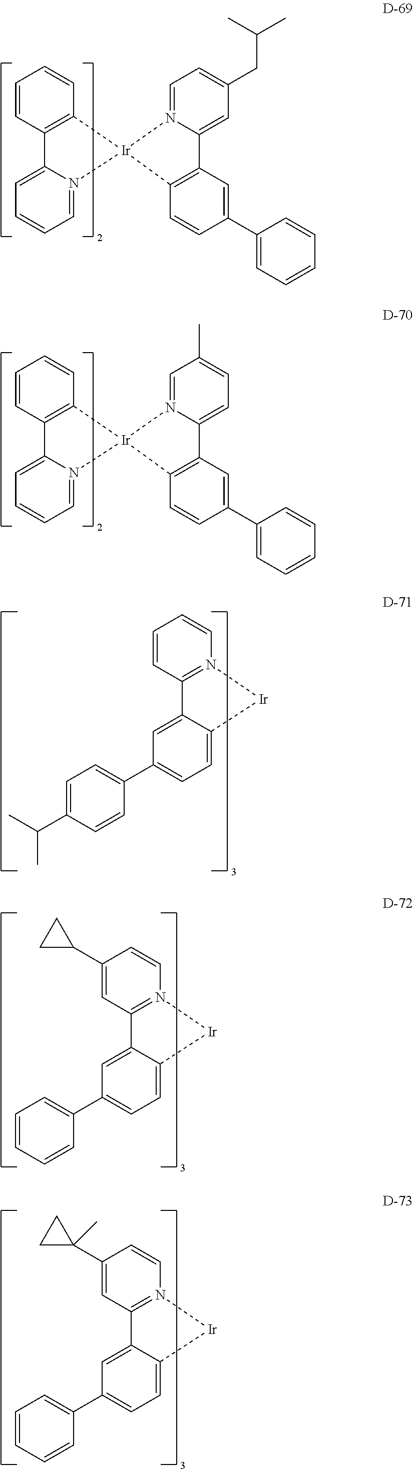

The present invention further provides the material for the organic electroluminescent device. The material comprises a first host material and a second host material; and the first host material may comprise the organic electroluminescent compounds of the present invention. The first host material and the second host material may be in the range of 1:99 to 99:1 in a weight ratio.

The second host material can be any of the known phosphorescent hosts, preferably phosphorescent hosts selected from the following formulae 12 and 13:

(Cz-L₃)ₑ-M (12)

(Cz)_{f}-L₃-M (13)

wherein

Cz represents the following structure:

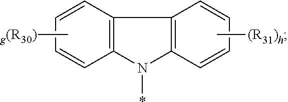

R₃₀ and R₃₁ each independently represent hydrogen, deuterium, a halogen, a substituted or unsubstituted (C1-C30)alkyl group, a substituted or unsubstituted (C6-C30)aryl group, a substituted or unsubstituted 5- or 30-membered heteroaryl group, or R₃₂R₃₃R₃₄Si—; R₃₂ to R₃₄ each independently represent a substituted or unsubstituted (C1-C30)alkyl group, or a substituted or unsubstituted (C6-C30)aryl group; each of R₃₀ or each of R₃₁ are the same or different; L₃ represents a chemical bond, a substituted or unsubstituted (C6-C30)arylene group, or a substituted or unsubstituted 5- or 30-membered heteroarylene group; M represents a substituted or unsubstituted (C6-C30)aryl group, or a substituted or unsubstituted 5- or 30-membered heteroaryl group; e to h each independently represent an integer of 0 to 4.

Specifically, the second host material includes the following (TPS means a triphenylsilane group):

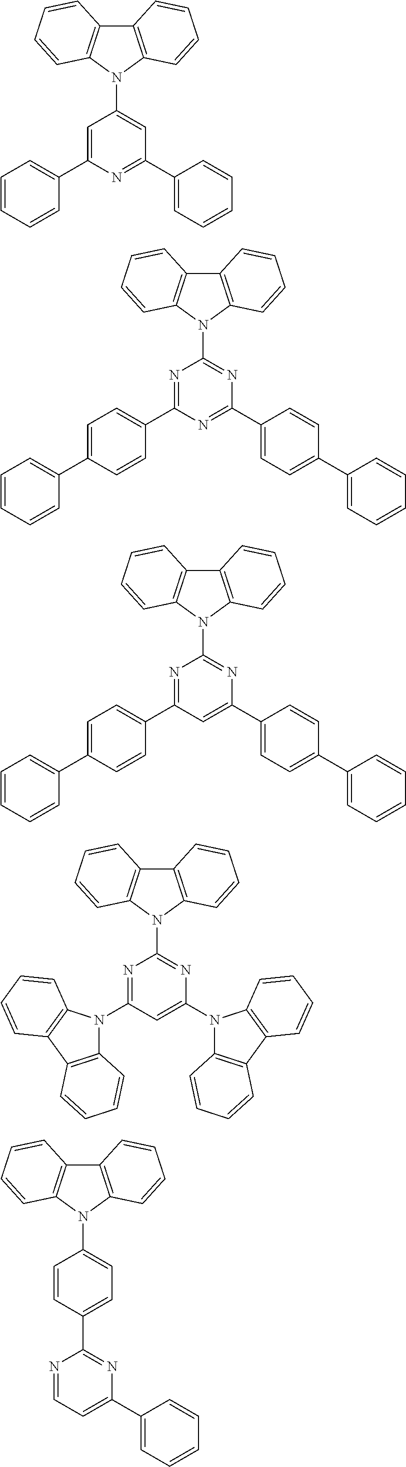

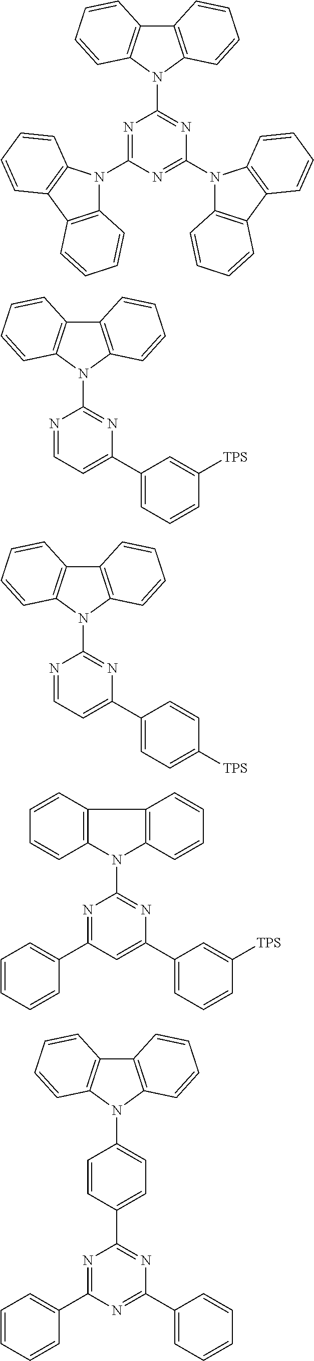

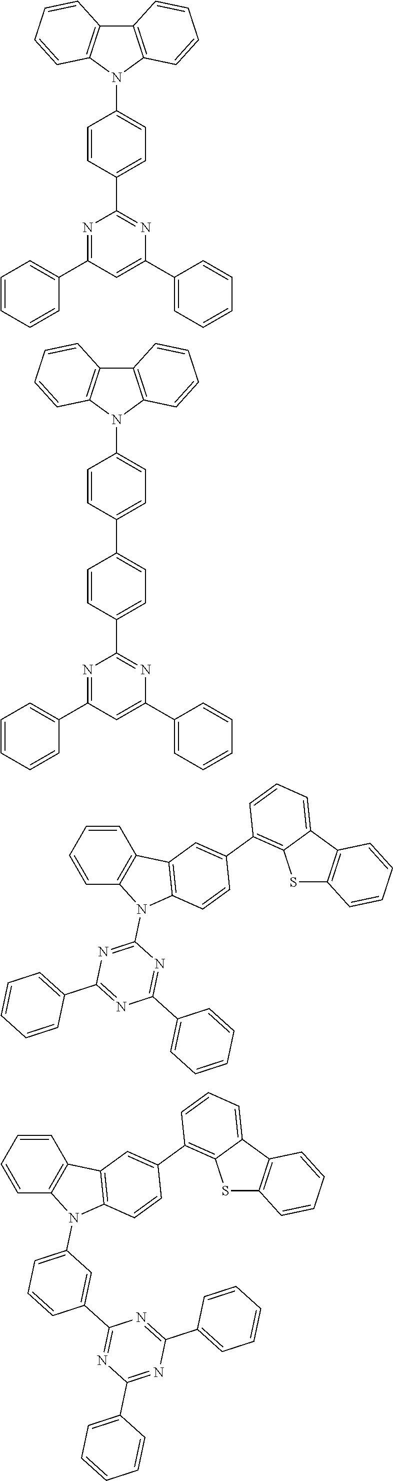

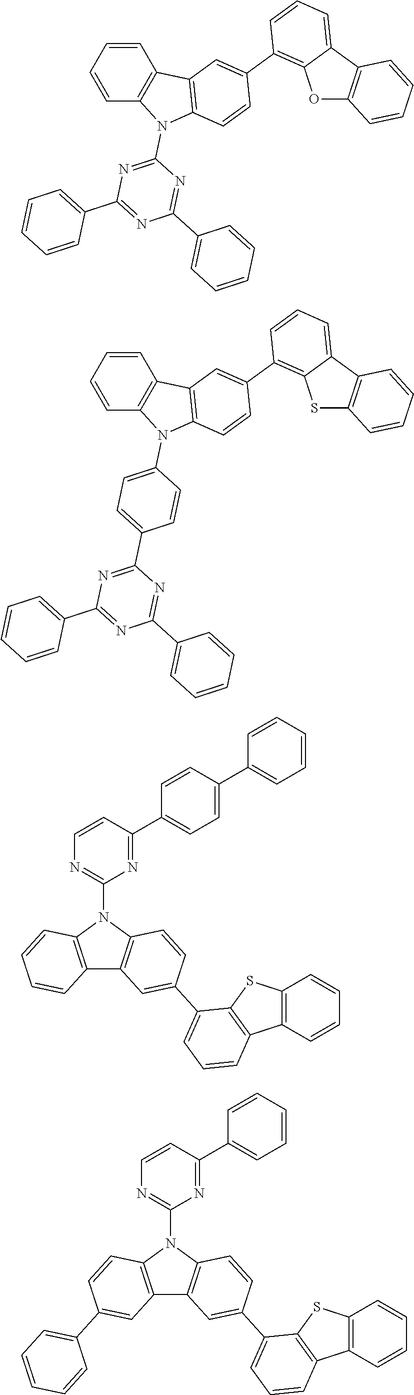

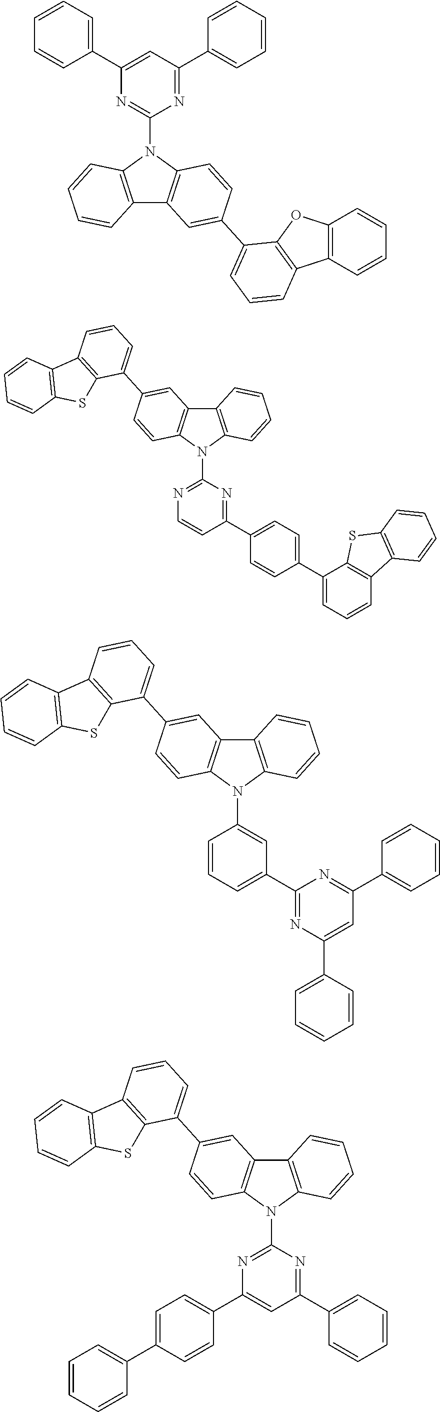 [SMILES: c1ccc(-c2cc(-c3ccccc3)nc(-n3c4ccccc4c4cc(-c5cccc6c5oc5ccccc56)ccc43)n2)cc1 ; c1ccc2c(c1)sc1c(-c3ccc(-c4ccnc(-n5c6ccccc6c6cc(-c7cccc8c7sc7ccccc78)ccc65)n4)cc3)cccc12 ; c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1]

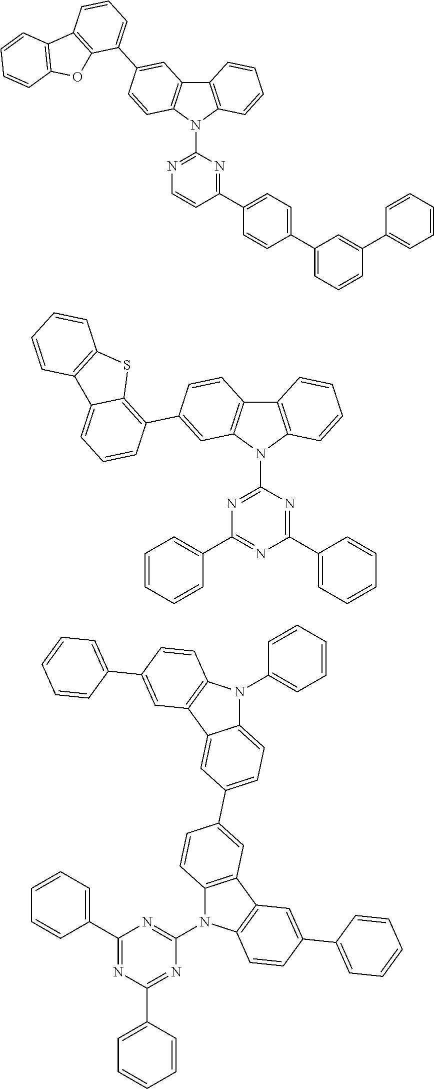

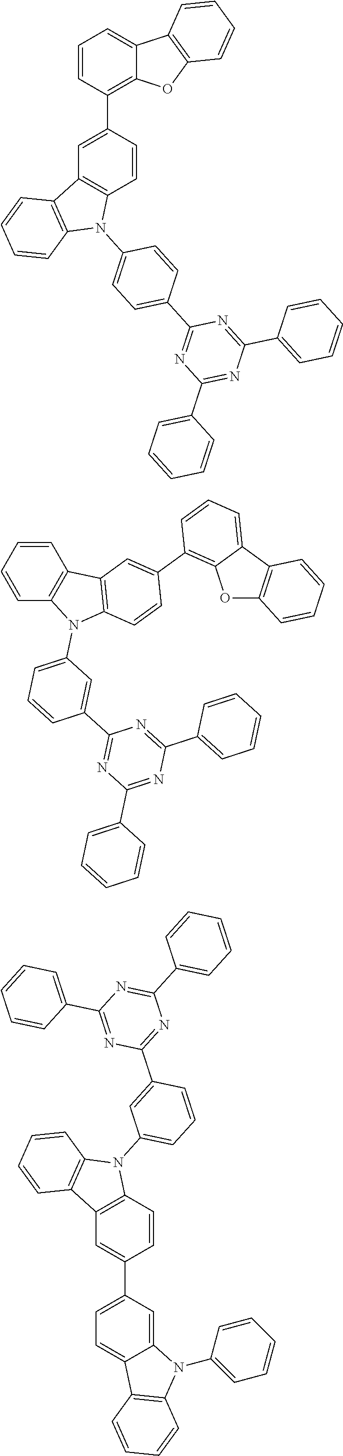

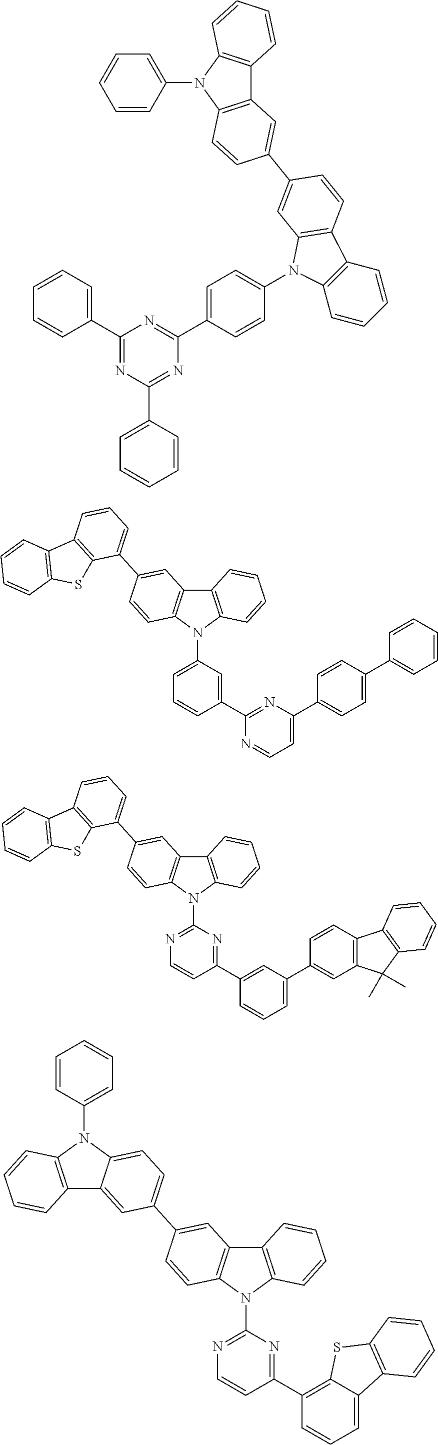

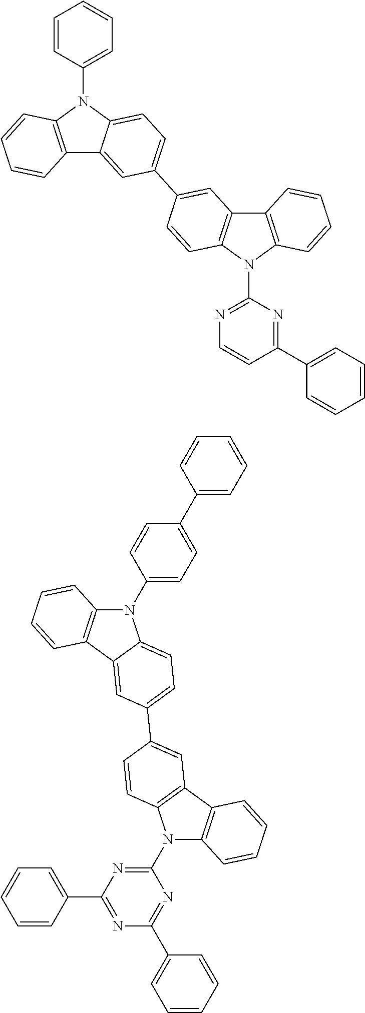 [SMILES: c1ccc(-c2ccnc(-n3c4ccccc4c4cc(-c5ccc6c(c5)c5ccccc5n6-c5ccccc5)ccc43)n2)cc1 ; c1ccc(-c2ccc(-n3c4ccccc4c4cc(-c5ccc6c(c5)c5ccccc5n6-c5nc(-c6ccccc6)nc(-c6ccccc6)n5)ccc43)cc2)cc1]

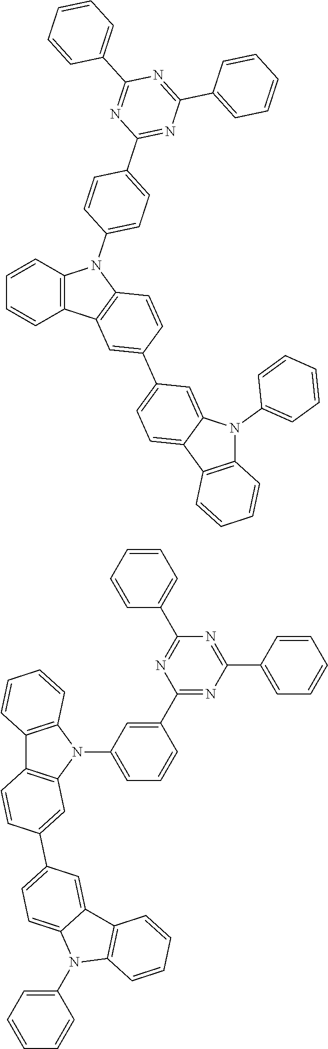 [SMILES: c1ccc(-c2nc(-c3ccccc3)nc(-c3ccc(-n4c5ccccc5c5cc(-c6ccc7c8ccccc8n(-c8ccccc8)c7c6)ccc54)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

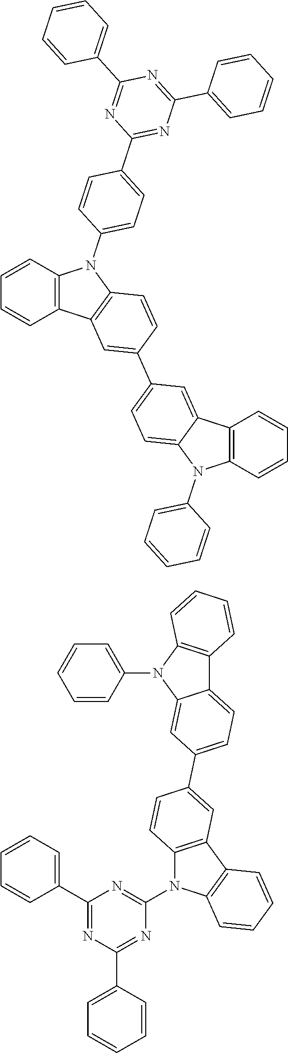

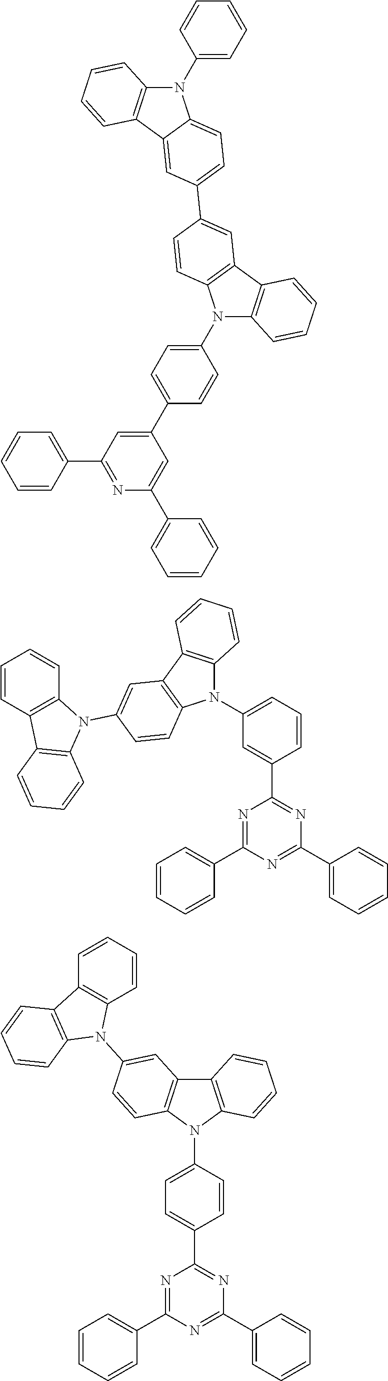

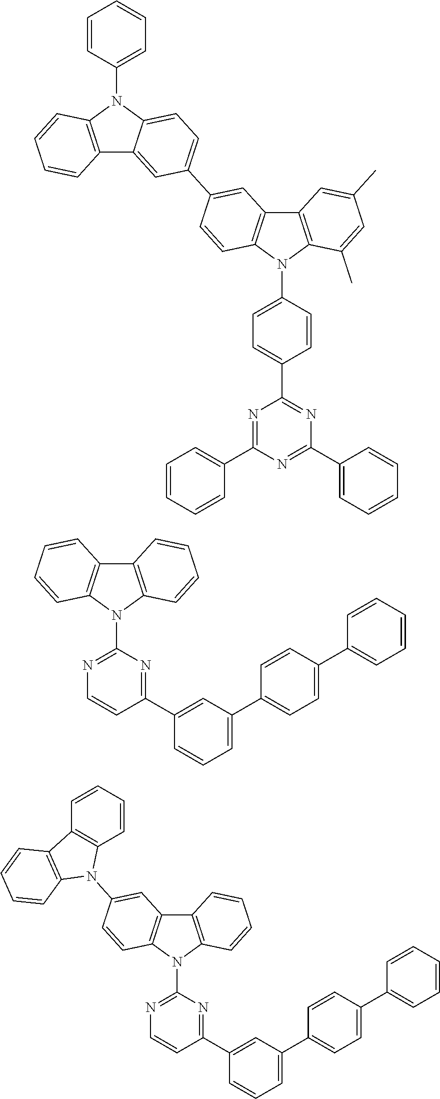

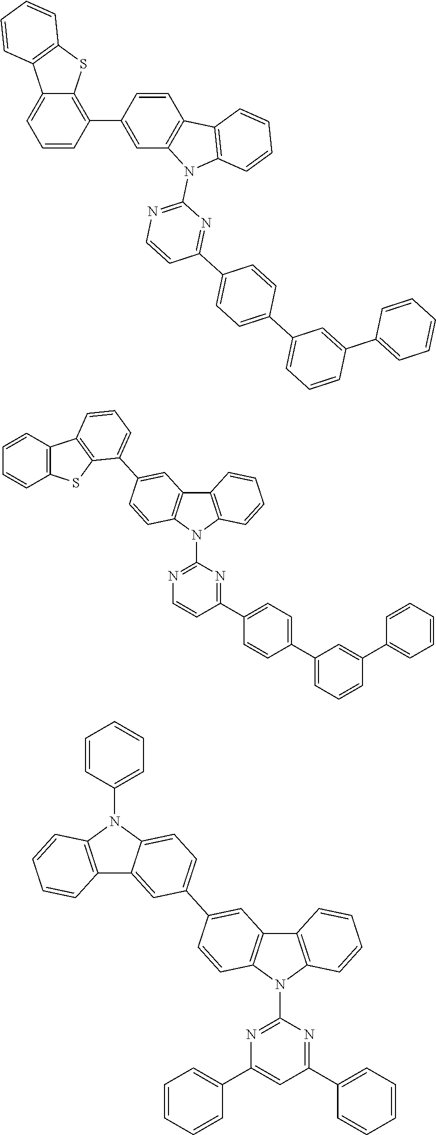 [SMILES: c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

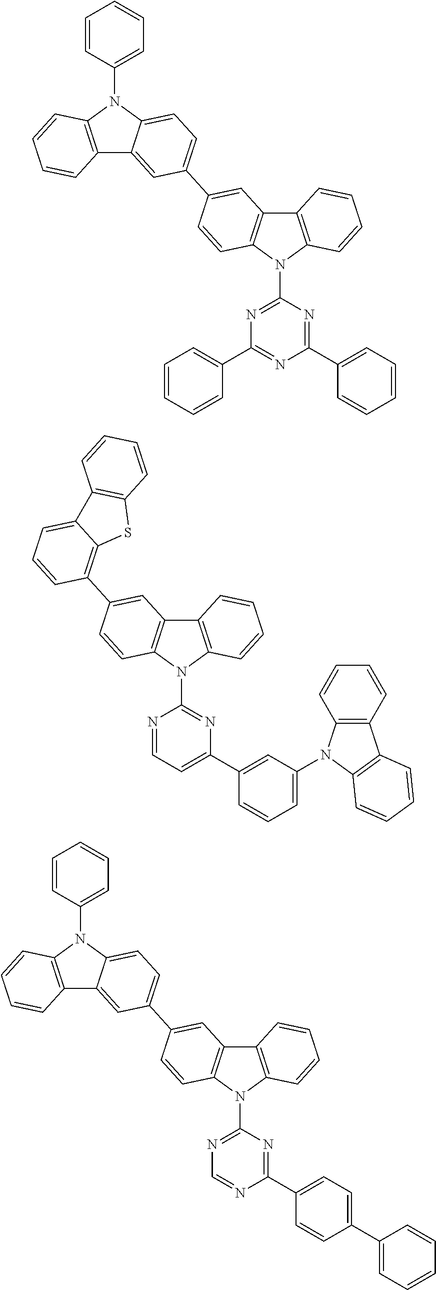 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1cc(-c2ccnc(-n3c4ccccc4c4cc(-c5cccc6c5sc5ccccc56)ccc43)n2)cc(-n2c3ccccc3c3ccccc32)c1 ; c1ccc(-c2ccc(-c3ncnc(-n4c5ccccc5c5cc(-c6ccc7c(c6)c6ccccc6n7-c6ccccc6)ccc54)n3)cc2)cc1]

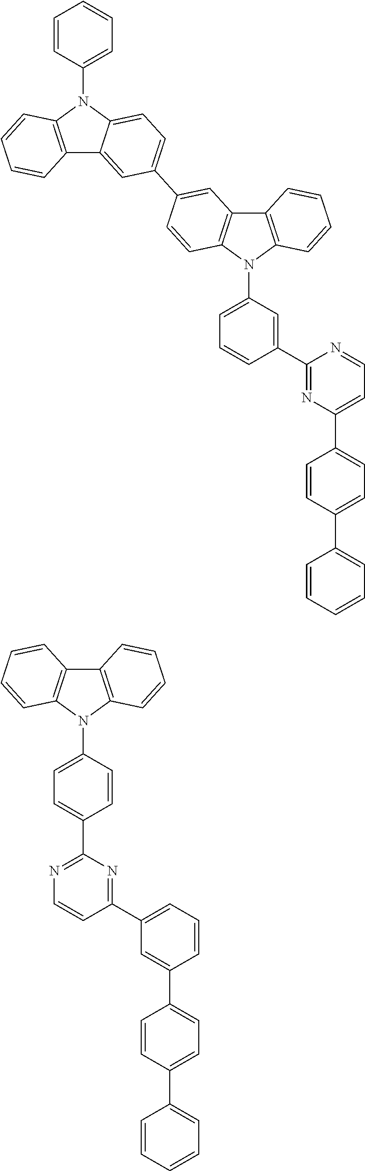 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1]

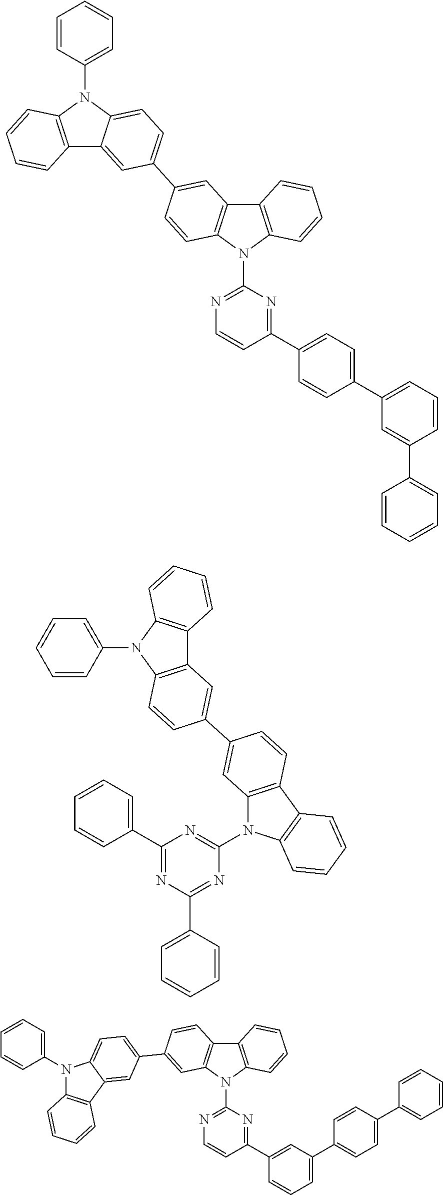

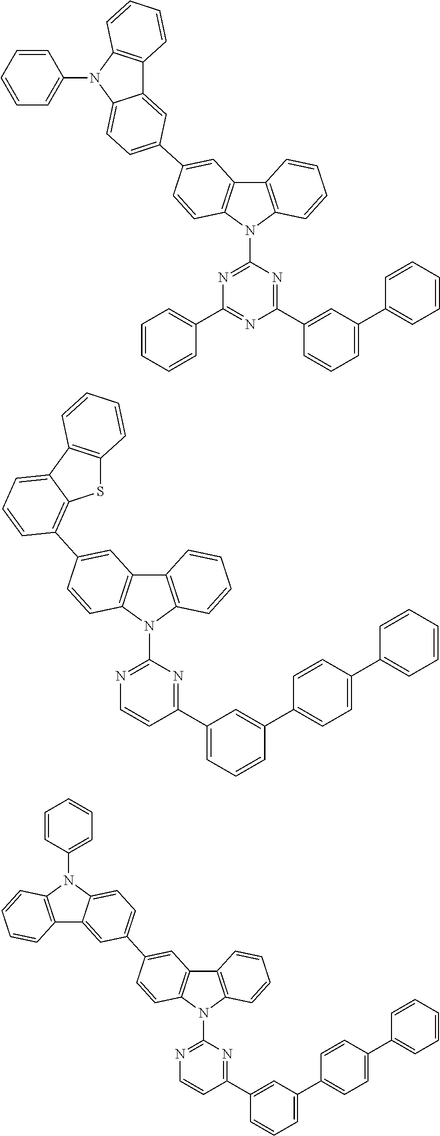 [SMILES: c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7cccc8c7sc7ccccc78)ccc65)n4)c3)cc2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

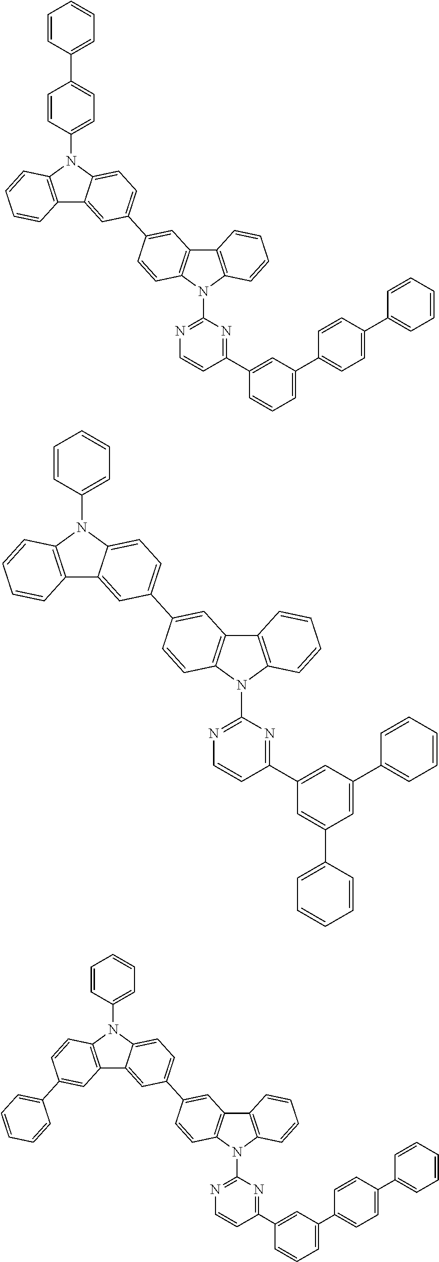 [SMILES: c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

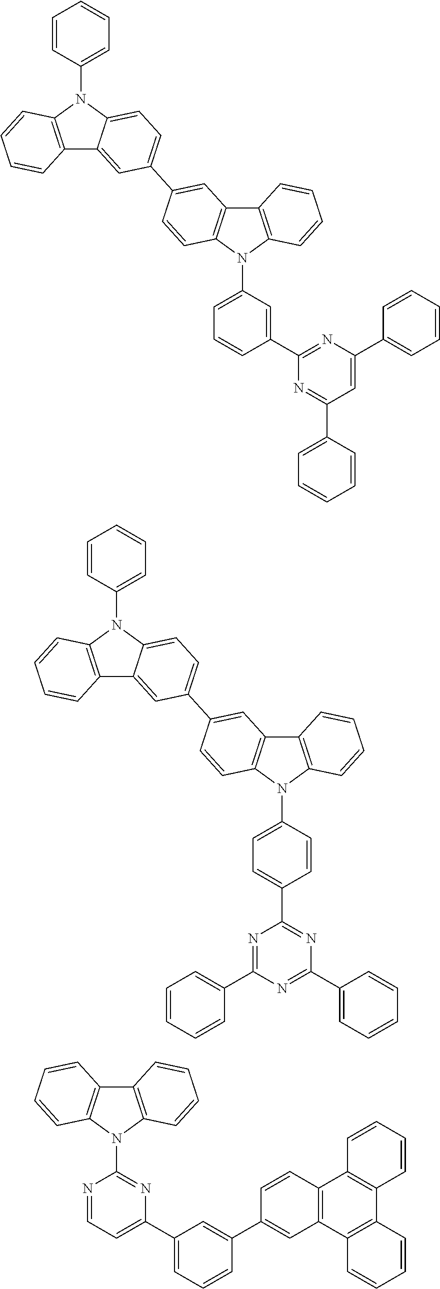

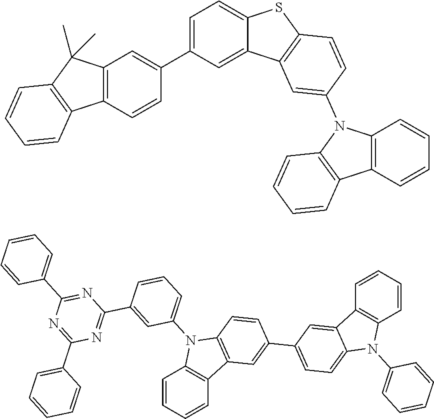 [SMILES: CC1(C)c2ccccc2-c2ccc(-c3ccc4sc5ccc(-n6c7ccccc7c7ccccc76)cc5c4c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

The organic electroluminescent device of the present invention may comprise a first electrode, a second electrode, and at least one organic layer between the first and second electrodes, wherein the organic layer comprises a light-emitting layer, the light-emitting layer comprises the organic electroluminescent material of the present invention and phosphorescent dopants, and the organic electroluminescent material is preferably used as a host material in the light-emitting layer.

The organic electroluminescent device according to the present invention may further comprise, in addition to the organic electroluminescent compounds represented by formula 1, at least one compound selected from the group consisting of arylamine-based compounds and styrylarylamine-based compounds in the organic layer.

In the organic electroluminescent device according to the present invention, the organic layer may further comprise, in addition to the organic electroluminescent compounds represented by formula 1, at least one metal selected from the group consisting of metals of Group 1, metals of Group 2, transition metals of the 4^{th} period, transition metals of the 5^{th} period, lanthanides, and organic metals of d-transition elements of the Periodic Table, or at least one complex compound comprising the metal.

In addition, the organic electroluminescent device of the present invention may emit white light by further comprising at least one light-emitting layer which comprises a blue electroluminescent compound, a red electroluminescent compound, or a green electroluminescent compound, besides the organic electroluminescent compound according to the present invention; and may further include a yellow or orange light-emitting layer, if necessary.

Preferably, in the organic electroluminescent device according to the present invention, at least one layer (hereinafter, “a surface layer”) selected from a chalcogenide layer, a metal halide layer and a metal oxide layer may be placed on an inner surface(s) of one or both electrode(s). Specifically, it is preferred that a chalcogenide (includes oxides) layer of silicon or aluminum is placed on an anode surface of an electroluminescent medium layer, and a metal halide layer or metal oxide layer is placed on a cathode surface of an electroluminescent medium layer. The surface layer provides operating stability for the organic electroluminescent device. Preferably, the chalcogenide includes SiOₓ(1≦X≦2), AlOₓ(1≦X≦1.5), SiON, SiAlON, etc.; the metal halide includes LiF, MgF₂, CaF₂, a rare earth metal fluoride, etc.; and the metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer constituting the organic electroluminescent device according to the present invention, dry film-forming methods, such as vacuum evaporation, sputtering, plasma, ion plating methods, etc., or wet film-forming methods, such as spin coating, dip coating, flow coating methods, etc., can be used.

When using a wet film-forming method, a thin film is formed by dissolving or dispersing the material constituting each layer in suitable solvents, such as ethanol, chloroform, tetrahydrofuran, dioxane, etc. The solvents are not specifically limited as long as the material constituting each layer is soluble or dispersible in the solvents, which do not cause any problems in forming a layer.

Hereinafter, the organic electroluminescent compound of the present invention, the preparation method of the compound, and the luminescent properties of the device comprising the compound will be explained in detail with reference to the following examples:

### EXAMPLE 1

### Preparation of Compound C-1

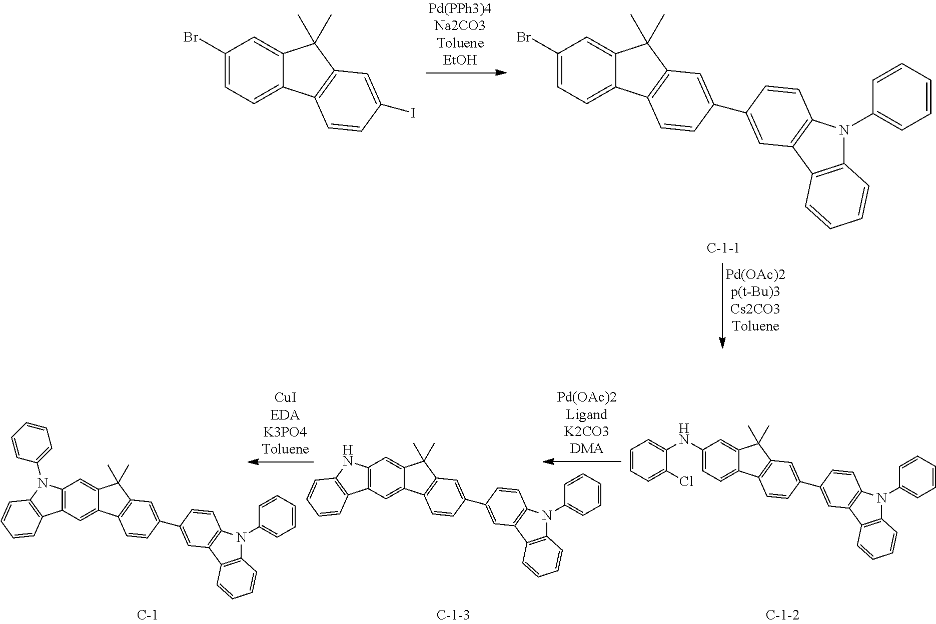

### Preparation of Compound C-1-1

After adding 2-bromo-7-iodo-9,9-dimethyl-9H-fluorene (25.0 g, 62.6 mmol), 9-phenyl-9H-carbazole-3-yl boronic acid (16.3 g, 56.9 mmol), tetrakis(triphenylphosphine)palladium(O) [Pd(PPh₃)₄] (3.6 g, 3.1 mmol), and Na₂CO₃ (19.9 g, 216.0 mmol) to a flask and dissolving the reaction mixture by adding toluene (400.0 ml), ethanol (EtOH) (100.0 ml), and distilled water (100.0 ml), the reaction mixture was stirred for 3 hours at 120° C. After reaction, the reaction was completed by slowly adding distilled water, the organic layer was extracted with ethylene acetate (EA). The obtained organic layer was dried with MgSO₄ to remove the remaining moisture, and was separated through column chromatography to obtain compound C-1-1 (27.5 g, 53.5 mmol, Yield: 84%).

### Preparation of Compound C-1-2

After adding compound C-1-1 (27.5 g, 53.5 mmol), 2-chloroaniline (11.2 ml, 106.9 mmol), palladium acetate (480.0 mg, 2.13 mmol), P(t-Bu)₃ (tri-t-butylphosphine) (1.0 ml, 6.2 mmol), and potassium-tert-butoxide (15.0 g, 133.6 mmol) to a flask and dissolving the reaction mixture by adding toluene (148.0 ml), the reaction mixture was refluxed for 24 hours at 120° C. After completing the reaction, the organic layer was extracted with EA. The obtained organic layer was dried with MgSO₄ to remove the remaining moisture, and was separated through column chromatography to obtain compound C-1-2 (14.5 g, 25.8 mmol, Yield: 48%).

### Preparation of Compound C-1-3

After adding compound C-1-2 (14.5 g, 25.8 mmol), palladium acetate (290.0 mg, 1.29 mmol), tri-t-butylphosphonium tetrafluoroborate (0.75 g, 2.58 mmol), and K₂CO₃ (10.7 g, 77.5 mmol) to a flask and dissolving the reaction mixture by adding dimethylacetamide (DMA) (143.0 ml), the reaction mixture was refluxed for 24 hours at 180° C. After completing the reaction, the organic layer was extracted with EA. The obtained organic layer was dried with MgSO₄ to remove the remaining moisture, and was separated through column chromatography to obtain compound C-1-3 (10.9 g, 20.7 mmol, Yield: 66%).

### Preparation of Compound C-1

After adding compound C-1-3 (9.9 g, 18.8 mmol), iodobenzene (3.2 ml, 28.3 mmol), CuI (1.8 g, 9.4 mmol), ethylenediamine (1.26 ml, 18.8 mmol) and K₃PO₄ (12.2 g, 56.6 mmol) to a flask and dissolving the reaction mixture by adding toluene (100.0 ml), the reaction mixture was refluxed for 24 hours at 120° C. After completing the reaction, the organic layer was extracted with EA. The obtained organic layer was dried with MgSO₄ to remove the remaining moisture, and was separated through column chromatography to obtain compound C-1 (6.2 g, 10.3 mmol, Yield: 55%).

### EXAMPLE 2

### Preparation of Compound C-22

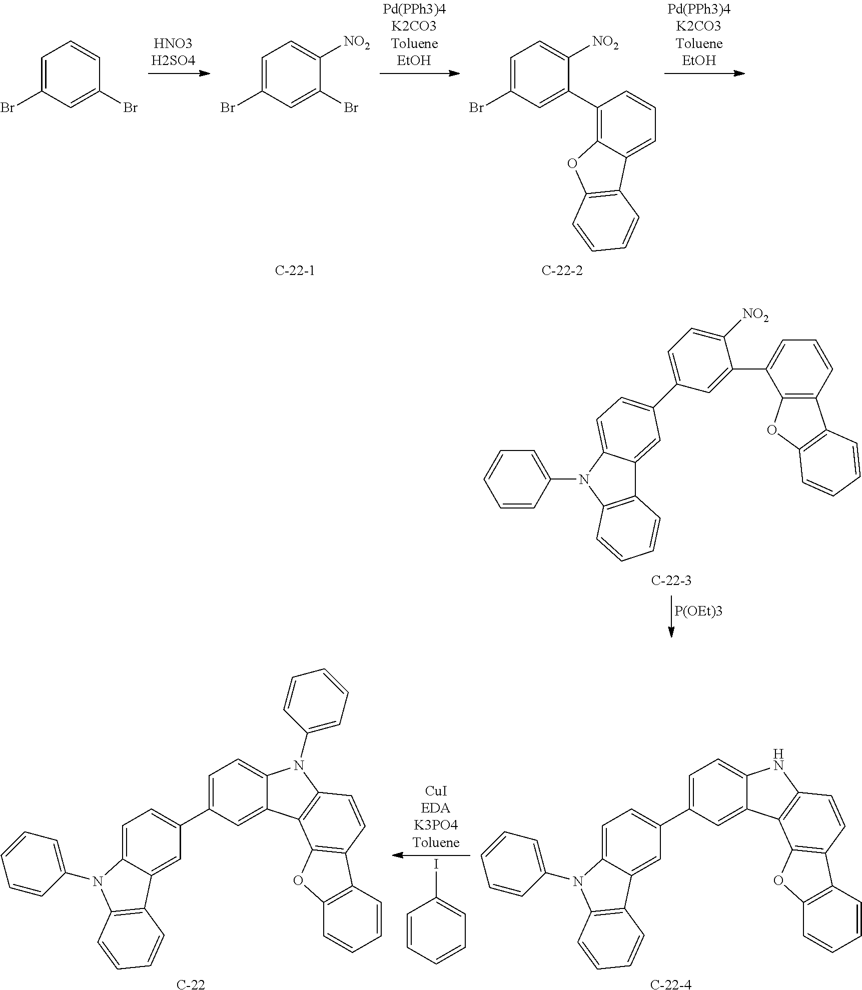

### Preparation of Compound C-22-1

1,3-dibromobenzene and sulfuric acid (250.0 ml) were added to a flask and the reaction mixture was cooled to an internal temperature of 0° C. Nitric acid (28.6 ml) was slowly added to the flask and the reaction mixture was stirred for 30 minute. After completing the reaction, the reaction mixture was added to ice water, and the obtained solid was filtered and rinsed with water. The solid was rinsed with NaOH to make a neutral solid. The solid was separated through column chromatography to obtain compound C-22-1 (60.0 g, 213.5 mmol, Yield: 50%).

### Preparation of Compound C-22-2

After adding compound C-22-1 (60.0 g, 213.5 mmol), dibenzo[b,d]thiophene-4-yl boronic acid (40.6 g, 177.9 mmol), Pd(PPh₃)₄ (8.2 g, 7.1 mmol), and Na₂CO₃ (56.6 g, 534.0 mmol) to a flask and dissolving the reaction mixture by adding toluene (520.0 ml), EtOH (260.0 ml), and distilled water (260.0 ml), the reaction mixture was stirred for 3 hours at 120° C. After reaction, the reaction was completed by slowly adding distilled water, the organic layer was extracted with EA. The obtained organic layer was dried with MgSO₄ to remove the remaining moisture, and was separated through column chromatography to obtain compound C-22-2 (42.0 g, 109.0 mmol, Yield: 51%).

### Preparation of Compound C-22-3

After adding compound C-22-2 (10.5 g, 29.8 mmol), 9-phenyl-9H-carbazole-3-yl boronic acid (10.3 g, 35.8 mmol), Pd(PPh₃)₄ (1.4 g, 1.2 mmol), and K₂CO₃ (12.3 g, 89.4 mmol) to a flask and dissolving the reaction mixture by adding toluene (100.0 ml), EtOH (45.0 ml), and distilled water (45.0 ml), the reaction mixture was stirred for 3 hours at 120° C. After reaction, the reaction was completed by slowly adding distilled water, the organic layer was extracted with EA. The obtained organic layer was dried with MgSO₄ to remove the remaining moisture, and was separated through column chromatography to obtain compound C-22-3 (8.5 g, 16.5 mmol, Yield: 55%).

### Preparation of Compound C-22-4

After adding compound C-22-3 (42.0 g, 109.0 mmol) to a flask and dissolving the reaction mixture by adding triethylphosphite (250.0 ml) and 1,2-dichlorobenzene (200.0 ml), the reaction mixture was stirred for 24 hours at 150° C. After completing the reaction, the remaining solvents were removed by a distillation apparatus, and the obtained organic layer was separated through column chromatography to obtain compound C-22-4 (10.5 g, 29.8 mmol, Yield: 27%).

### Preparation of Compound C-22

After adding compound C-22-4 (8.5 g, 16.5 mmol), iodobenzene (3.7 ml, 33.0 mmol), CuI (1.6 g, 8.2 mmol), ethylenediamine (1.1 ml, 16.5 mmol) and K₃PO₄ (10.5 g, 49.5 mmol) to a flask and dissolving the reaction mixture by adding toluene (100.0 ml), the reaction mixture was refluxed for 24 hours at 120° C. After completing the reaction, the organic layer was extracted with EA. The obtained organic layer was dried with MgSO₄ to remove the remaining moisture, and was separated through column chromatography to obtain compound C-22 (4.5 g, 7.6 mmol, Yield: 46%).

### EXAMPLE 3

### Preparation of Compound C-26

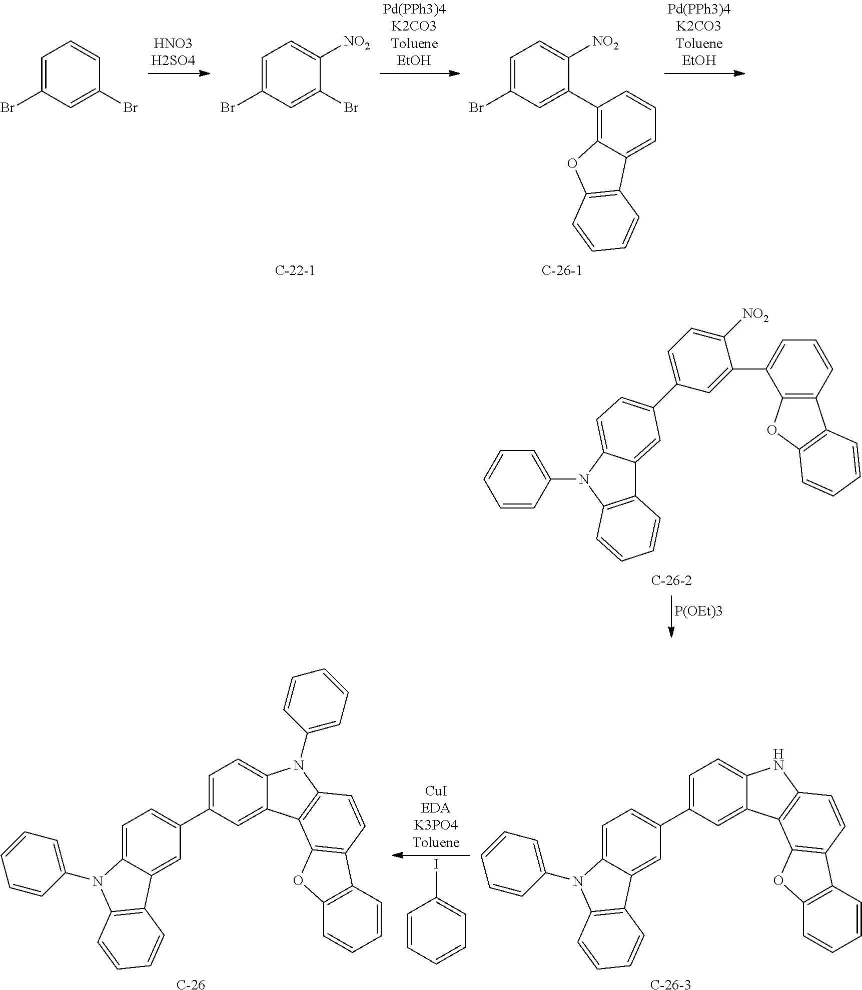

### Preparation of Compound C-26-1

After adding compound C-22-1 (60.0 g, 213.5 mmol), dibenzo[b,d]furan-4-yl boronic acid (37.7 g, 177.9 mmol), Pd(PPh₃)₄ (10.2 g, 8.8 mmol), and Na₂CO₃ (56.6 g, 534.0 mmol) to a flask and dissolving the reaction mixture by adding toluene (520.0 ml), EtOH (260.0 ml), and distilled water (260.0 ml), the reaction mixture was stirred for 3 hours at 120° C. After reaction, the reaction was completed by slowly adding distilled water, the organic layer was extracted with EA. The obtained organic layer was dried with MgSO₄ to remove the remaining moisture, and was separated through column chromatography to obtain compound C-26-1 (42.0 g, 114.0 mmol, Yield: 54%).

### Preparation of Compound C-26-2

After adding compound C-26-1 (10.0 g, 29.7 mmol), 9-phenyl-9H-carbazole-3-yl boronic acid (10.2 g, 35.7 mmol), Pd(PPh₃)₄ (1.4 g, 1.2 mmol), and K₂CO₃ (12.3 g, 89.4 mmol) to a flask and dissolving the reaction mixture by adding toluene (100.0 ml), EtOH (45.0 ml), and distilled water (45.0 ml), the reaction mixture was stirred for 3 hours at 120° C. After reaction, the reaction was completed by slowly adding distilled water, the organic layer was extracted with EA. The obtained organic layer was dried with MgSO₄ to remove the remaining moisture, and was separated through column chromatography to obtain compound C-26-2 (8.0 g, 16.0 mmol, Yield: 54%).

### Preparation of Compound C-26-3

After adding compound C-26-2 (42.0 g, 114.0 mmol) to a flask and dissolving the reaction mixture by adding triethylphosphite (250.0 ml) and 1,2-dichlorobenzene (200.0 ml), the reaction mixture was stirred for 24 hours at 150° C. After completing the reaction, the remaining solvents were removed by a distillation apparatus, and the obtained organic layer was separated through column chromatography to obtain compound C-26-3 (10.5 g, 29.7 mmol, Yield: 26%).

### Preparation of Compound C-26

After adding compound C-26-3 (8.0 g, 16.0 mmol), iodobenzene (3.6 ml, 32.0 mmol), CuI (1.5 g, 8.0 mmol), ethylenediamine (1.1 ml, 16.0 mmol) and K₃PO₄ (10.2 g, 48.1 mmol) to a flask and dissolving the reaction mixture by adding toluene (100.0 ml), the reaction mixture was refluxed for 24 hours at 120° C. After completing the reaction, the organic layer was extracted EA and was dried with MgSO₄ to remove the remaining moisture. The obtained organic layer was separated through column chromatography to obtain compound C-26 (4.5 g, 7.8 mmol, Yield: 49%).

### EXAMPLE 4

### Preparation of Compound C-12

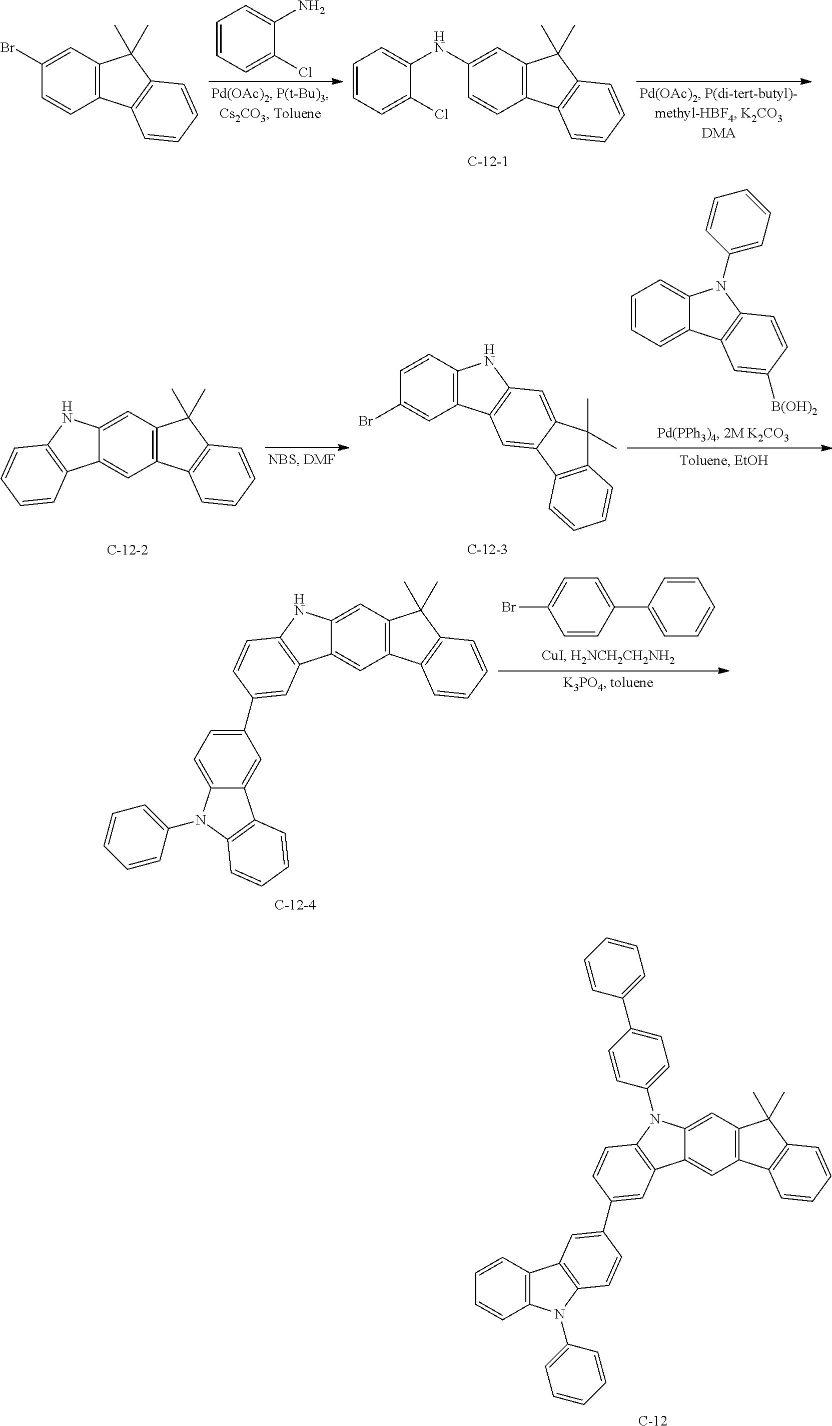

### Preparation of Compound C-12-1

Toluene (600.0 ml) was added to 2-bromo-9,9-dimethylfluorene (56.0 g, 0.20 mol), 2-chloroaniline (31.0 g, 0.24 mol), palladium acetate (1.5 g, 0.001 mol), P(t-Bu)₃ (4.0 ml, 0.021 mol), and Cs₂CO₃ (143.0 g, 0.439 mol). The mixture was stirred for 12 hours at 120° C. After completing the reaction, the mixture was rinsed with distilled water and the organic layer was extracted with EA. After drying the obtained organic layer with MgSO₄, the remaining solvents were removed by using a rotary evaporator. The obtained organic layer was purified through column chromatography to obtain compound C-12-1 (65.0 g, Yield: 92%).

### Preparation of Compound C-12-2

DMA (1000.0 ml) was added to compound C-12-1 (65.0 g, 0.20 mol), palladium acetate (2.3 g, 0.01 mol), di-tert-butyl(methyl)phosphonium tetrafluoroborate (5.9 g, 0.02 mol), and Na₂CO₃ (64.0 g, 0.60 mol). The mixture was stirred for 16 hours at 190° C. After completing the reaction, the mixture was rinsed with distilled water and the organic layer was extracted with EA.

After drying the obtained organic layer with MgSO₄, the remaining solvents were removed by using a rotary evaporator. The obtained organic layer was purified through column chromatography to obtain compound C-12-2 (31.0 g, Yield: 54%).

### Preparation of Compound C-12-3

Compound C-12-2 (10.0 g, 0.035 mol) and dimethylformamide (DMF) (500.0 ml) were added to a two-neck round bottom flask (2 L) and the reaction mixture was stirred for 10 minutes at 0° C. After adding N-bromosuccinic imide (NBS) (6.0 g, 0.03 mol) to DMF (350.0 ml), the solution was slowly added to the flask, and the mixture was stirred for 6 hours at 0° C. After completing the reaction, the mixture was neutralized by adding distilled water, and the organic layer was extracted with EA. After drying the obtained organic layer with MgSO₄, the remaining solvents were removed by using a rotary evaporator. The obtained organic layer was purified through column chromatography with EA as a developing solvent to obtain compound C-12-3 (10.0 g, Yield: 78%).

### Preparation of Compound C-12-4

Compound C-12-3 (11.2 g, 31.0 mmol), 9-phenylcarbazole-3-boronic acid (11.0 g, 35.7 mmol), Pd(PPh₃)₄ (1.8 g, 1.6 mmol), K₂CO₃ (11.0 g, 78.0 mmol), toluene (120.0 ml), ethanol (40.0 ml), and distilled water (40.0 ml) to a round bottom flask (500 ml). The reaction mixture was stirred for 12 hours at 120° C. After completing the reaction, the mixture was rinsed with distilled water, and the organic layer was extracted with EA. After drying the obtained organic layer with MgSO₄, the remaining solvents were removed by using a rotary evaporator. The obtained organic layer was purified through column chromatography to obtain compound C-12-4 (13.6 g, Yield: 84%).

### Preparation of Compound C-12

After adding compound C-12-4 (6.0 g, 11.4 mmol), 4-bromobiphenyl (2.9 g, 12.5 mmol), CuI (1.0 g, 5.7 mmol), ethylenediamine (1.5 ml, 23.0 mmol), K₃PO₄ (6.0 g, 29.0 mmol), and toluene (60.0 ml) to a round bottom flask (250 ml), the reaction mixture was heated to 120° C. and was stirred for 12 hours. After completing the reaction, the mixture was rinsed with distilled water, and the organic layer was extracted with EA. After drying the obtained organic layer with MgSO₄, the remaining solvents were removed by using a rotary evaporator. The obtained organic layer was purified through column chromatography to obtain compound C-12 (5.0 g, Yield: 65%).

### EXAMPLE 5

### Preparation of Compound C-10

After adding compound C-12-4 (8.8 g, 16.7 mmol), iodobenzene (2.8 ml, 25.1 mmol), CuI (1.6 g, 8.3 mmol), ethylenediamine (1.1 ml, 16.7 mmol) and K₃PO₄ (11.0 g, 50.3 mmol) to a flask and dissolving the reaction mixture by adding toluene (100.0 ml), the reaction mixture was stirred for 24 hours at 120° C. After completing the reaction, the organic layer was extracted EA and was dried with MgSO₄ to remove the remaining moisture. The obtained organic layer was separated through column chromatography to obtain compound C-10 (6.0 g, 9.9 mmol, Yield: 60%).

### EXAMPLE 6

### Preparation of Compound C-13

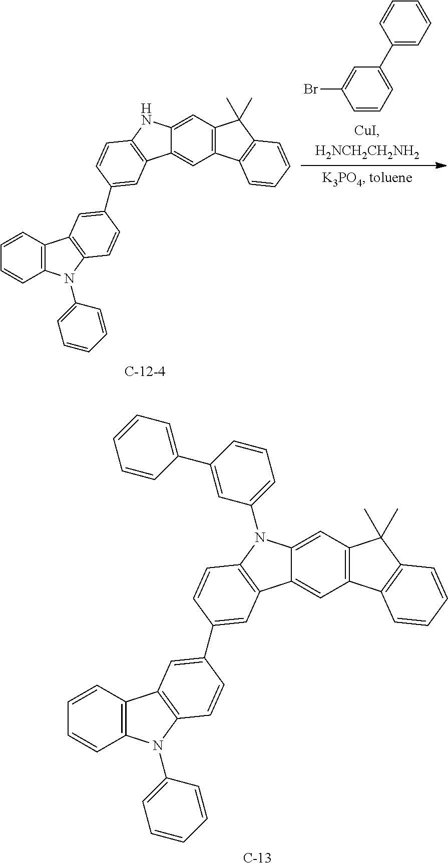

After adding compound C-12-4 (7.0 g, 13.3 mmol), 3-bromobiphenyl (3.1 g, 13.3 mmol), CuI (1.3 g, 6.7 mmol), ethylenediamine (2.0 ml, 26.6 mmol), K₃PO₄ (7.0 g, 33.0 mmol), and toluene (70.0 ml) to a round bottom flask (250 ml), the reaction mixture was heated to 120° C. and was stirred for 12 hours. After completing the reaction, the mixture was rinsed with distilled water, and the organic layer was extracted with EA. After drying the obtained organic layer with MgSO₄, the remaining solvents were removed by using a rotary evaporator. The obtained organic layer was purified through column chromatography to obtain compound C-13 (6.4 g, Yield: 71%).

### EXAMPLE 7

### Preparation of Compound C-24

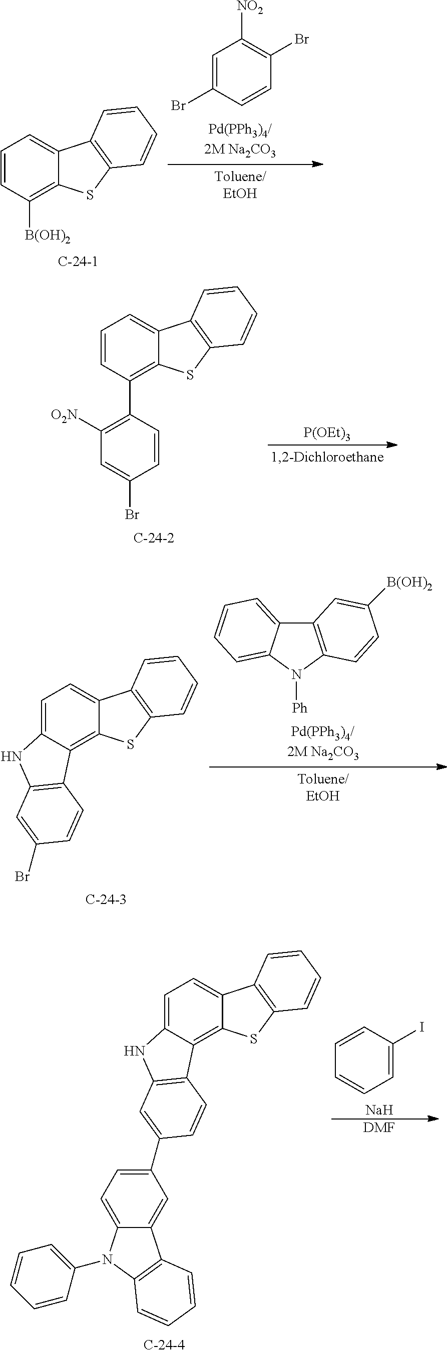

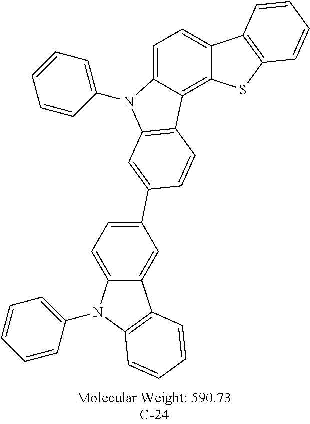 [SMILES: c1ccc(-n2c3ccccc3c3cc(-c4ccc5c6c7sc8ccccc8c7ccc6n(-c6ccccc6)c5c4)ccc32)cc1]

### Preparation of Compound C-24-2

Compound C-24-1 (29.0 g, 128.0 mmol), Pd(PPh₃)₄ (4.9 g, 4.3 mmol), Na₂CO₃ (28.0 g, 267.0 mmol), toluene (450.0 ml), ethanol (150.0 ml), and distilled water (150.0 ml) were added to a round bottom flask (2 L) and the reaction mixture was stirred for 1.5 hours at 120° C. The reaction mixture was extracted with EA/distilled water, and the obtained organic layer was dried with MgSO₄ to remove the remaining moisture and was distilled under the reduced pressure. The crude product was purified through column chromatography with methylene chloride (MC) and hexane as developing solvents to obtain compound C-24-2 as a yellow solid (34.0 g, Yield: 70%).

### Preparation of Compound C-24-3

Compound C-24-2 (34.0 g, 88.5 mmol), P(OEt)₃ (250.0 ml), and 1,2-dichlorobenzene (250.0 ml) were added to a round bottom flask (2 L) and the reaction mixture was stirred for 3.5 hours at 150° C. The reaction mixture was separated by distillation and was extracted with EA/distilled water. The obtained organic layer was dried with MgSO₄ to remove the remaining moisture and was distilled under the reduced pressure. The crude product was purified through column chromatography with MC and hexane as developing solvents to obtain compound C-24-3 as a white solid (14.6 g, Yield: 47%).

### Preparation of Compound C-24-4

Compound C-24-3 (6.0 g, 17.0 mmol), 9-phenyl-9H-carbazole-3-yl boronic acid (6.4 g, 22.0 mmol), Pd(PPh₃)₄ (984.0 mg, 0.85 mmol), K₂CO₃ (5.9 g, 43.0 mmol), toluene (80.0 ml), ethanol (20.0 ml), and distilled water (20.0 ml) were added to a round bottom flask (500 ml) and the reaction mixture was stirred for 4 hours at 120° C. The reaction mixture was extracted with EA/distilled water. The obtained organic layer was dried with MgSO₄ to remove the remaining moisture and was distilled under the reduced pressure. The crude product was filtered on silica with chloroform to obtain compound C-24-4 as a white solid (5.0 g, Yield: 57%).

### Preparation of Compound C-24

Compound C-24-4 (4.4 g, 8.5 mmol), iodobenzene (4.36 g, 21.4 mmol), CuI (814.0 mg, 4.3 mmol), K₃PO₄ (5.4 g, 25.6 mmol), ethylenediamine (1.2 ml, 17.0 mmol), and toluene (45.0 ml) were added to a round bottom flask (250 ml) and the reaction mixture was stirred for 6 hours at 120° C. The reaction mixture was extracted with EA/distilled water. The obtained organic layer was dried with MgSO₄ to remove the remaining moisture and was distilled under the reduced pressure. The crude product was purified through column chromatography with MC and hexane as developing solvents and was recrystallized with DMF to obtain compound C-24 as a white solid (1.0 g, Yield: 20%).

### EXAMPLE 8

### Preparation of Compound C-11

3-(4-bromophenyl)-9-phenyl-9H-carbazole (3.2 g, 8.0 mmol), 7,7-dimethyl-5-phenyl-5,7-dihydroindeno[2,1-b]carbazole-2-yl boronic acid (3.9 g, 11.0 mmol), Pd(PPh₃)₄ (464.0 mg, 0.40 mmol), K₂CO₃(3.3 g, 243.0 mmol), toluene (24.0 ml), ethanol (12.0 ml), and distilled water (12.0 ml) were added to a round bottom flask (500 ml) and the reaction mixture was stirred for 4 hours at 120° C. The reaction mixture was extracted with EA/distilled water. The obtained organic layer was dried with MgSO₄ to remove the remaining moisture and was distilled under the reduced pressure. The crude product was filtered on silica with chloroform to obtain compound C-11 as a white solid (2.2 g, Yield: 41%).

The physical properties of the compounds of the present invention, which were prepared in Examples 1 to 8, are provided in the table 1 below:

TABLE 1

| Compound | Yield | MS/EIMS | | UV | | |
|---|---|---|---|---|---|---|
| Nos. | (%) | Found | Calculated | (nm) | PL (nm) | mp (° C.) |
| C-1 | 55% | 599.61 | 600.75 | 344 nm | 387 nm | 265 |
| C-10 | 60% | 599.74 | 600.75 | 342 nm | 406 nm | 176 |
| C-11 | 41% | 676.32 | 676.84 | 394 nm | 322 nm | 270 |
| C-12 | 65% | 676.65 | 676.84 | 322 nm | 409 nm | 319 |
| C-13 | 70% | 676.92. | 676.84 | 308 nm | 407 nm | 194 |
| C-22 | 46% | 589.97 | 590.73 | 334 nm | 389 nm | 226 |
| C-24 | 20% | 589.51 | 590.73 | 308 nm | 393 nm | 229 |
| C-26 | 48% | 573.95 | 574.67 | 356 nm | 386 nm | 203 |

### Device Example 1

### Production of an OLED Device Using the Organic Electroluminescent Compound According to the Present Invention

An OLED device was produced using the organic electroluminescent compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol, and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalene-1-yl)-N⁴,N⁴-diphenylbenzene-1,4-diamine) was introduced into a cell of the vacuum vapor depositing apparatus, and then the pressure in the chamber of the apparatus was controlled to 10⁻⁶ torr. Thereafter, an electric current was applied to the cell to evaporate the above introduced material, thereby forming a hole injection layer having a thickness of 60 nm on the ITO substrate. Then, compound C-1 according to the present invention was introduced into another cell of the vacuum vapor depositing apparatus, and was evaporated by applying electric current to the cell, thereby forming a hole transport layer having a thickness of 20 nm on the hole injection layer. Thereafter, 9-(3-(4,6-diphenyl-1,3,5-triazine-2-yl)phenyl)-9′-phenyl-9H,9H′-3,3′-bicarbazole as a host was introduced into one cell of the vacuum vapor depositing apparatus, and tris(4-methyl-2,5-diphenylpyridine)iridium (D-5) as a dopant was introduced into another cell. The two materials were evaporated at different rates and deposited in a doping amount of 15 wt % of the dopant, based on the total weight of the host and dopant, to form a light-emitting layer having a thickness of 30 nm on the hole transport layer. Then, 2-(4-(9,10-di(naphthalene-2-yl)anthracen-2-yl)phenyl)-1-phenyl-1H-benzo[d]imidazole was introduced into one cell and lithium quinolate (Liq) was introduced into another cell. The two materials were evaporated at the same rate and were respectively deposited in a doping amount of 50 wt % to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed green emission having a luminance of 5050 cd/m² and a current density of 12.5 mA/cm².

### Device Example 2

### Production of an OLED Device Using the Organic Electroluminescent Compound According to the Present Invention

An OLED device was produced in the same manner as in Device Example 1, except for using compound C-10 as the hole transport layer, 9-phenyl-10-(4-phenylnaphthalene-1-yl)anthracene as a host, and (E)-9,9-dimethyl-7-(4-(naphthalene-2-yl(phenyl)amino)styryl)-N,N-diphenyl-9H-fluorene-2-amine as a dopant.

The produced OLED device showed blue emission having a luminance of 2050 cd/m² and a current density of 28.5 mA/cm².

### Device Example 3

### Production of an OLED Device Using the Organic Electroluminescent Compound According to the Present Invention

An OLED device was produced in the same manner as in Device Example 1, except for using compound C-11 as the hole transport layer.

The produced OLED device showed green emission having a luminance of 4000 cd/m² and a current density of 7.4 mA/cm².

### Device Example 4

### Production of an OLED Device Using the Organic Electroluminescent Compound According to the Present Invention

An OLED device was produced in the same manner as in Device Example 1, except for using compound C-12 as the hole transport layer.

The produced OLED device showed green emission having a luminance of 7000 cd/m² and a current density of 13.5 mA/cm².

### Device Example 5

### Production of an OLED Device Using the Organic Electroluminescent Compound According to the Present Invention

An OLED device was produced in the same manner as in Device Example 1, except for using compound C-22 as the hole transport layer.

The produced OLED device showed blue emission having a luminance of 3000 cd/m² and a current density of 41.1 mA/cm².

### Device Example 6

### Production of an OLED Device Using the Organic Electroluminescent Compound According to the Present Invention

An OLED device was produced in the same manner as in Device Example 1, except for using compound C-26 as the hole transport layer.

The produced OLED device showed green emission having a luminance of 2000 cd/m² and a current density of 3.7 mA/cm².

### Device Example 7

### Production of an OLED Device Using the Organic Electroluminescent Compound According to the Present Invention

An OLED device was produced in the same manner as in Device Example 1, except for using compound C-24 as the hole transport layer.

The produced OLED device showed green emission having a luminance of 2000 cd/m² and a current density of 5.5 mA/cm².

### Device Example 8

### Production of an OLED Device Using the Organic Electroluminescent Compound According to the Present Invention

An OLED device was produced in the same manner as in Device Example 1, except for using compound C-13 as the hole transport layer.

The produced OLED device showed green emission having a luminance of 5520 cd/m² and a current density of 10.5 mA/cm².

### Comparative Example 1

### Production of an OLED Device Using Conventional Electroluminescent Compounds

An OLED device was produced in the same manner as in Device Example 1, except that a hole transport layer having a thickness of 20 nm was deposited by using N,N′-di(4-biphenyl)-N,N′-di(4-biphenyl)-4,4′-diaminobiphenyl, a light-emitting layer having a thickness of 30 nm was deposited on the hole transport layer by using 4,4′-N,N′-dicarbazole-biphenyl as a host and tris(2-phenylpyridine)iridium (D-4) as a dopant, and a hole blocking layer having a thickness of 10 nm was deposited by using bis(2-methyl-8-quinolinato)(4-phenylphenolato)aluminum(III).

The produced OLED device showed green emission having a luminance of 4080 cd/m² and a current density of 12.0 mA/cm².

### Comparative Example 2

### Production of an OLED Device Using Conventional Electroluminescent Compounds

An OLED device was produced in the same manner as in Device Example 1, except that a hole transport layer having a thickness of 20 nm was deposited by using N,N′-di(4-biphenyl)-N,N′-di(4-biphenyl)-4,4′-diaminobiphenyl, a light-emitting layer having a thickness of 30 nm was deposited on the hole transport layer by using 9-phenyl-10-(4-phenylnaphthalene-1-yl)anthracene as a host and (E)-9,9-dimethyl-7-(4-(naphthalene-2-yl(phenyl)amino)styryl)-N,N-diphenyl-9H-fluorene-2-amine as a dopant.

The produced OLED device showed blue emission having a luminance of 1010 cd/m² and a current density of 16.8 mA/cm².

The organic electroluminescent compounds of the present invention have luminous characteristics superior to the conventional materials.

1. An organic electroluminescent compound represented by the following formula 1: 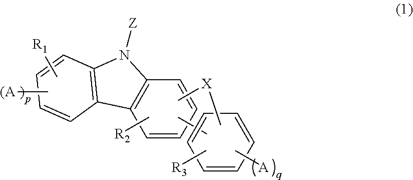
wherein
A is represented by the following formula 2: 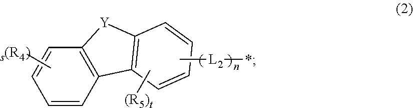
formula 2 is bonded to the compound of formula 1 via *;
Z is represented by the following formula 3:
*-(L₁)ₘ-Ar₁ (3);
formula 3 is bonded to the compound of formula 1 via *;
L₁ and L₂ each independently represent a single bond, a substituted or unsubstituted 5-to 30-membered heteroarylene group, or a substituted or unsubstituted (C6-C30)arylene group;
X and Y each independently represent —O—, —S—, —N(R₆)—, —C(R₇)(R₈)—, or —Si(R₉)(R₁₀)—;
Ar₁ and R₁ to R₅ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₁₁R₁₂, or —SiR₁₃R₁₄R₁₅; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur, proviso that where q is 1, R₁ is not the group of formula 2, and p is 1, R₃ is not the group of formula 2;
R₆ to R₁₅ each independently represent hydrogen, deuterium, a halogen, a substituted or unsubstituted (C1-C30)alkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring;
m and n each independently represent an integer of 0 to 2; where m is 2, each of L₁ is the same or different, and n is 2, each of L₂ is the same or different;
p and q each independently represent an integer of 0 or 1; where p+q=1;
s and t each independently represent an integer of 1 or 2; where s is 2, each of R₄ is the same or different, and t is 2, each of R₅ is the same or different; and
the heteroaryl(ene) group contains at least one hetero atom selected from B, N, O, S, P(═O), Si and P.

2. The organic electroluminescent compound according to claim 1, wherein the compound is one selected from the group consisting of the following formulae 4 to 9: 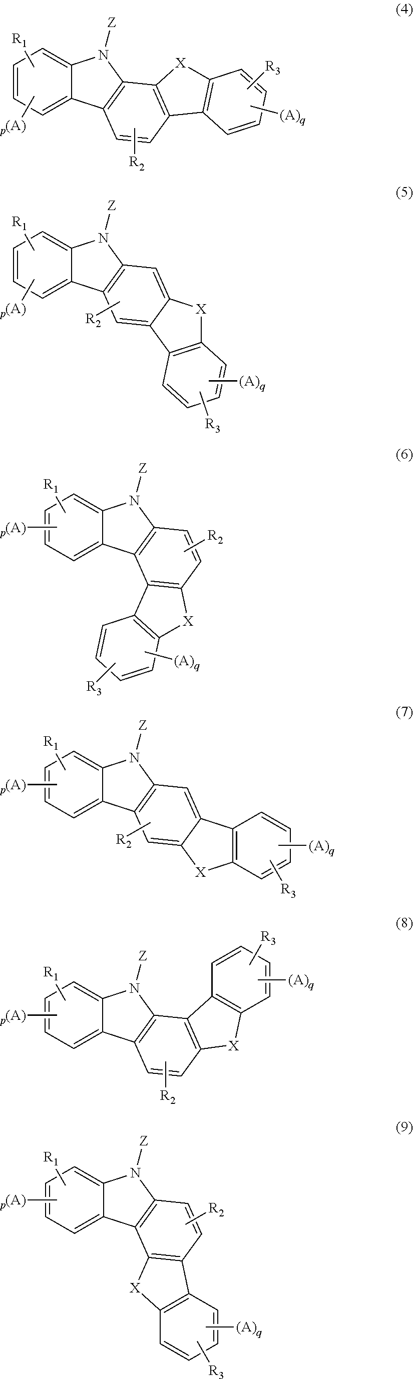
wherein
A, Z, X, R₁ to R₃, p and q are as defined in claim 1.

3. The organic electroluminescent compound according to claim 1, wherein the substituents of the substituted alkyl group, the substituted aryl(ene) group, and the substituted heteroaryl(ene) group in L₁, L₂, Ar₁, and R₁ to R₁₅ each independently are at least one selected from the group consisting of deuterium; a halogen; a cyano group; a carboxyl group; a nitro group; a hydroxyl group; a (C1-C30)alkyl group; a halo(C1-C30)alkyl group; a (C6-C30)aryl group; a 5- to 30-membered heteroaryl group; a 5- to 30-membered heteroaryl group substituted with a (C6-C30)aryl; a (C6-C30)aryl group substituted with a 5- to 30-membered heteroaryl; a (C3-C30)cycloalkyl group; a 3- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; and a (C1-C30)alkyl(C6-C30)aryl group.

4. The organic electroluminescent compound according to claim 2, wherein A is represented by the following formula 10: 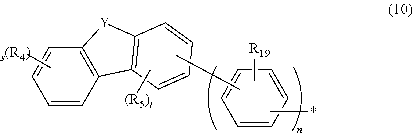
wherein
formula 10 is bonded to the compounds of formulae 1 and 4 to 9 via *;
Y, R₄, R₅, n, s and t are as defined in claim 1;
R₁₉ represents hydrogen, deuterium, a halogen, a substituted or unsubstituted (C1-C30)alkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur; and
the heteroaryl group contains at least one hetero atom selected from B, N, O, S, P(═O), Si and P.

5. The organic electroluminescent compound according to claim 2, wherein X represents —O—, —S, or —C(R₇)(R₈)—, in which R₇ and R₈ are as defined in claim 1.

6. The organic electroluminescent compound according to claim 2, wherein Y represents —O—, —S, or —N(R₆)—, in which R₆ is as defined in claim 1.

7. The organic electroluminescent compound according to claim 2, wherein Z is represented by formula 3, wherein Ar₁ represents a substituted or unsubstituted (C1-C30)alkyl group, a substituted or unsubstituted (C6-C30)aryl group, a substituted or unsubstituted 5- to 30-membered heteroaryl group, —NR₁₁R₁₂ or —SiR₁₃R₁₄R₁₅, in which R₁₁ to R₁₅ are as defined in claim 1.

8. The organic electroluminescent compound according to claim 7, wherein Z is represented by the following formula 11: 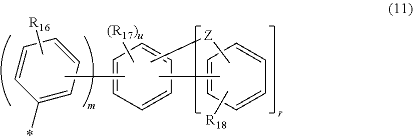
wherein
formula 11 is bonded to the compounds of formulae 1 and 4 to 9 via *;
Z represents —O—, —S—, —N(R₂₀)—, —C(R₂₁)(R₂₂)—, or —Si(R₂₃)(R₂₄)—;
R₁₆ to R₁₈ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, —NR₂₅R₂₆ or —SiR₂₇R₂₈R₂₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;
R₂₀ to R₂₉ each independently represent hydrogen, deuterium, a halogen, a substituted or unsubstituted (C1-C30)alkyl group, a substituted or unsubstituted (C6-C30)aryl group, or a substituted or unsubstituted 5- to 30-membered heteroaryl group; or are linked to an adjacent substituent(s) to form a mono- or polycyclic, 3- to 30-membered alicyclic or aromatic ring;
m represents an integer of 0 to 2;
r represents an integer of 0 or 1;
u represents an integer of 1 to 3; where u is 2 or more, each of R₁₇ is the same or different; and
the heteroaryl group contains at least one hetero atom selected from B, N, O, S, P(═O), Si and P.

9. The organic electroluminescent compound according to claim 1, wherein the compound represented by formula 1 is selected from the group consisting of:

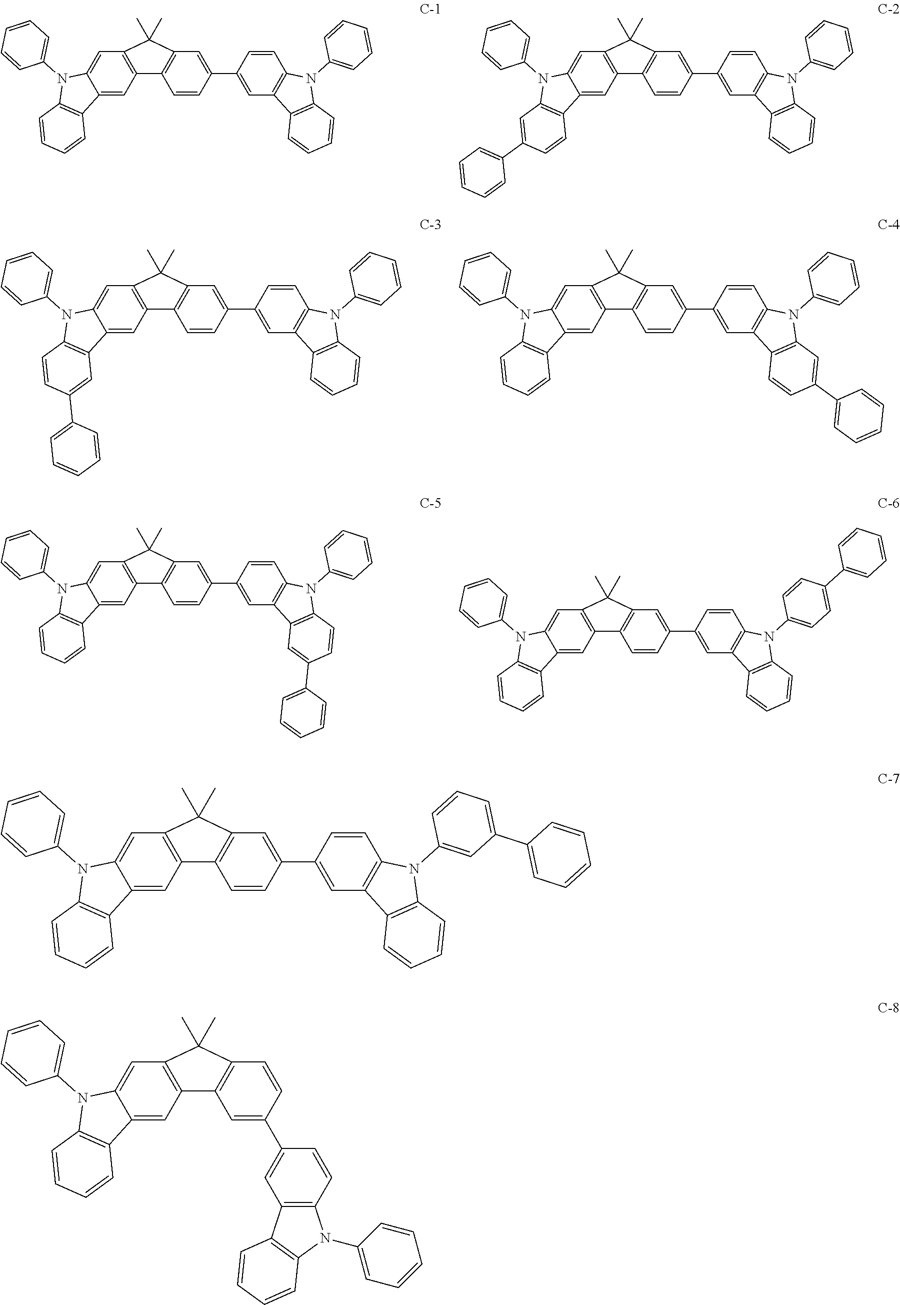

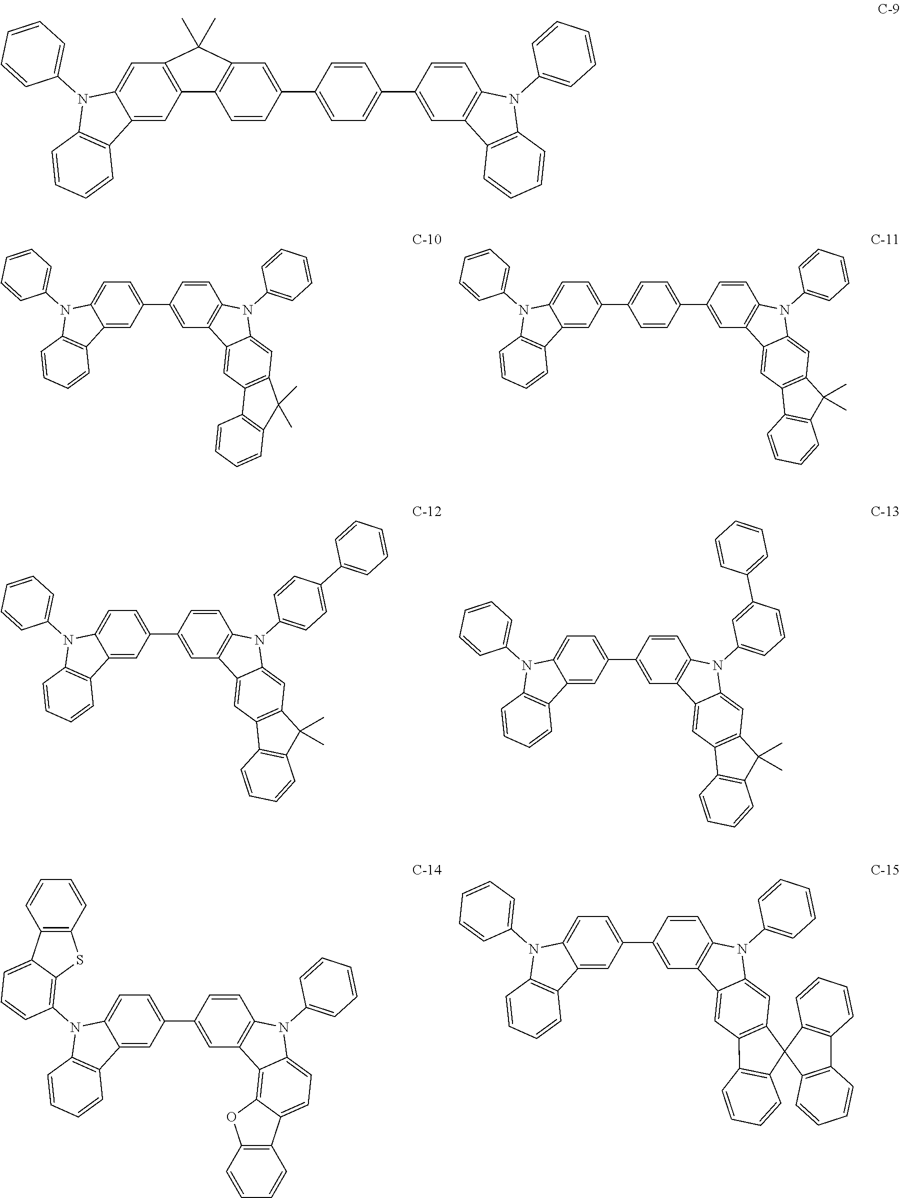

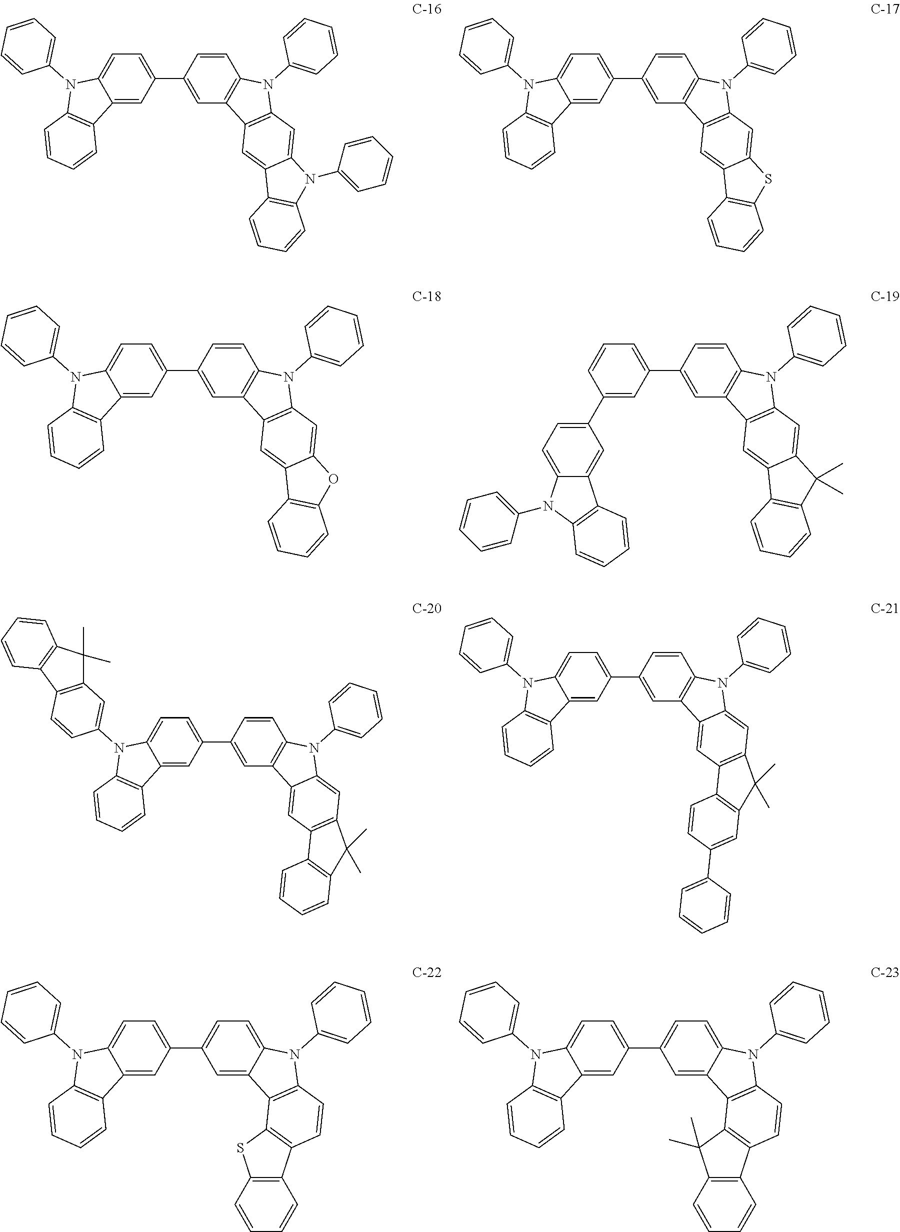

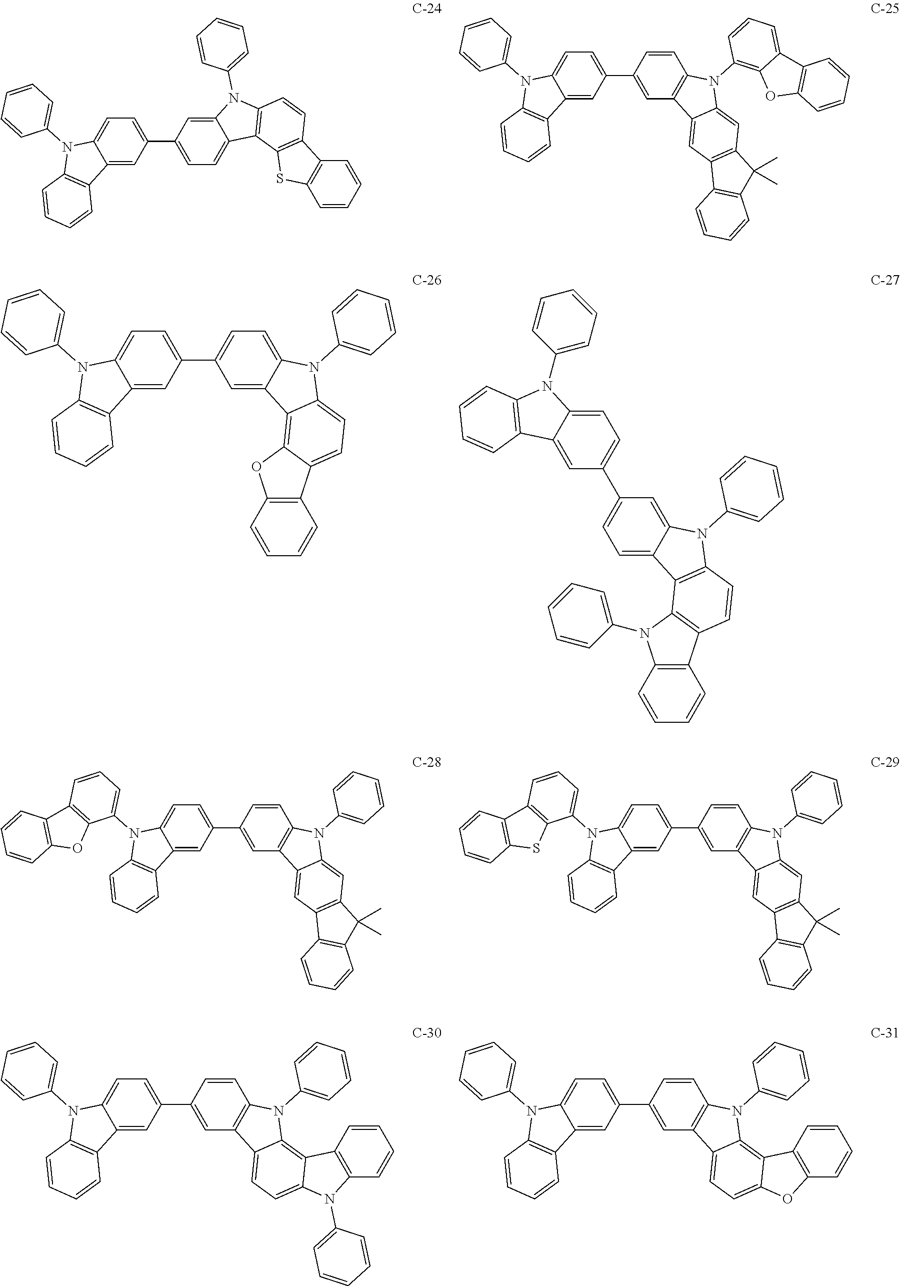

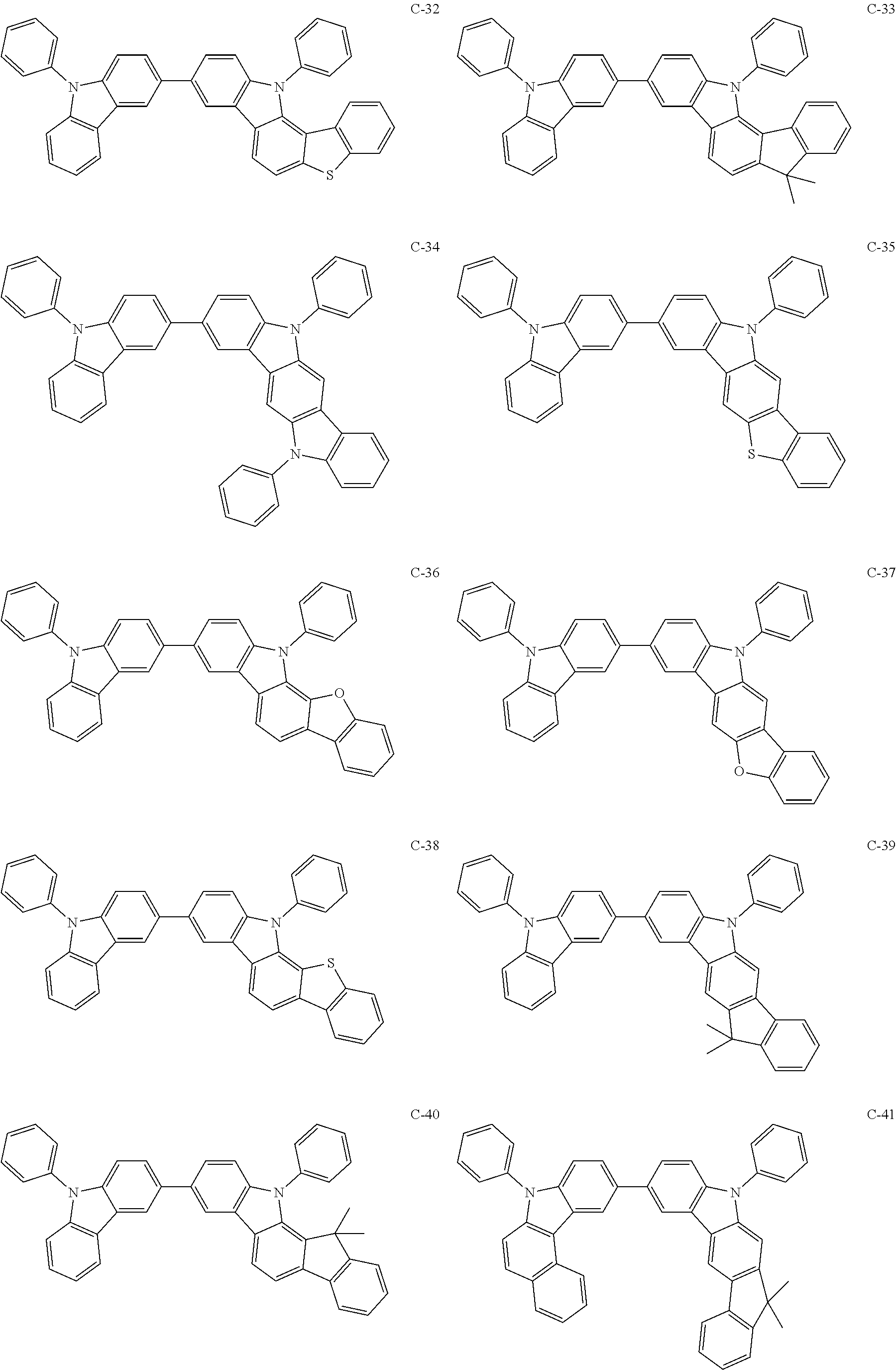

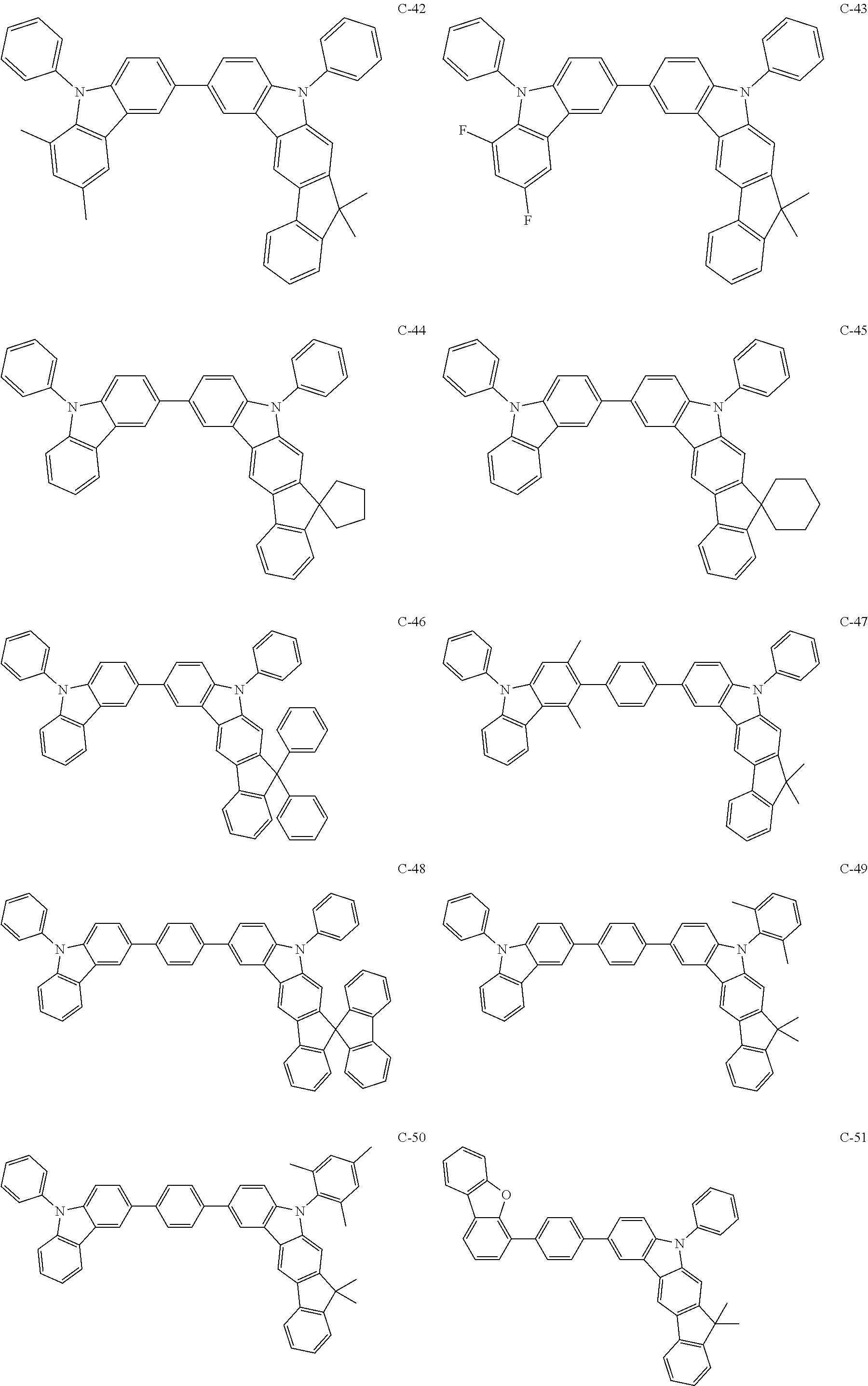

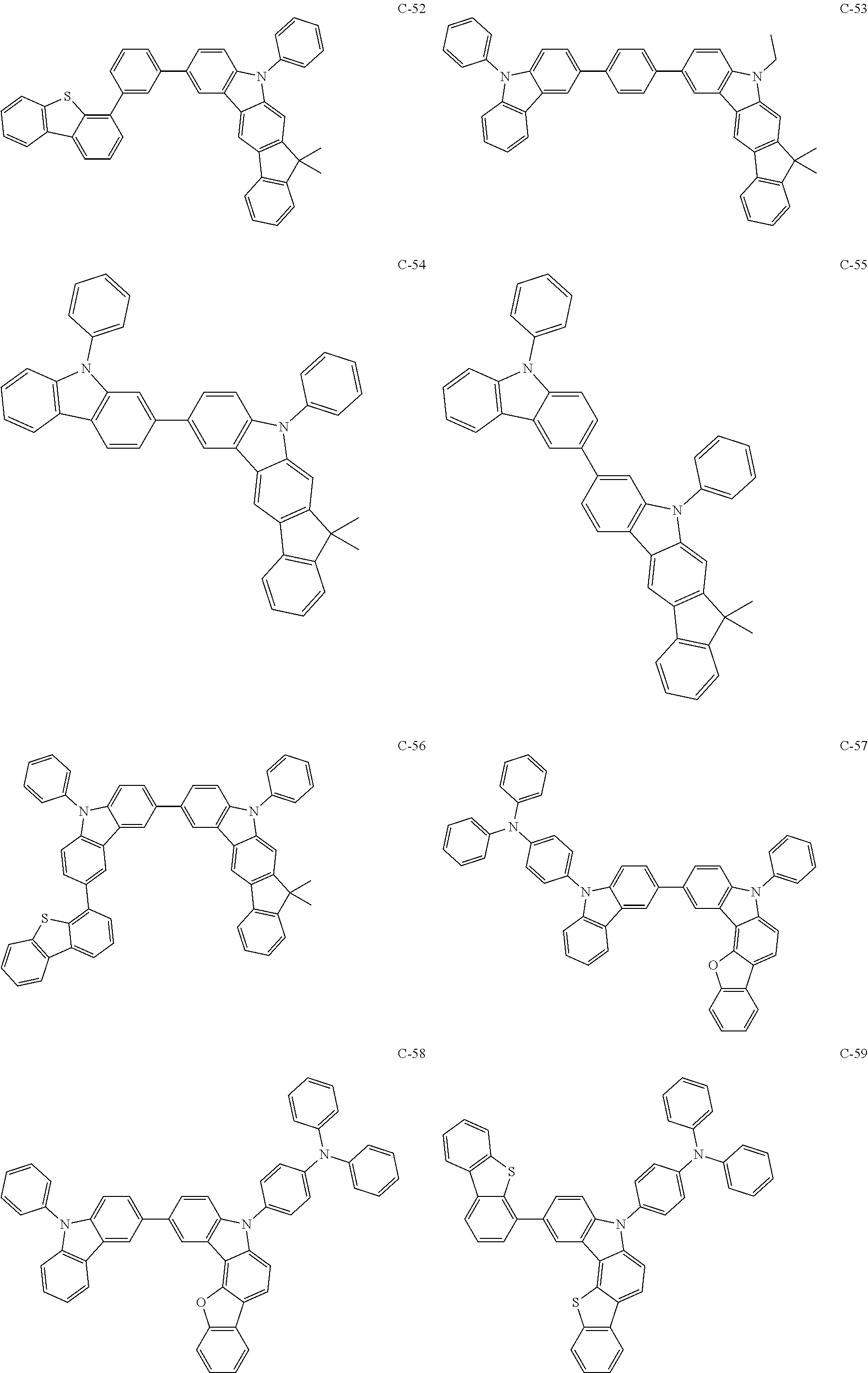

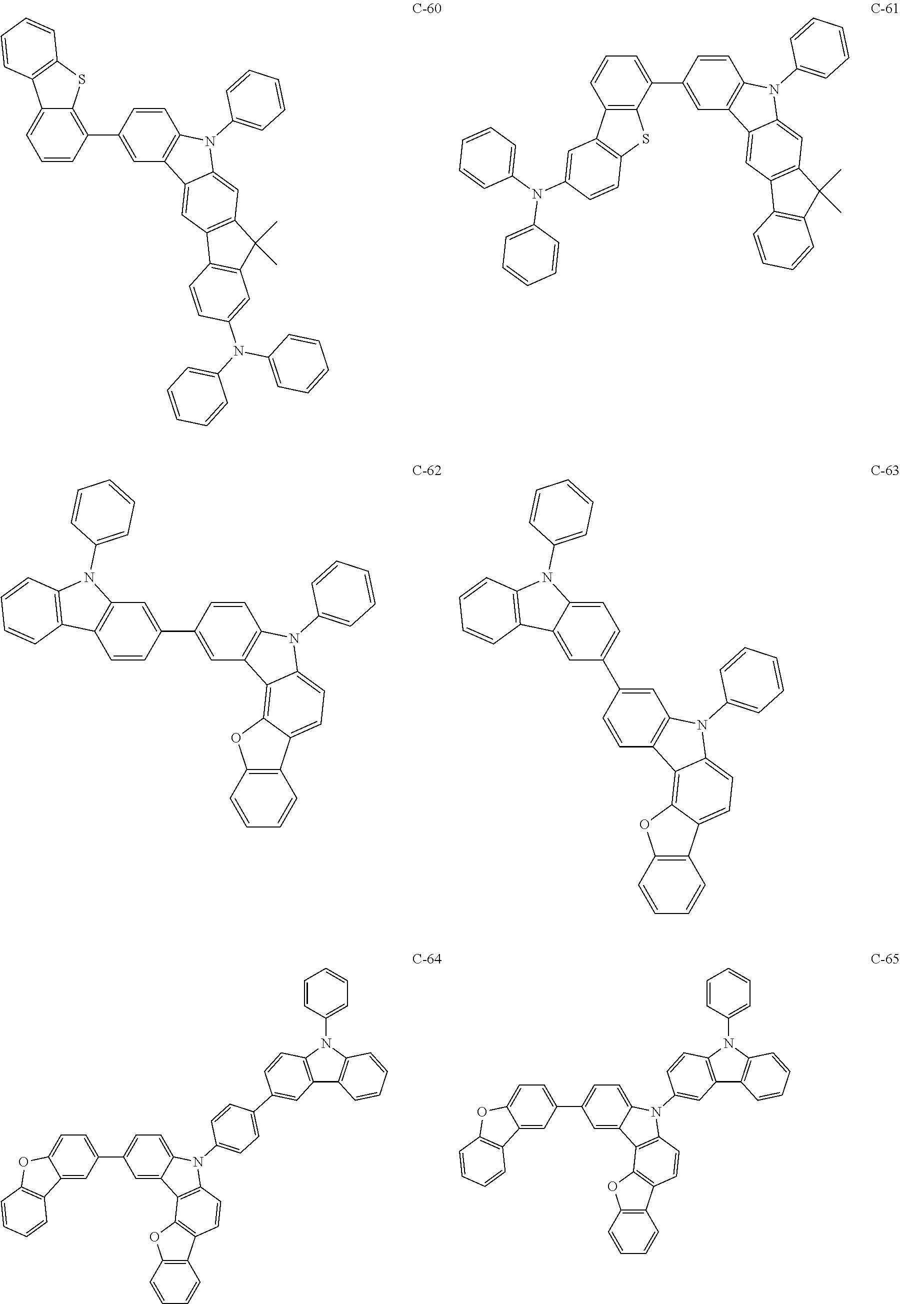

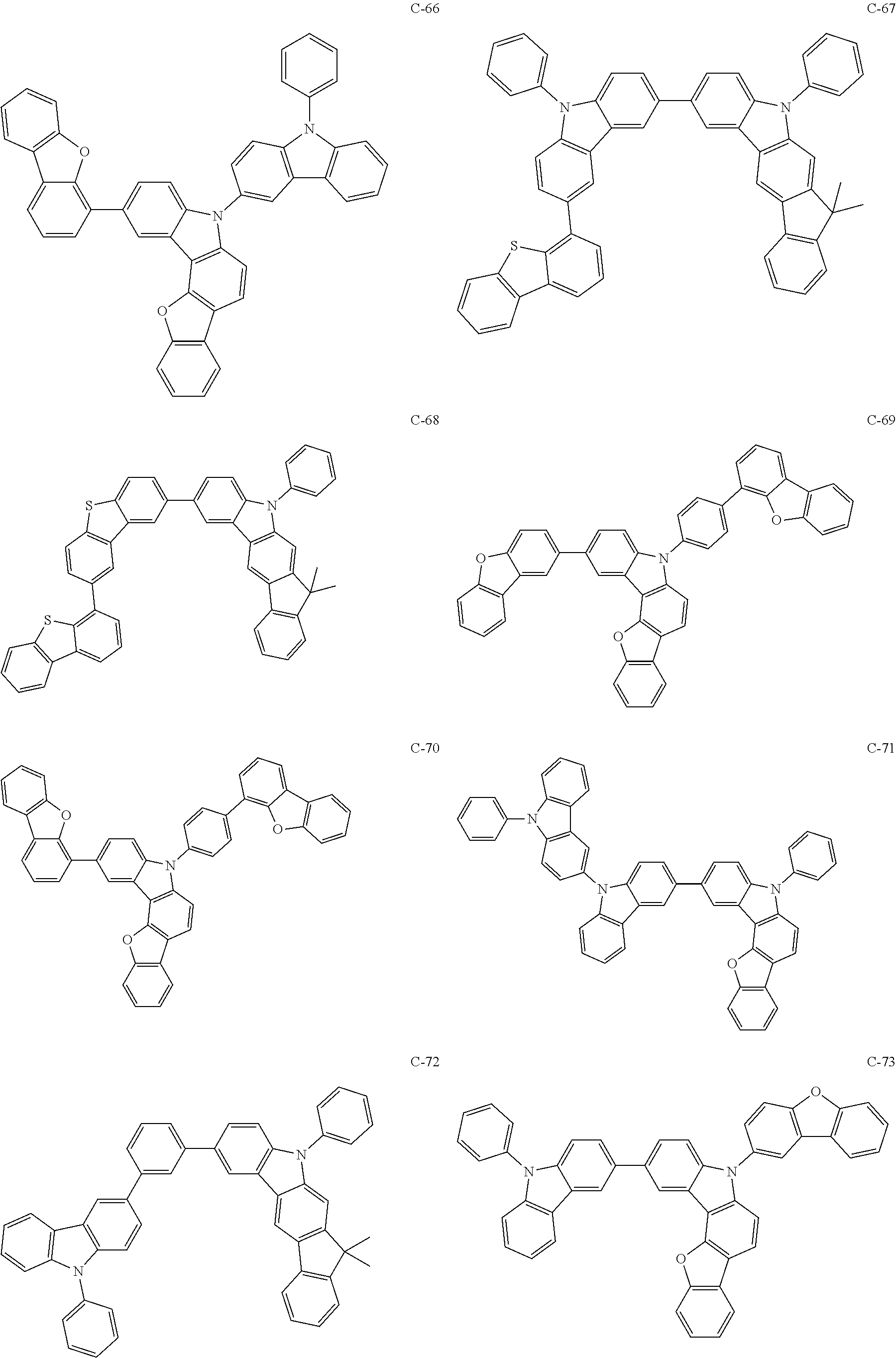

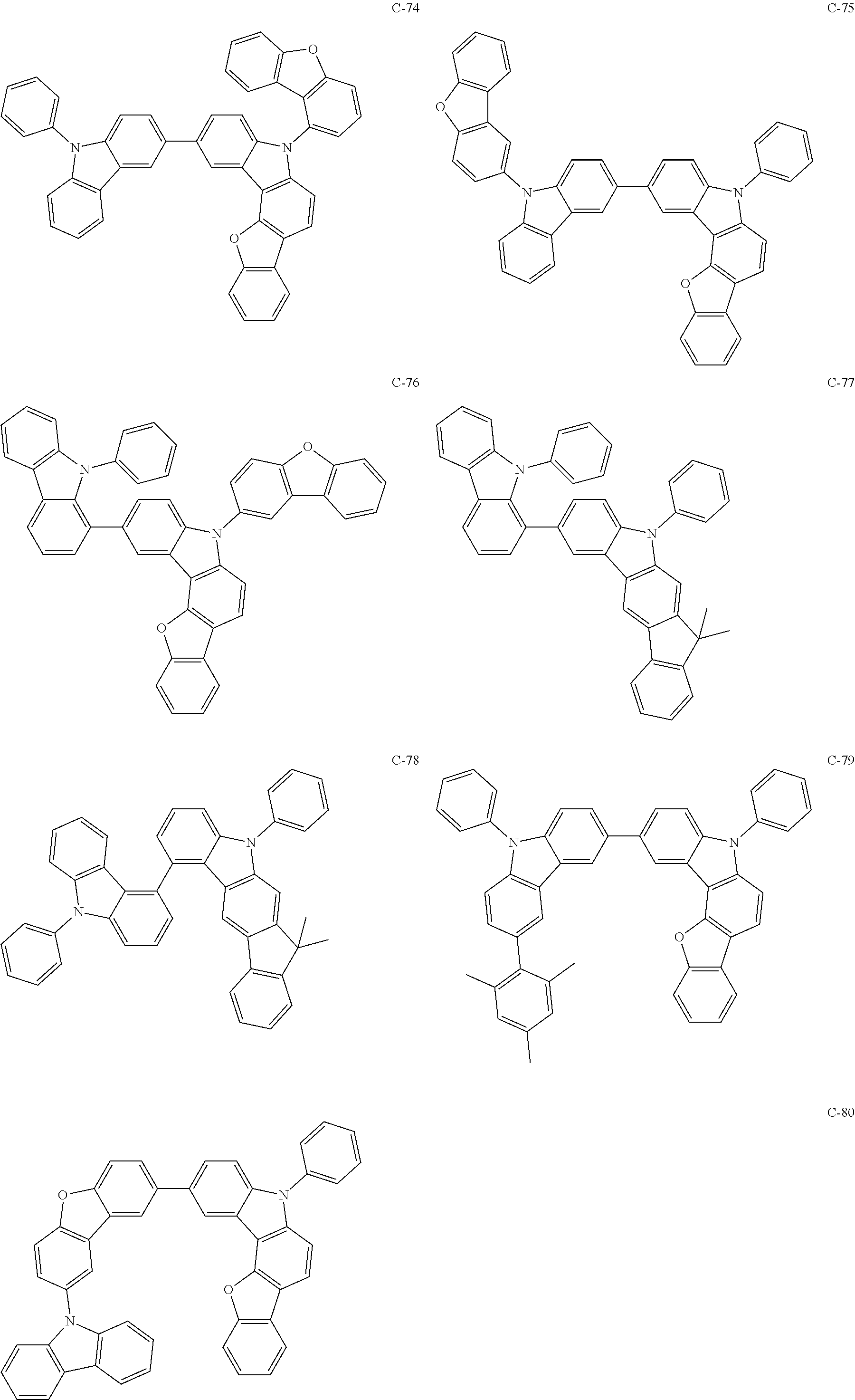

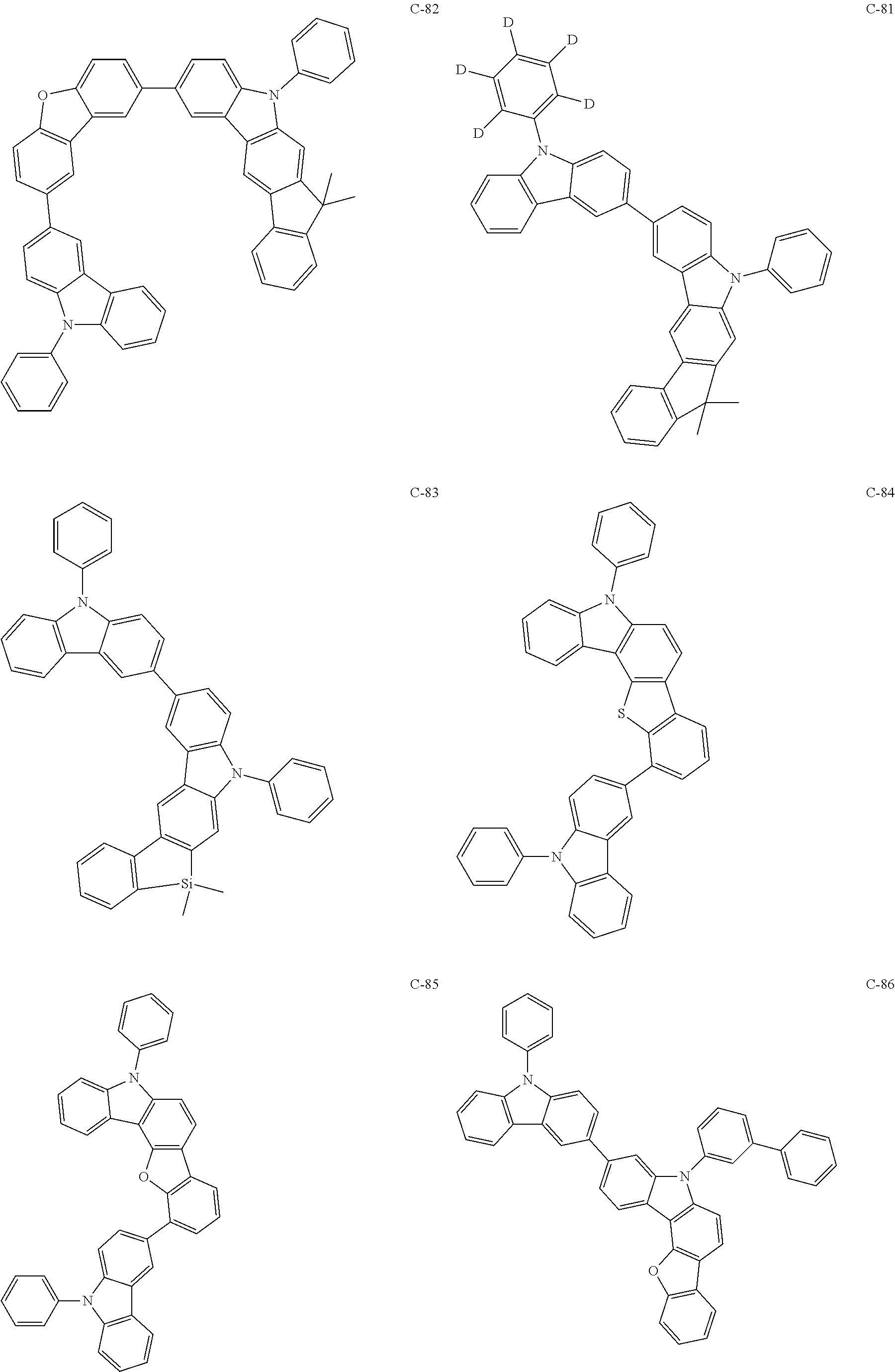

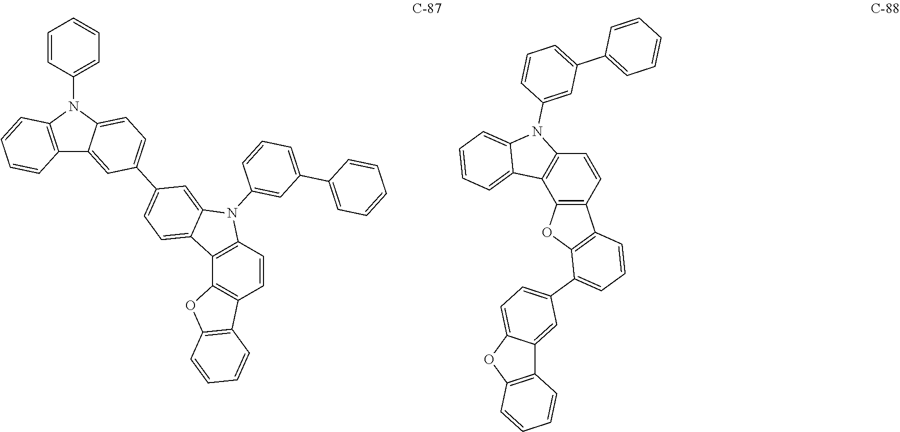 [SMILES: c1ccc(-c2cccc(-n3c4cc(-c5ccc6c(c5)c5ccccc5n6-c5ccccc5)ccc4c4c5oc6ccccc6c5ccc43)c2)cc1 ; c1ccc(-c2cccc(-n3c4ccccc4c4c5oc6c(-c7ccc8oc9ccccc9c8c7)cccc6c5ccc43)c2)cc1]

10. An organic electroluminescent device comprising the compound according to claim 1.
